(19) United States
(12) Patent Application Publication
(10) Pub. No.: US 2013/0303777 A1
(43) Pub. Date: Nov. 14, 2013

(54) LUMINESCENT MATERIAL, AND ORGANIC LIGHT-EMITTING ELEMENT, WAVELENGTH-CONVERTING LIGHT-EMITTING ELEMENT, LIGHT-CONVERTING LIGHT-EMITTING ELEMENT, ORGANIC LASER DIODE LIGHT-EMITTING ELEMENT, DYE LASER, DISPLAY DEVICE, AND ILLUMINATION DEVICE USING SAME

(71) Applicants: Ken Okamoto, Osaka-shi (JP); Tetsuji Itoh, Osaka-shi (JP); Masahito Ohe, Osaka-shi (JP); Yoshimasa Fujita, Osaka-shi (JP); Hidenori Ogata, Osaka-shi (JP); Akinori Itoh, Osaka-shi (JP); Makoto Yamada, Osaka-shi (JP)

(72) Inventors: Ken Okamoto, Osaka-shi (JP); Tetsuji Itoh, Osaka-shi (JP); Masahito Ohe, Osaka-shi (JP); Yoshimasa Fujita, Osaka-shi (JP); Hidenori Ogata, Osaka-shi (JP); Akinori Itoh, Osaka-shi (JP); Makoto Yamada, Osaka-shi (JP)

(73) Assignee: Sharp Kabushiki Kaisha, Osaka-shi (JP)

(21) Appl. No.: 13/877,901

(22) PCT Filed: Oct. 4, 2011
(86) PCT No.: PCT/JP2011/072833

§ 371 Date: Jul. 30, 2013

(30) Foreign Application Priority Data
Oct. 6, 2010 (JP) 2010-226740

(51) Int. Cl. H01L 51/00; G09G 3/30; H01S 3/14; H05B 33/08; H01L 51/52; H01L 33/50

(52) U.S. Cl. CPC H01L 51/0085; H01L 51/52; H01L 33/502; H01S 3/14; H05B 33/0896; G09G 3/30
USPC 548/103; 257/40; 257/98; 372/40; 315/291; 345/690; 556/7; 345/77

(57) ABSTRACT

A luminescent material includes a transition metal complex which comprises any one of Ir, Os, and Pt as a central metal; and at least one of a carbene ligand and a silylene ligand. The carbene ligand includes a boron atom in a skeleton thereof. The carbene ligand is neutral or monoanionic. The carbene ligand is monodentate, bidentate, or tridentate. The silylene ligand includes a boron atom in a skeleton thereof. The silylene ligand is neutral or monoanionic. The silylene ligand is monodentate, bidentate, or tridentate.

### TECHNICAL FIELD

The present invention relates to a luminescent material, and an organic light-emitting element, a wavelength-converting light-emitting element (color-converting light-emitting element), a light-converting light-emitting element, an organic laser diode light-emitting element, a dye laser, a display device, and an illumination device using the same.

Priority is claimed on Japanese Patent Application No. 2010-226740, filed Oct. 6, 2010, the content of which is hereby incorporated herein by reference in its entirety.

### BACKGROUND ART

In order to reduce the power consumption of an organic EL (electroluminescence) element, a highly efficient luminescent material has been developed. A phosphorescent luminescent material using the emission from the triplet excited state can obtain a higher luminous efficiency compared to a fluorescent luminescent material using only the fluorescent emission from the singlet excited state. Therefore, a phosphorescent luminescent material has been developed.

Currently, a phosphorescent material capable of achieving an internal quantum efficiency of approximately 100% at a maximum is used for green pixels and red pixels of an organic EL element. However, a fluorescent material having an internal quantum efficiency of approximately 25% at a maximum is used for blue pixels. The reason is because blue light emission requires a higher energy than that of red light or green light emission; and when it is attempted to obtain high-energy emission from phosphorescent emission at the triplet excited level, portions in a molecular structure which are unstable under high energy are likely to deteriorate.

As a blue phosphorescent material, in order to obtain a high-energy triplet excited state, an iridium (Ir) complex in which an electron-attracting group such as fluorine is introduced into a ligand as a substituent is known (for example, refer to NPLs 1 to 5). However, in a blue phosphorescent material into which an electron-attracting group is introduced, the luminous efficiency is relatively high, whereas the light resistance is low and the lifetime is short.

In addition, it is reported that short-wavelength emission is possible in a complex in which a carbene ligand is used without introducing an electron-attracting group thereinto (refer to NPL 6 and PTL 1).

### CITATION LIST

### Patent Literature

Patent Document 1: Japanese Patent No. 4351702 Non-Patent Literature
Non-Patent Document 1: Angew. Chem. Int. Ed., 2008, 47, 4542-4545
Non-Patent Document 2: Chem. Eur. J., 2008, 14, 5423-5434
Non-Patent Document 3: Inorg. Chem., Vol. 47, No. 5, 2008, 1476-1487
Non-Patent Document 4: Organic EL Display, Ohmsha, TOKITO Shizuo, ADACHI Chihaya, and MURATA Hideyuki
Non-Patent Document 5: Highly Efficient OLEDs with Phosphorescent Materials, VILEY-VCH, Edited by Hartmut Yersin
Non-Patent Document 6: Inorg. Chem., 44, 2005, 7992

### SUMMARY OF INVENTION

Luminescent materials disclosed in Non-Patent Document 6 and Patent Document 1 emit blue phosphorescence without introducing an electron-attracting group, which deteriorates light resistance, thereinto. However, the luminous efficiency is low.

Therefore, the development of a luminescent material, which emits blue light with a high luminous efficiency without introducing an electron-attracting group thereinto, is desired.

Various aspects of the present invention have been conceived in consideration of such circumstances of the related art; and are to provide a highly efficient luminescent material, and an organic light-emitting element, a wavelength-converting light-emitting element, a light-converting light-emitting element, an organic laser diode light-emitting element, a dye laser, a display device, and an illumination device using the same.

### Means for Solving the Problem

In order to solve the above-described problems, the present inventors have thoroughly studied and found the following configurations which are aspects of the present invention.

According to an aspect of the present invention, there is provided a luminescent material including a transition metal complex, wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

In the luminescent material according to the aspect, the transition metal complex may include a partial structure represented by the following formula (1) or (2).

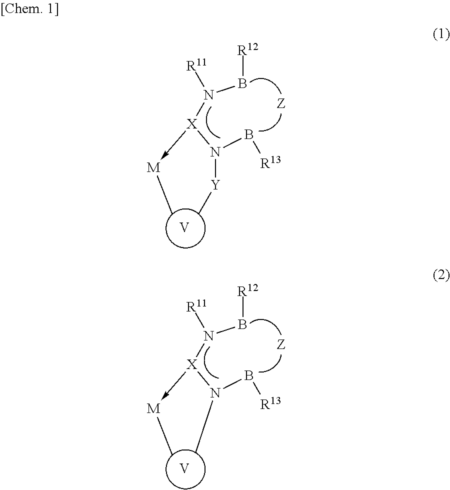

(In the formulae (1) and (2), M represents Ir, Os, or Pt; X represents C or Si; R¹¹, R¹², and R¹³ each independently represent a monovalent organic group; Y represents a divalent hydrocarbon group; Z represents a divalent organic group; and V represents a divalent organic group having a ring structure.)

In the luminescent material according to the aspect, the transition metal complex may include a partial structure represented by the following formula (3) or (4).

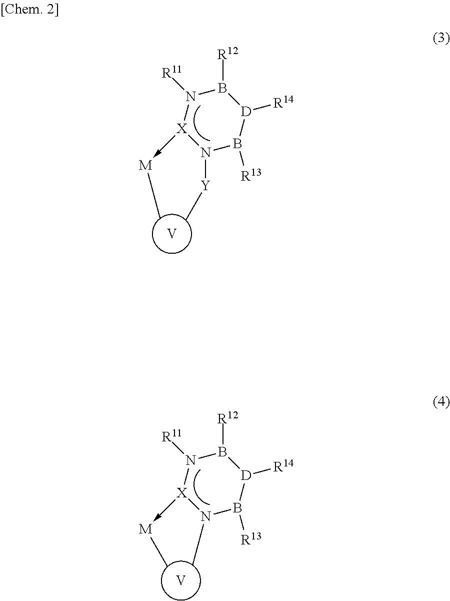

(In the formulae (3) and (4), M represents Ir, Os, or Pt; X represents C or Si; R¹¹, R¹², R¹³, and R¹⁴ each independently represent a monovalent organic group; Y represents a divalent hydrocarbon group; D represents an electron-donating atom; and V represents a divalent organic group having a ring structure.)

In the luminescent material according to the aspect, the transition metal complex may include a partial structure represented by the following formula (5) or (6).

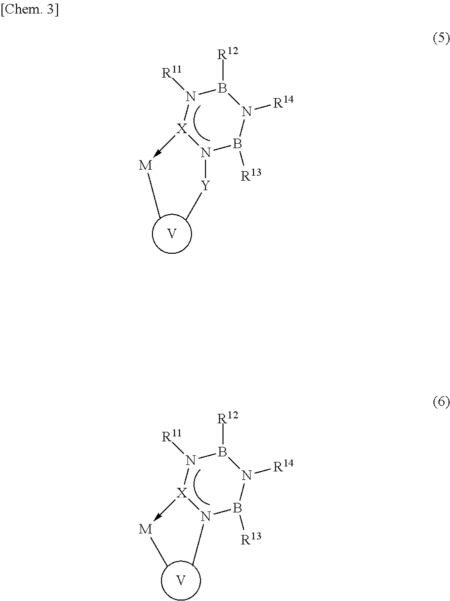

(In the formulae (5) and (6), M represents Ir, Os, or Pt; X represents C or Si; R¹¹, R¹², R¹³, and R¹⁴ each independently represent a monovalent organic group; Y represents a divalent hydrocarbon group; and V represents a divalent organic group having a ring structure.)

In the luminescent material according to the aspect, the transition metal complex may include a partial structure represented by the following formula (7) or (8).

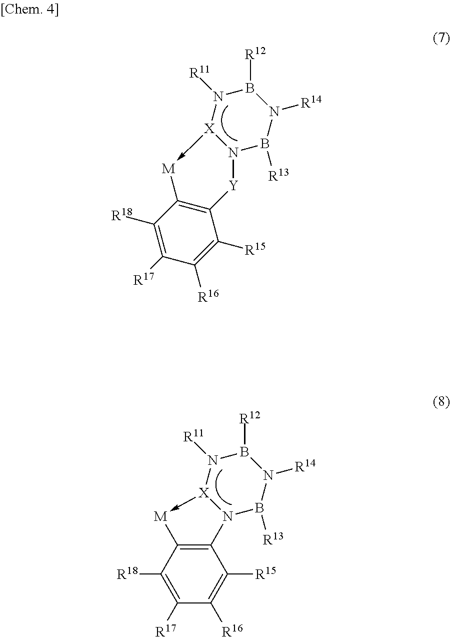

(In the formulae (7) and (8), M represents Ir, Os, or Pt; X represents C or Si; R¹¹, R¹², R¹³, R¹⁴, R¹⁵, R¹⁶, R¹⁷, and R¹⁸ each independently represent a monovalent organic group; and Y represents a divalent hydrocarbon group.)

In the luminescent material according to the aspect, the transition metal complex may include a partial structure represented by the following formula (9).

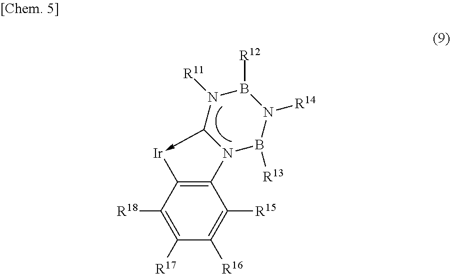

(In the formula (9), R¹¹, R¹², R¹³, R¹⁴, R¹⁵, R¹⁶, R¹⁷, and R¹⁸ each independently represent a monovalent organic group.)

In the luminescent material according to the aspect, the transition metal complex may be a tris complex in which three bidentate ligands are coordinated, and the amount of a mer (meridional) isomer contained in the transition metal complex may be greater than that of a fac (facial) isomer.

According to another aspect of the present invention, there is provided an organic light-emitting element including: at least one organic layer that includes a light-emitting layer; and a pair of electrodes between which the organic layer is interposed, wherein the organic layer includes a transition metal complex, wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

In the organic light-emitting element according to another aspect, the light-emitting layer may include the luminescent material.

According to still another aspect of the present invention, there is provided a wavelength-converting light-emitting element including an organic light-emitting element and a fluorescent layer which is disposed on a side of extracting light from the organic light-emitting element, wherein the fluorescent layer absorbs light emitted from the organic light-emitting element and emits light having a different wavelength from that of the absorbed light, wherein the organic light-emitting element includes at least one organic layer that includes a light-emitting layer and a pair of electrodes between which the organic layer is interposed, wherein the organic layer includes a transition metal complex, and wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided a wavelength-converting light-emitting element including a light-emitting element; and a fluorescent layer which is disposed on a side of extracting light from the light-emitting element, wherein the fluorescent layer absorbs light emitted from the light-emitting element and emits light having a different wavelength from that of the absorbed light,

wherein the fluorescent layer includes a transition metal complex, and wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided a light-converting light-emitting element including at least one organic layer that includes a light-emitting layer, a layer for multiplying a current, and a pair of electrodes between which the organic layer and the layer for multiplying a current are interposed, wherein the light-emitting layer includes a host material and a transition metal complex, and wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided an organic laser diode light-emitting element including an excitation light source and a resonator structure that is irradiated with light emitted from the excitation light source, wherein the resonator structure includes at least one organic layer that includes a laser-active layer and a pair of electrodes between which the organic layer is interposed, wherein the laser active layer includes a host material and a transition metal complex, wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided a dye laser including: a laser medium that contains a luminescent material and an excitation light source that stimulates the luminescent material of the laser medium to emit phosphorescence and to perform laser oscillation, wherein the luminescent material is a transition metal complex, wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided a display device including: an image signal output portion that outputs an image signal, a drive portion that applies a current or a voltage based on the signal output from the image signal output portion, and a light-emitting portion that emits light based on the current or the voltage applied from the drive portion, wherein the light-emitting portion is an organic light-emitting element including at least one organic layer that includes a light-emitting layer and a pair of electrodes between which the organic layer is interposed, wherein the organic layer includes a transition metal complex, wherein the transition metal complex includes any one of Ir, Os, and Pt as a central metal, and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided a display device including an image signal output portion that outputs an image signal, a drive portion that applies a current or a voltage based on the signal output from the image signal output portion, and a light-emitting portion that emits light based on the current or the voltage applied from the drive portion, wherein the light-emitting portion is a wavelength-converting light-emitting element including an organic light-emitting element and a fluorescent layer that is disposed on a side of extracting light from the organic light-emitting element, wherein the fluorescent layer absorbs light emitted from the organic light-emitting element and emits light having a different wavelength from that of the absorbed light, wherein the organic light-emitting element includes at least one organic layer that includes a light-emitting layer and a pair of electrodes between which the organic layer is interposed, wherein the organic layer includes a transition metal complex, wherein the transition metal complex includes any one of Ir, Os, and Pt as a central metal, and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided a display device including an image signal output portion that outputs an image signal, a drive portion that applies a current or a voltage based on the signal output from the image signal output portion, and a light-emitting portion that emits light based on the current or the voltage applied from the drive portion, wherein the light-emitting portion is a light-converting light-emitting element including at least one organic layer that includes a light-emitting layer, a layer for multiplying a current, and a pair of electrodes between which the organic layer and the layer for multiplying a current are interposed, wherein the light-emitting layer includes a host material and a transition metal complex, and wherein the transition metal complex includes any one of Ir, Os, and Pt as a central metal, and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still aspect of the present invention, there is provided an electronic apparatus including the above-described display device.

In the display device according to the aspect, an anode and a cathode of the light-emitting portion may be arranged in a matrix shape.

In the display device according to the aspect, the light-emitting portion may be driven by a thin film transistor.

According to still another aspect of the present invention, there is provided an illumination device including a drive portion that applies a current or a voltage, and a light-emitting portion that emits light based on the current or the voltage applied from the drive portion, wherein the light-emitting portion is an organic light-emitting element including at least one organic layer that includes a light-emitting layer and a pair of electrodes between which the organic layer is interposed, wherein the organic layer includes a transition metal complex, wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided an illumination device including a drive portion that applies a current or a voltage and a light-emitting portion that emits light based on the current or the voltage applied from the drive portion, wherein the light-emitting portion is a wavelength-converting light-emitting element including an organic light-emitting element and a fluorescent layer which is disposed on a side of extracting light from the organic light-emitting element, wherein the fluorescent layer absorbs light emitted from the organic light-emitting element and emits light having a different wavelength from that of the absorbed light, wherein the organic light-emitting element includes at least one organic layer that includes a light-emitting layer and a pair of electrodes between which the organic layer is interposed, and wherein the organic layer includes a transition metal complex, wherein the transition metal complex includes any one of Ir, Os, and Pt as a central metal and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided an illumination device including a drive portion that applies a current or a voltage and a light-emitting portion that emits light based on the current or the voltage applied from the drive portion, wherein the light-emitting portion is a light-converting light-emitting element including at least one organic layer that includes a light-emitting layer, a layer for multiplying a current, and a pair of electrodes between which the organic layer and the layer for multiplying a current are interposed, wherein the light-emitting layer includes a host material and a transition metal complex, and wherein the transition metal complex includes any one of Ir, Os, and Pt as a central meta; and at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

According to still another aspect of the present invention, there is provided an illumination apparatus including the above-described illumination device.

### Effects of Invention

According to the aspects of the present invention, it is possible to provide a highly efficient luminescent material, and an organic light-emitting element, a wavelength-converting light-emitting element, a light-converting light-emitting element, an organic laser diode light-emitting element, a dye laser, a display device, and an illumination device using the same.

### BRIEF DESCRIPTION OF DRAWINGS

FIG. 1 is a diagram schematically illustrating a first embodiment of an organic light-emitting element according to the present invention.

FIG. 2 is a cross-sectional view schematically illustrating a second embodiment of the organic light-emitting element according to the present invention.

FIG. 3 is a cross-sectional view illustrating a first embodiment of a wavelength-converting light-emitting element according to the present invention.

FIG. 4 is a top view illustrating the wavelength-converting light-emitting element of FIG. 3.

FIG. 5 is a diagram schematically illustrating a first embodiment of a light-converting light-emitting element according to the present invention.

FIG. 6 is a diagram schematically illustrating a first embodiment of an organic laser diode light-emitting element according to the present invention.

FIG. 7 is a diagram schematically illustrating a first embodiment of a dye laser according to the present invention.

FIG. 8 is a diagram illustrating a configuration example of the connection between an interconnection structure and a drive circuit in a display device according to the present invention.

FIG. 9 is a diagram illustrating a circuit constituting one pixel which is arranged in a display device including an organic light-emitting element according to the present invention.

FIG. 10 is a perspective view schematically illustrating a first embodiment of an illumination device according to the present invention.

FIG. 11 is a diagram illustrating an external appearance of a ceiling light which is an application example of an organic EL device according to the present invention.

FIG. 12 is a diagram illustrating an external appearance of an illumination stand which is an application example of an organic EL device according to the present invention.

FIG. 13 is a diagram illustrating an external appearance of a mobile phone which is an application example of an organic EL device according to the present invention.

FIG. 14 is a diagram illustrating an external appearance of a thin-screen TV which is an application example of an organic EL device according to the present invention.

FIG. 15 is a diagram illustrating an external appearance of a portable game machine which is an application example of an organic EL device according to the present invention.

FIG. 16 is a diagram illustrating an external appearance of a laptop computer which is an application example of an organic EL device according to the present invention.

### DESCRIPTION OF EMBODIMENTS

### First Embodiment

### <Luminescent Material>

A luminescent material according to an embodiment of the present invention is a transition metal complex which includes any one of Ir, Os, and Pt as a central metal and at least one of a carbene ligand and a silylene ligand, in which the carbene ligand includes a boron atom in a skeleton thereof, the carbene ligand is neutral or monoanionic, the carbene ligand is monodentate, bidentate, or tridentate, the silylene ligand includes a boron atom in a skeleton thereof, the silylene ligand is neutral or monoanionic, and the silylene ligand is monodentate, bidentate, or tridentate. In the transition metal complex which is the luminescent material according to the embodiment, when a central metal is Ir or Os, the transition metal complex has a 6-coordinated octahedral structure; and when a central metal is Pt, the transition metal complex has a 4-coordinated square planar structure.

For example, it is preferable that the transition metal complex, which is the luminescent material according to the embodiment, includes a partial structure represented by the following formula (1) or (2).

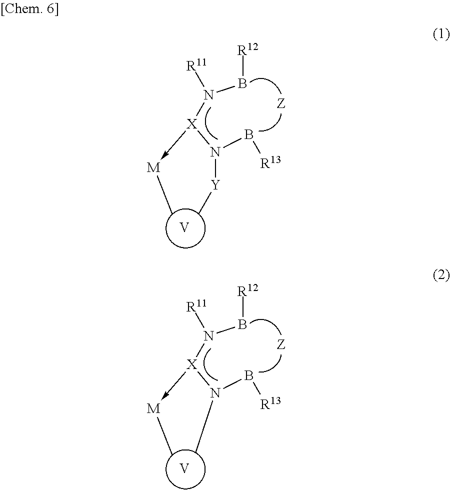

(In the formulae (1) and (2), M represents Ir, Os, or Pt; X represents C or Si; R¹¹, R¹², and R¹³ each independently represent a monovalent organic group; Y represents a divalent hydrocarbon group; Z represents a divalent organic group; and V represents a divalent organic group having a ring structure.)

Examples of the monovalent organic group represented by R¹¹, R¹², and R¹³ include an aliphatic hydrocarbon group having 1 to 8 carbon atoms or an aromatic group having 1 to 10 carbon atoms. The aliphatic hydrocarbon group and the aromatic group represented by R¹¹, R¹², and R¹³ may have a substituent.

Examples of the aliphatic hydrocarbon group having 1 to 8 carbon atoms represented by R¹¹, R¹², and R¹³ include a linear, branched, or cyclic aliphatic hydrocarbon group. Specific examples thereof include a methyl group, an ethyl group, an n-propyl group, an isopropyl group, an n-butyl group, a tert-butyl group, an n-pentyl group, an n-hexyl group, an n-heptyl group, an n-octyl group, and a cyclohexyl group. R¹¹ and R¹² may be partially bonded and integrated to form a ring structure.

Examples of the aromatic group having 1 to 10 carbon atoms represented by R¹¹, R¹², and R¹³ include a phenyl group and a naphthyl group, and these aromatic groups may have a substituent.

Examples of the divalent hydrocarbon group represented by Y include a divalent hydrocarbon group having 1 to 3 carbon atoms. Specific examples thereof include —CH₂—, —CH₂—CH₂—, and —C(CH₃)₂—. Among these, —CH₂— is preferable.

Examples of the divalent organic group having a ring structure represented by V include an aromatic cyclic divalent organic structure. An aromatic hydrocarbon group or an aromatic group containing nitrogen and carbon is preferable. It is preferable that the divalent organic group having a ring structure represented by V be represented by any one of the following formulae (V-1) to (V-5).

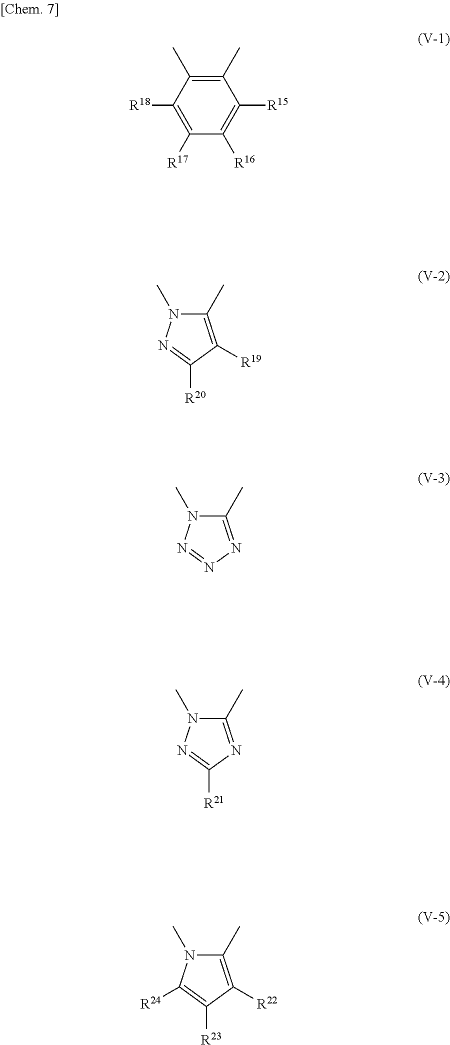

In the formula (V-1), for example, R¹⁵, R¹⁶, R¹⁷, and R¹⁸ each independently represent a monovalent organic group. Examples of the monovalent organic group include a hydrogen atom, an aliphatic hydrocarbon group having 1 to 8 carbon atoms and an aromatic group having 1 to 10 carbon atoms. The aliphatic hydrocarbon group and the aromatic group represented by R¹⁵, R¹⁶, R¹⁷, and R¹⁸ may have a substituent. Examples of the aliphatic hydrocarbon group and the aromatic group represented by R¹⁵, R¹⁶, R¹⁷, and R¹⁸ are the same as those represented by R¹¹, R¹², and R¹³ in the formula (1) or (2). R¹⁵ and R¹⁶, R¹⁶ and R¹⁷, and R¹⁷ and R¹⁸ may be partially bonded and integrated to form a ring structure. Specific examples thereof include a structure in which R¹⁵ and R¹⁶ are partially bonded and linked with a cyclic group such as adamantane.

In the formula (V-2), R¹⁹ and R²¹ each independently represent a monovalent organic group. Examples of the monovalent organic group include a hydrogen atom, an aliphatic hydrocarbon group having 1 to 8 carbon atoms, or an aromatic group having 1 to 10 carbon atoms. The aliphatic hydrocarbon group and the aromatic group represented by R¹⁹ and R²⁰ may have a substituent. Examples of the aliphatic hydrocarbon group and the aromatic group represented by R¹⁹ and R²⁰ are the same as those represented by R¹¹, R¹², and R¹³ in the formula (1) or (2). R¹⁹ and R²⁰ may be partially bonded and integrated to form a ring structure. Specific examples include a structure in which R¹⁹ and R²⁰ are partially bonded and linked with a cyclic group such as adamantane.

In the formula (V-4), R²¹ represents a monovalent organic group. Examples of the monovalent organic group include a hydrogen atom, an aliphatic hydrocarbon group having 1 to 8 carbon atoms, or an aromatic group having 1 to 10 carbon atoms. The aliphatic hydrocarbon group and the aromatic group represented by R²¹ may have a substituent. Examples of the aliphatic hydrocarbon group and the aromatic group represented by R²¹ are the same as those represented by R¹¹, R¹², and R¹³ in the formula (1) or (2).

In the formula (V-5), R²², R²³, R²⁴ each independently represent a monovalent organic group. Examples of the monovalent organic group include a hydrogen atom, an aliphatic hydrocarbon group having 1 to 8 carbon atoms, or an aromatic group having 1 to 10 carbon atoms. The aliphatic hydrocarbon group and the aromatic group represented by R²², R²³ and R²⁴ may have a substituent. Examples of the aliphatic hydrocarbon group and the aromatic group represented by R²², R²³ and R²⁴ are the same as those represented by R¹¹, R¹², and R¹³ in the formula (1) or (2). R²² and R²³; and R²³ and R²⁴ may be partially bonded and integrated to form a ring structure. Specific examples thereof include a structure in which R²² and R²³ are partially bonded and linked with a cyclic group such as adamantane.

In the formulae (1) and (2), it is preferable that the divalent organic group represented by Z contain an electron-donating atom. That is, it is preferable that the luminescent material according to the embodiment be a transition metal complex including a partial structure represented by the following formula (3) or (4).

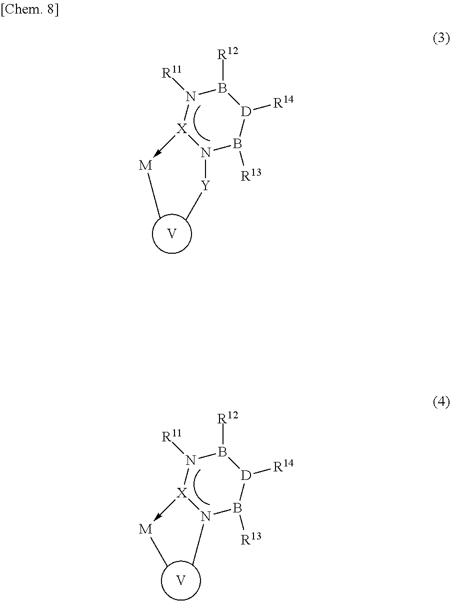

(In the formulae (3) and (4), M represents Ir, Os, or Pt; X represents C or Si; R¹¹, R¹², R¹³, and R¹⁴ each independently represent a monovalent organic group; Y represents a divalent hydrocarbon group; D represents an electron-donating atom; and V represents a divalent organic group having a ring structure.)

In the formulae (3) and (4), specific examples of R¹¹, R¹², R¹³, X, M, V, and Y are the same as above.

Examples of the monovalent organic group represented by R¹⁴ include an aliphatic hydrocarbon group having 1 to 8 carbon atoms, or an aromatic group having 1 to 10 carbon atoms. The aliphatic hydrocarbon group and the aromatic group represented by R¹⁴ may have a substituent.

Examples of the aliphatic hydrocarbon group having 1 to 8 carbon atoms represented by R¹⁴ include a linear, branched, or cyclic aliphatic hydrocarbon group. Specific examples thereof include a methyl group, an ethyl group, an n-propyl group, an isopropyl group, an n-butyl group, a tert-butyl group, an n-pentyl group, an n-hexyl group, an n-heptyl group, an n-octyl group, and a cyclohexyl group. R¹¹ and R¹² may be partially bonded and integrated to form a ring structure.

Examples of the aromatic group having 1 to 10 carbon atoms represented by R¹⁴ include a phenyl group and a naphthyl group, and these aromatic groups may have a substituent.

Specific examples of the electron-donating atom represented by D include C, N, P, O, and S. Among these, C or N is preferable; and N is particularly preferable.

For example, it is preferable that the luminescent material according to the embodiment be a transition metal complex including a partial structure represented by the following formula (5) or (6).

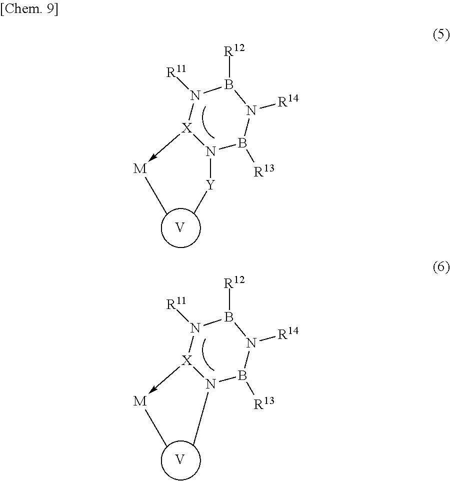

(In the formulae (5) and (6), M represents Ir, Os, or Pt; X represents C or Si; R¹¹, R¹², R¹³, and R¹⁴ each independently represent a monovalent organic group; Y represents a divalent hydrocarbon group; and V represents a divalent organic group having a ring structure.)

In the formulae (5) and (6), specific examples of R¹¹, R¹², R¹³, R¹⁴, X, M, V, and Y are the same as above.

Furthermore, it is preferable that the luminescent material according to the embodiment be a transition metal complex including a partial structure represented by the following formula (7) or (8).

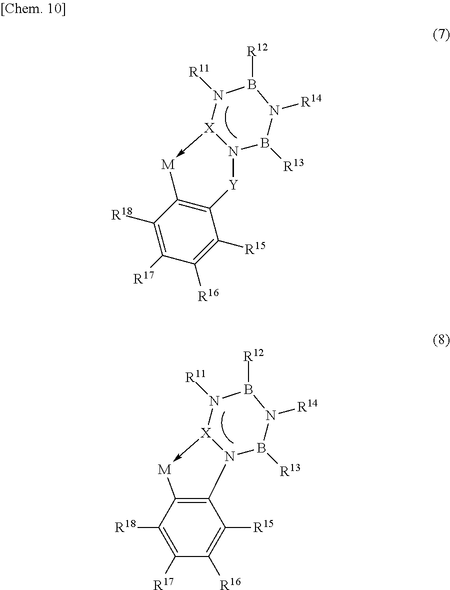

(In the formulae (7) and (8), M represents Ir, Os, or Pt; X represents C or Si; R¹¹, R¹², R¹³, R¹⁴, R¹⁵, R¹⁶, R¹⁷, and R¹⁸ each independently represent a monovalent organic group; and Y represents a divalent hydrocarbon group.)

In the formulae (7) and (8), specific examples of R¹¹, R¹², R¹³, R¹⁴, R¹⁵, R¹⁶, R¹⁷, R¹⁸, X, M, and Y are the same as above.

In addition, for example, it is particularly preferable that the luminescent material according to the embodiment be an Ir complex including a partial structure represented by the following formula (9).

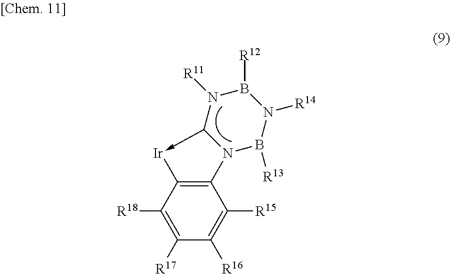

(In the formula (9), R¹¹, R¹², R¹³, R¹⁴, R¹⁵, R¹⁶, R¹⁷, and R¹⁸ each independently represent a monovalent organic group)

In the formula (9), specific examples of R¹¹, R¹², R¹³, R¹⁴, R¹⁵, R¹⁶, R¹⁷, and R¹⁸ are the same as above.

In addition, it is preferable that, when a central metal is any one of Ir and Os, the luminescent material according to the embodiment be a tris complex in which three bidentate ligands are coordinated. In this case, as geometric isomers, a mer (meridional) isomer or a fac isomer (facial) may be present. In the luminescent material according to the embodiment, either or both of a mer isomer and a fac isomer may be present. Among these, as described below in Examples, it is preferable that the amount of a mer isomer contained in the transition metal complex be greater than that of a fac isomer, from the viewpoint of improving the PL quantum yield.

Hereinafter, preferable examples of a transition metal complex which is the luminescent material according to the embodiment, but the embodiment is not limited thereto. In the following examples, geometric isomers are not particularly distinguished, and the luminescent material according the embodiment may contain both geometric isomers. In addition, in the following structural formulae, Ph represents a phenyl group.

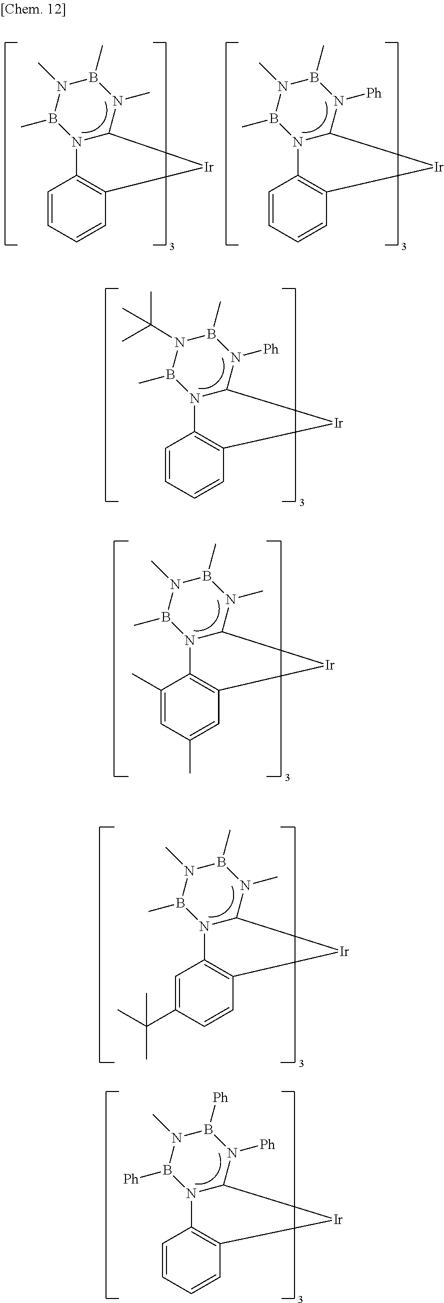

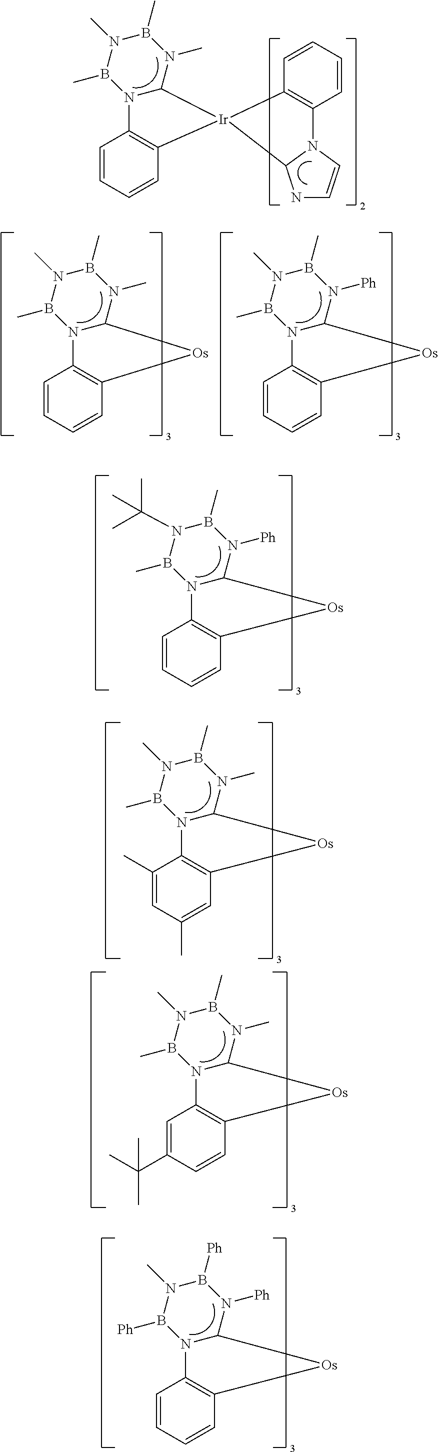

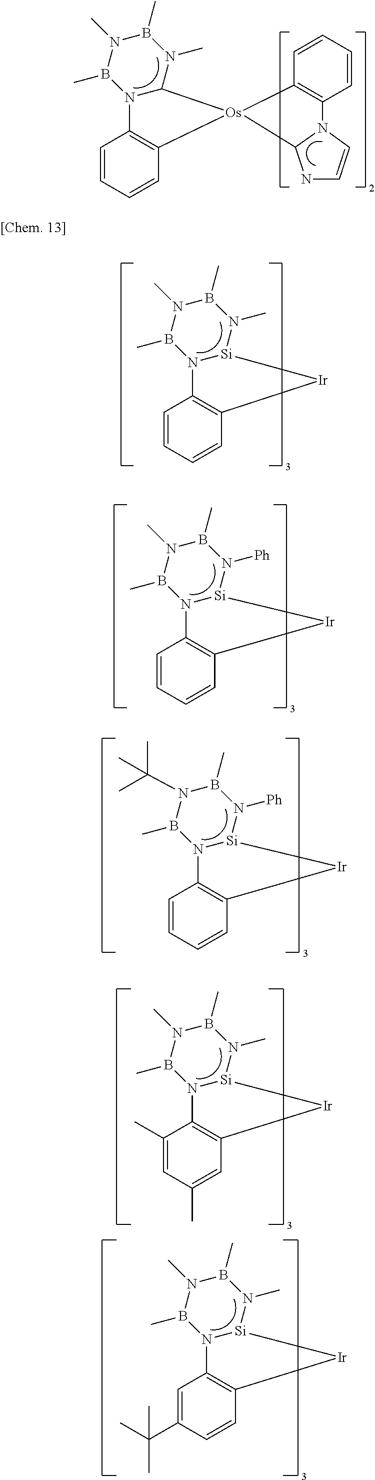

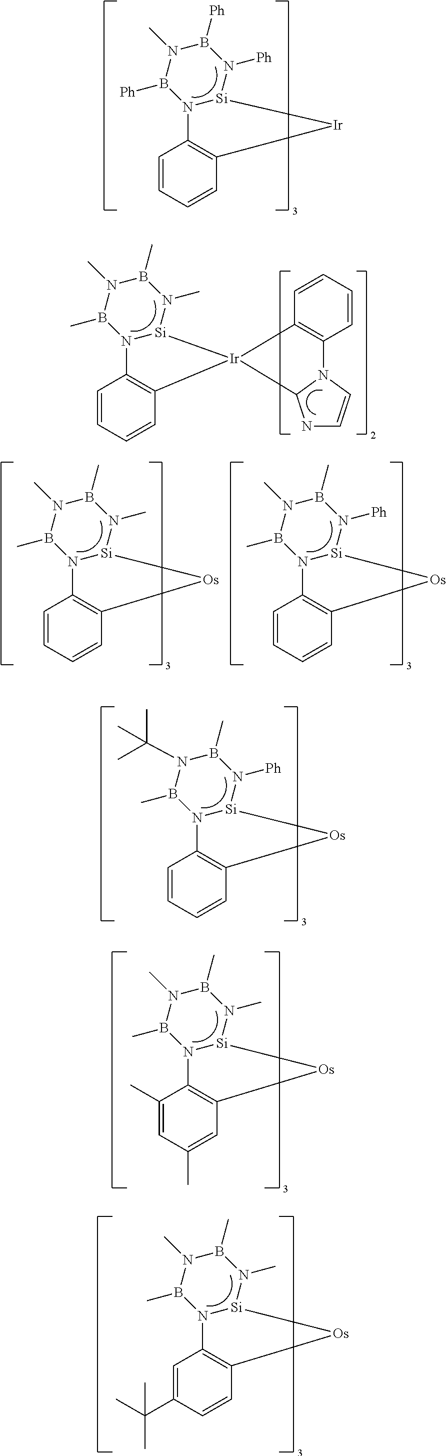

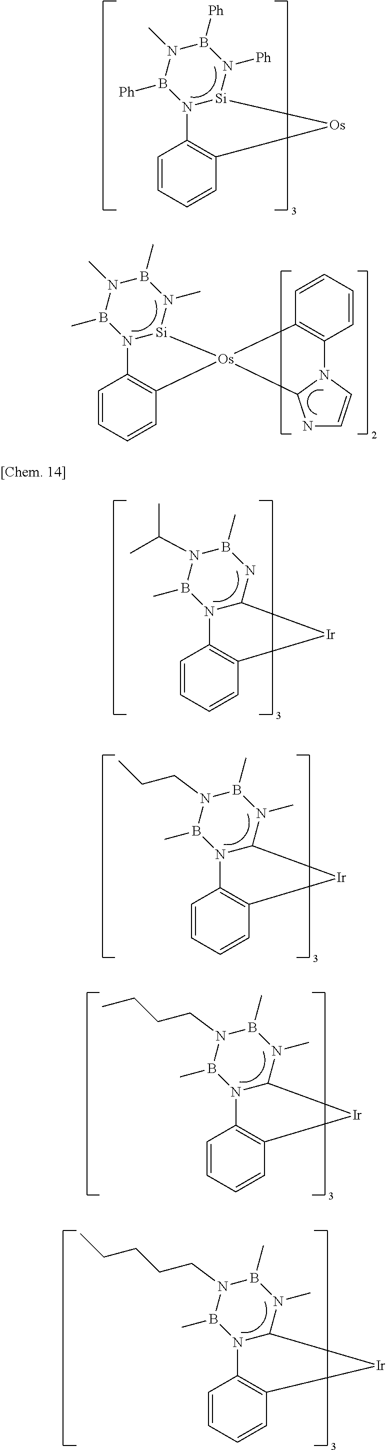

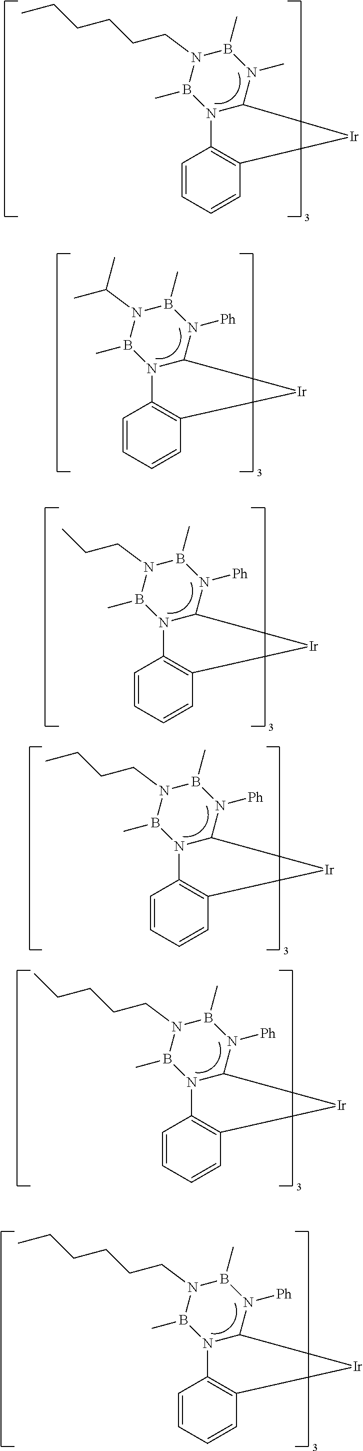

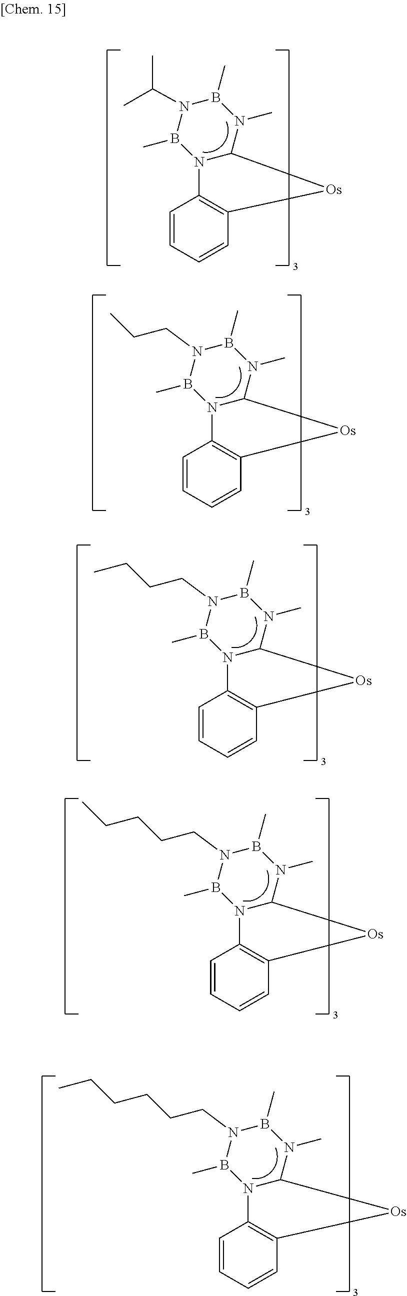

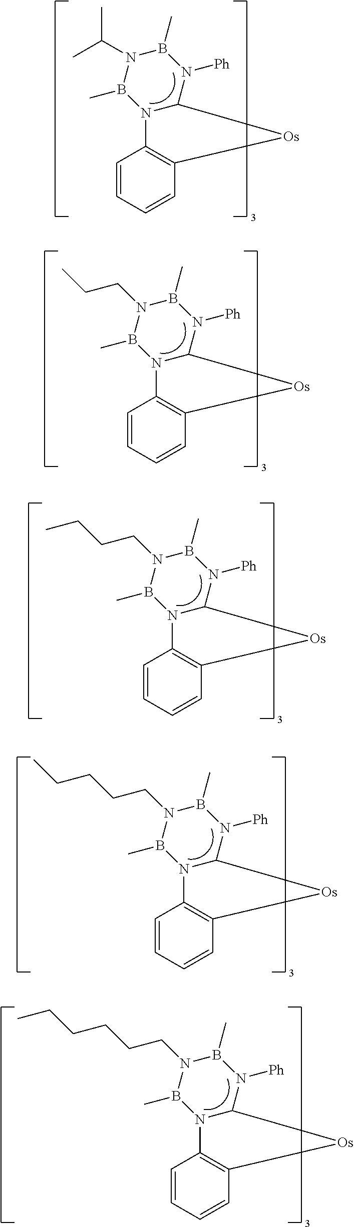

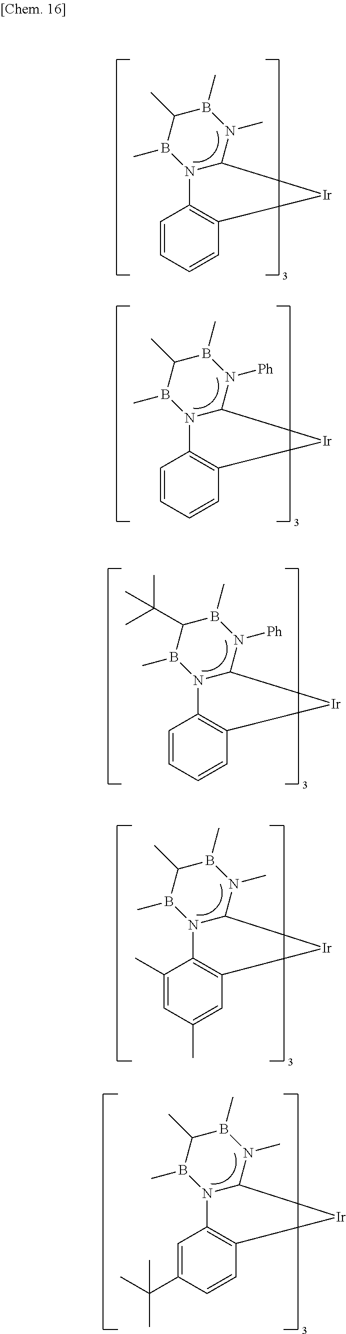

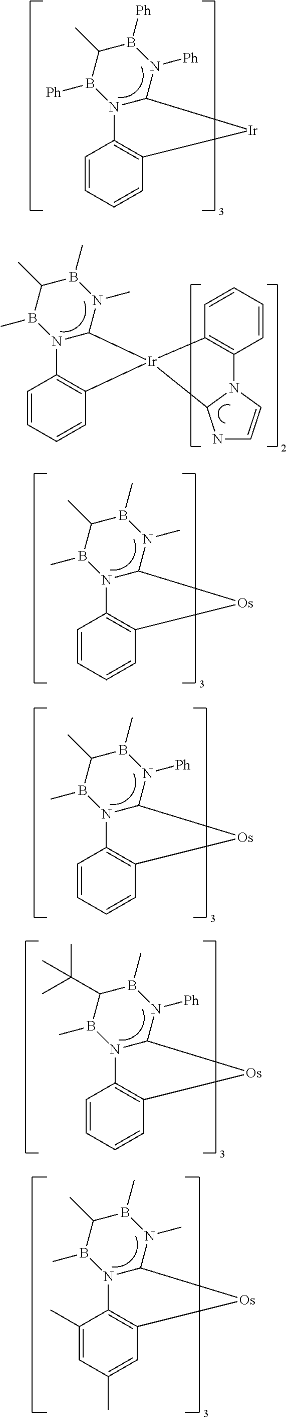

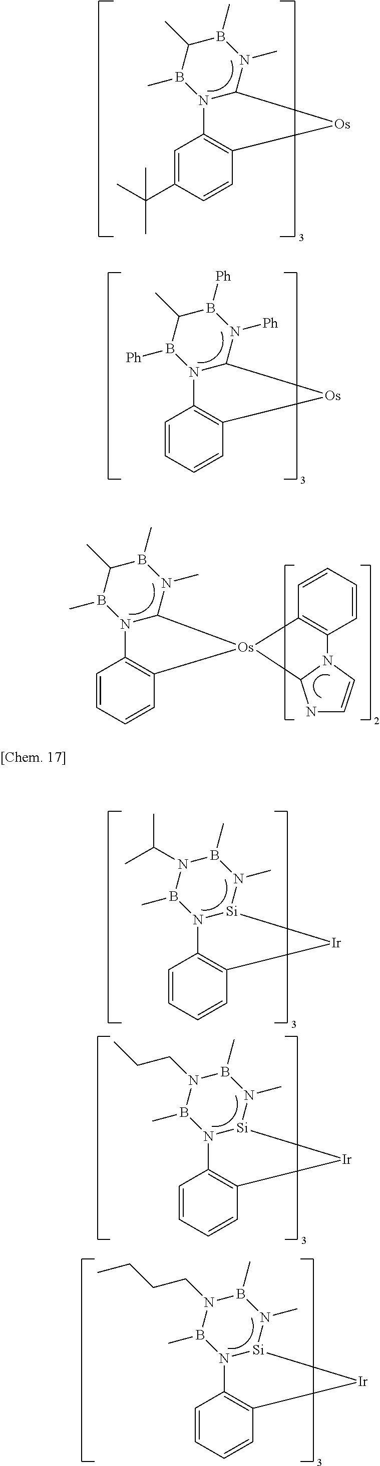

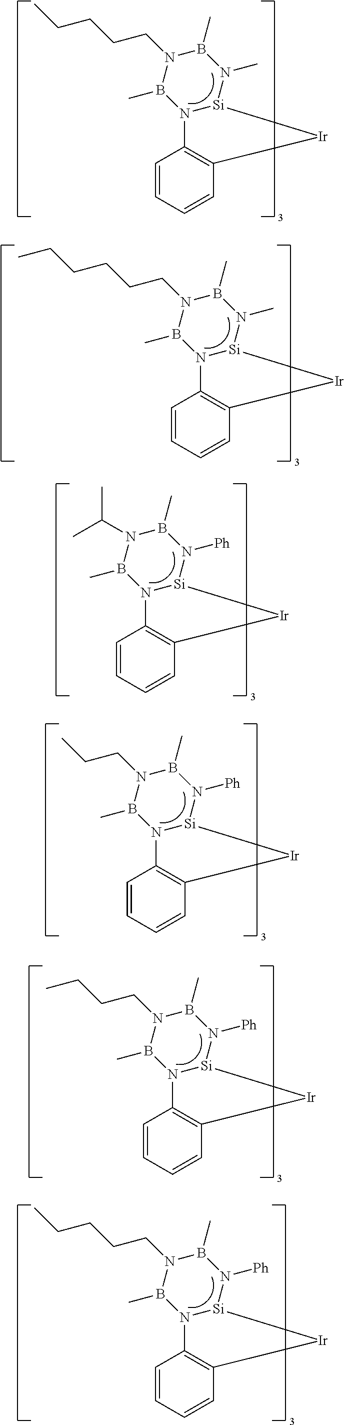

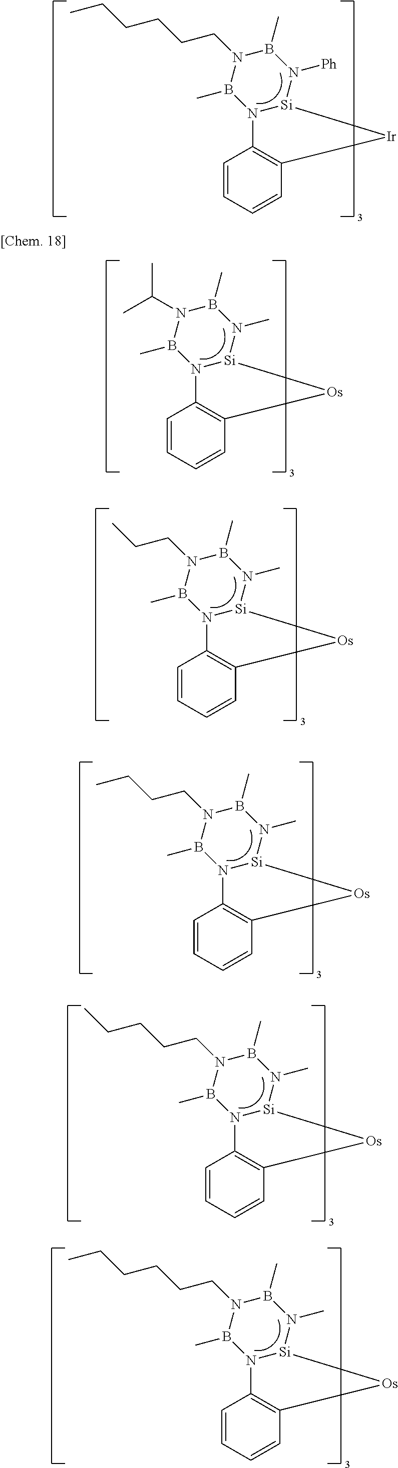

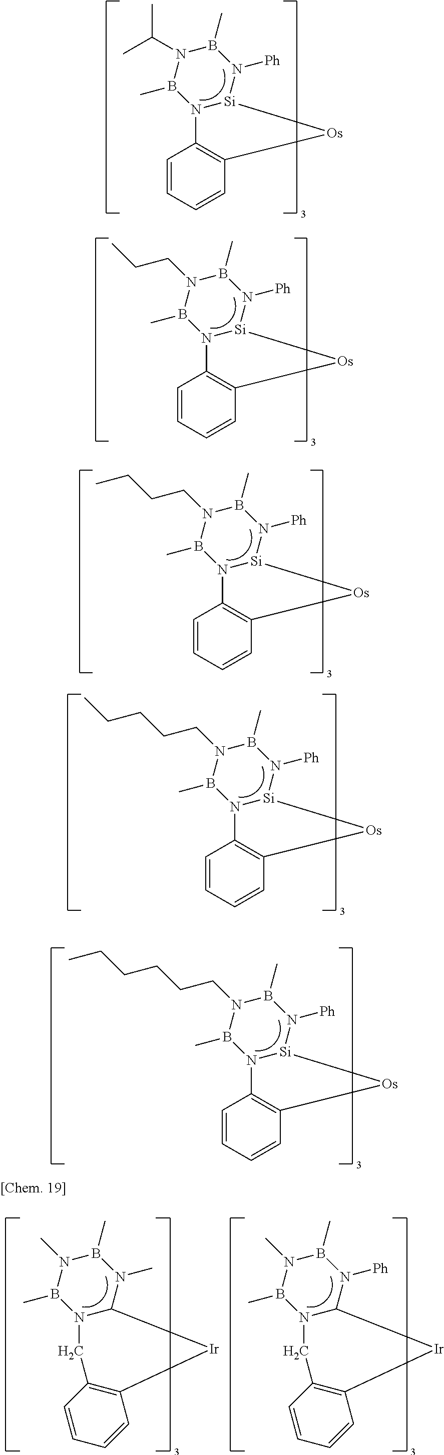

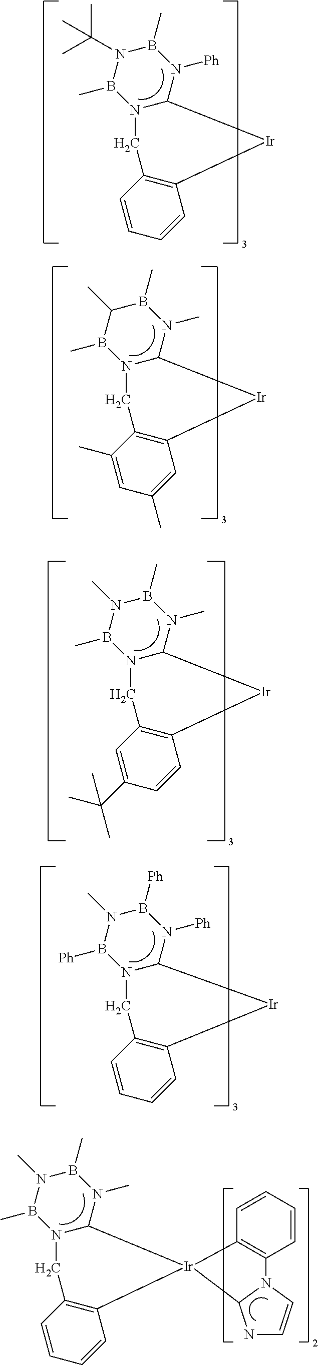

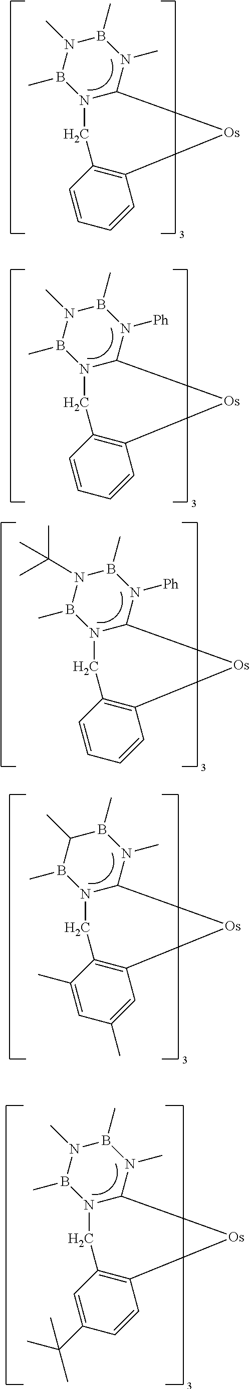

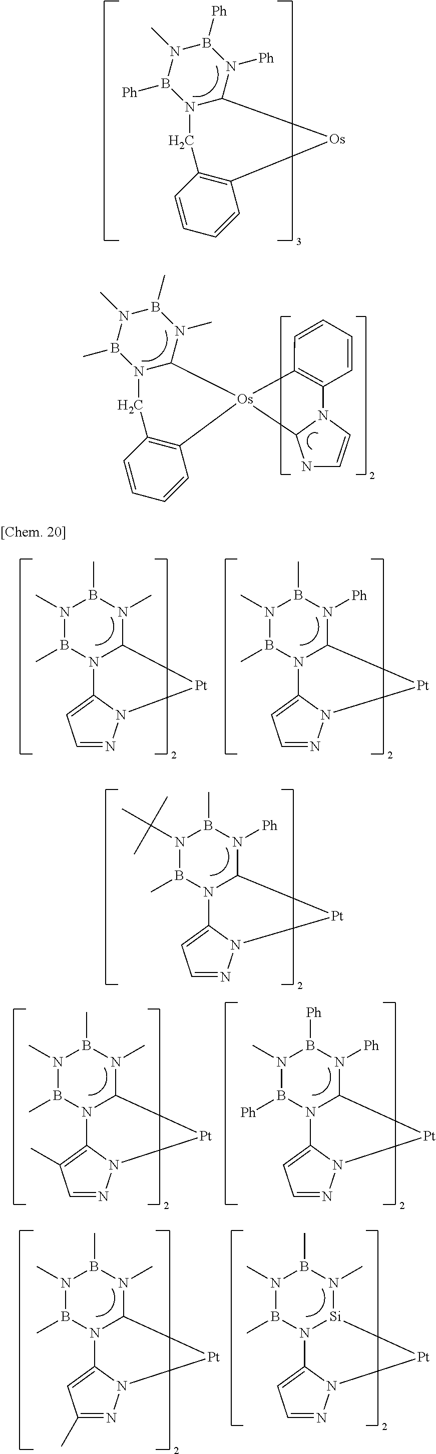

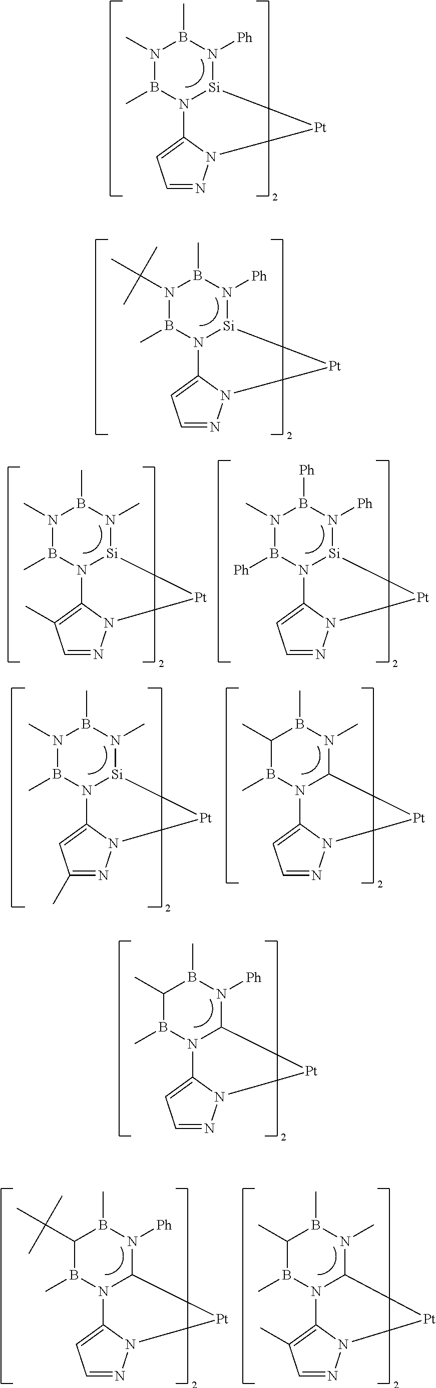

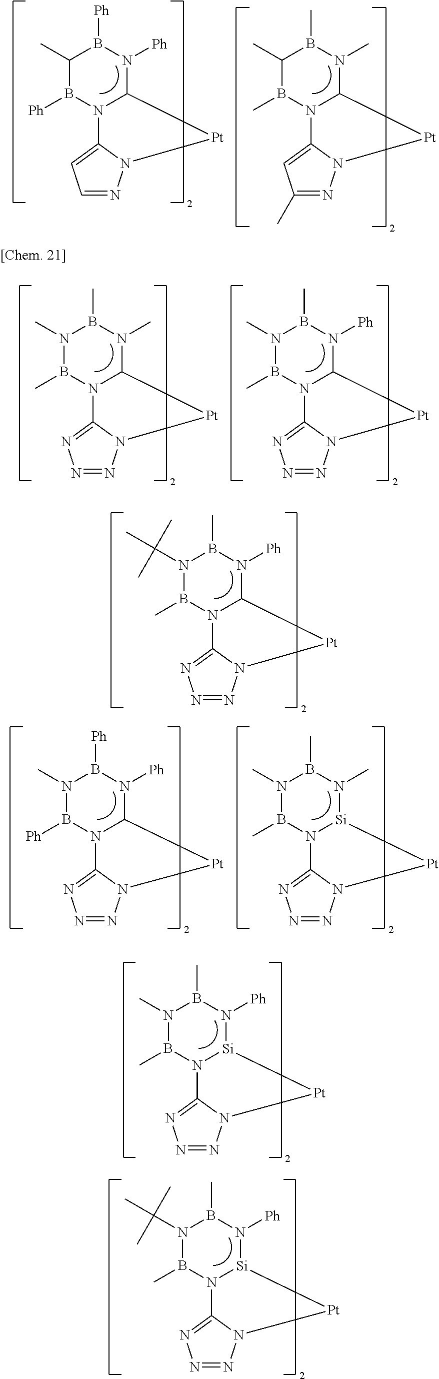

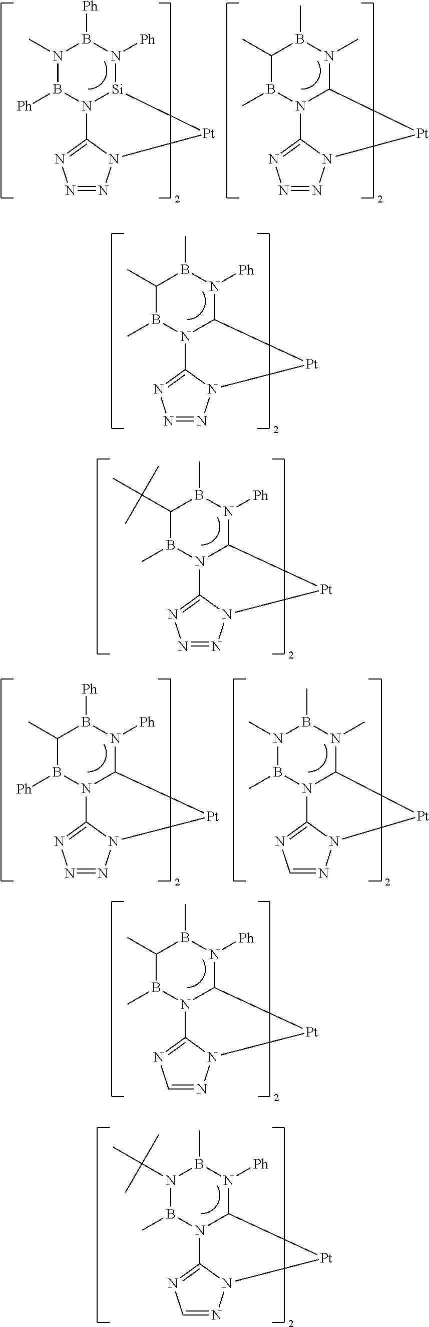

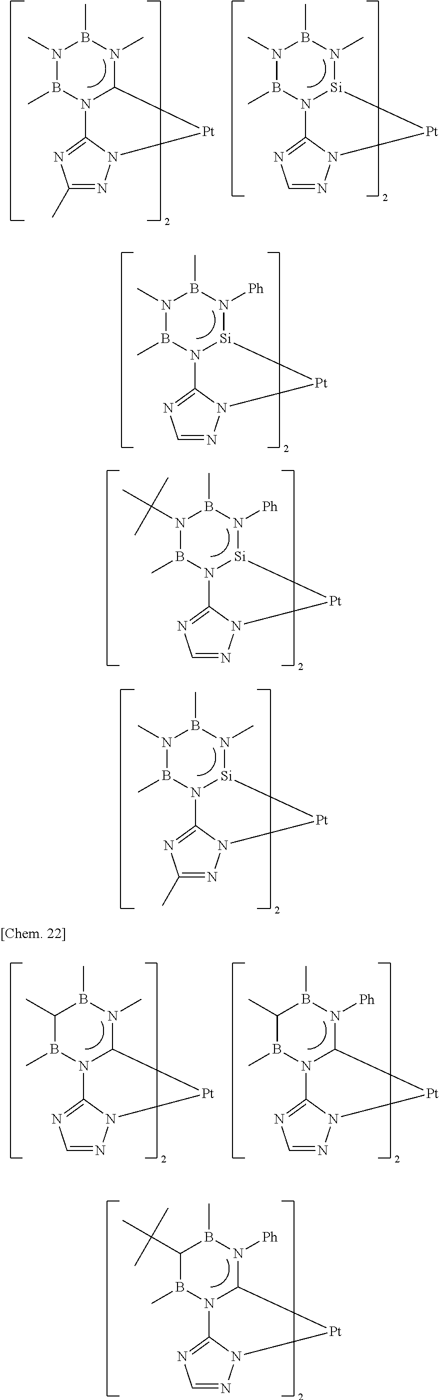

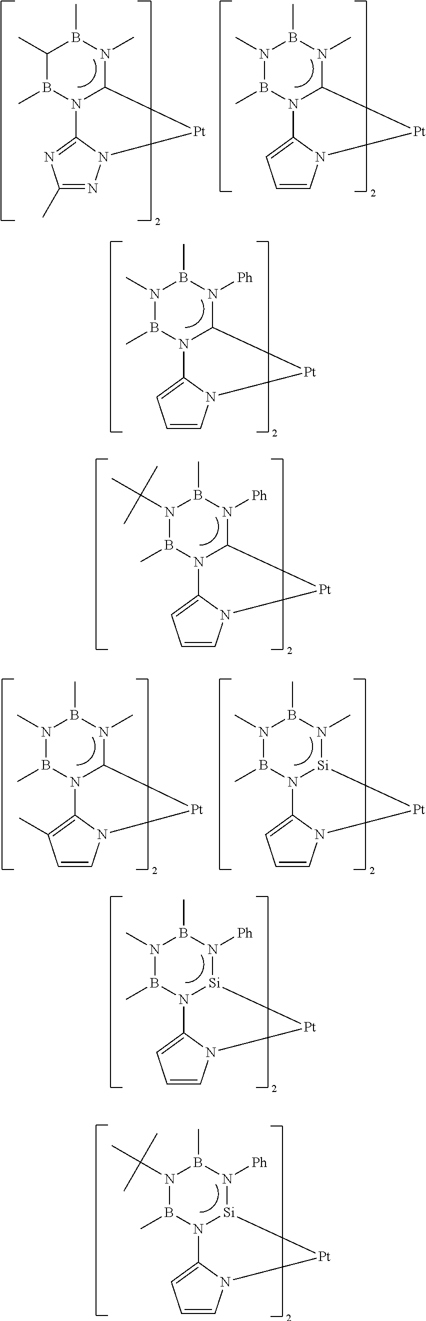

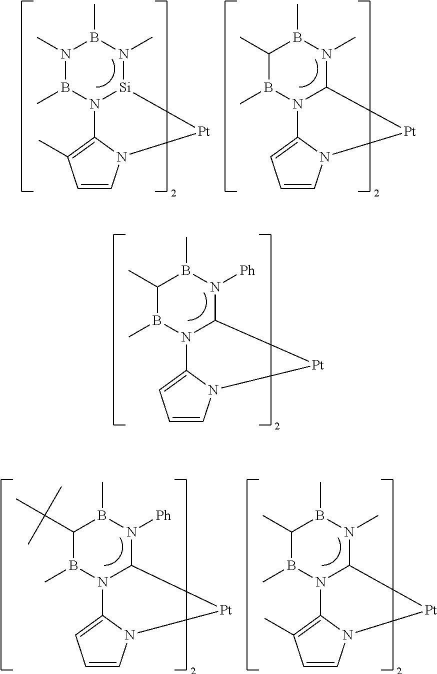

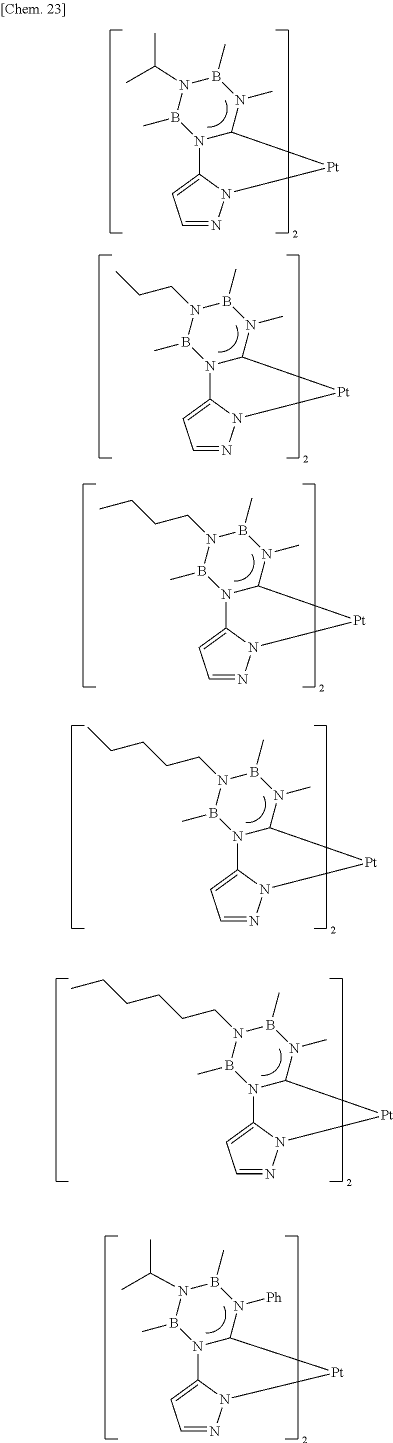

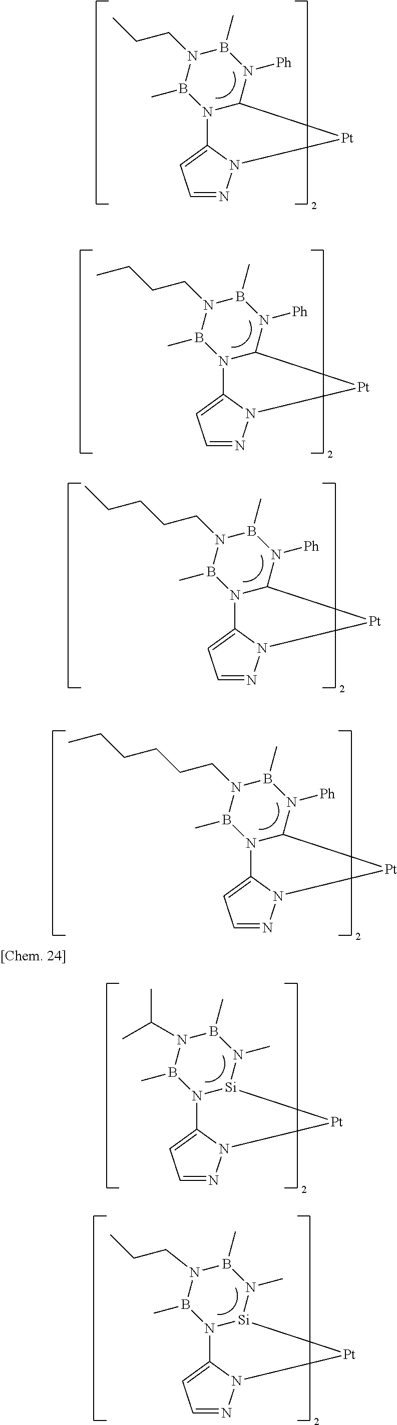

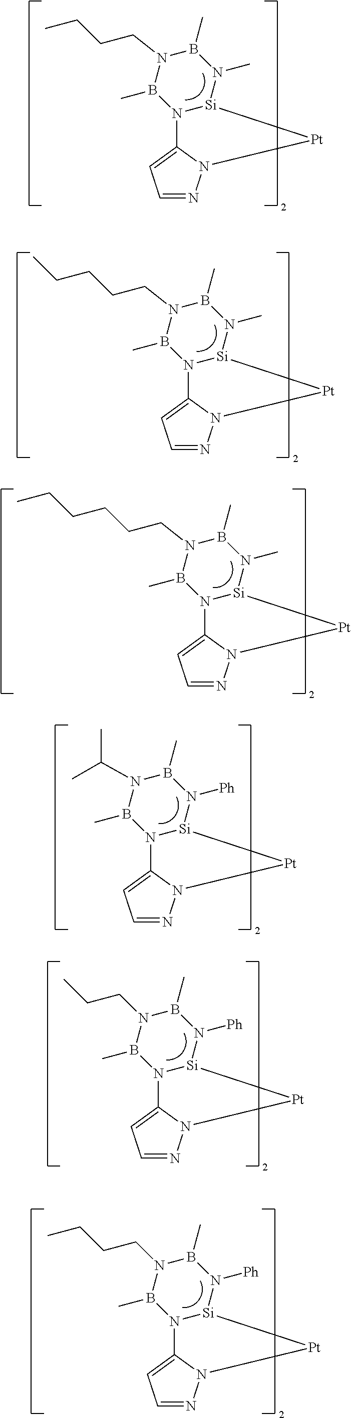

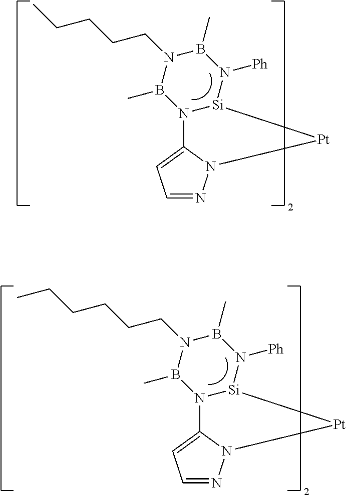

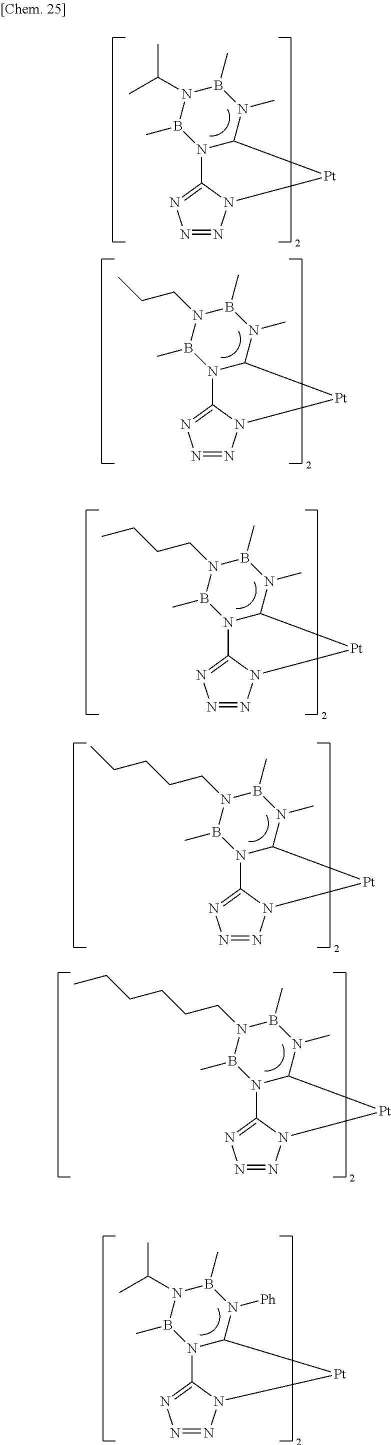

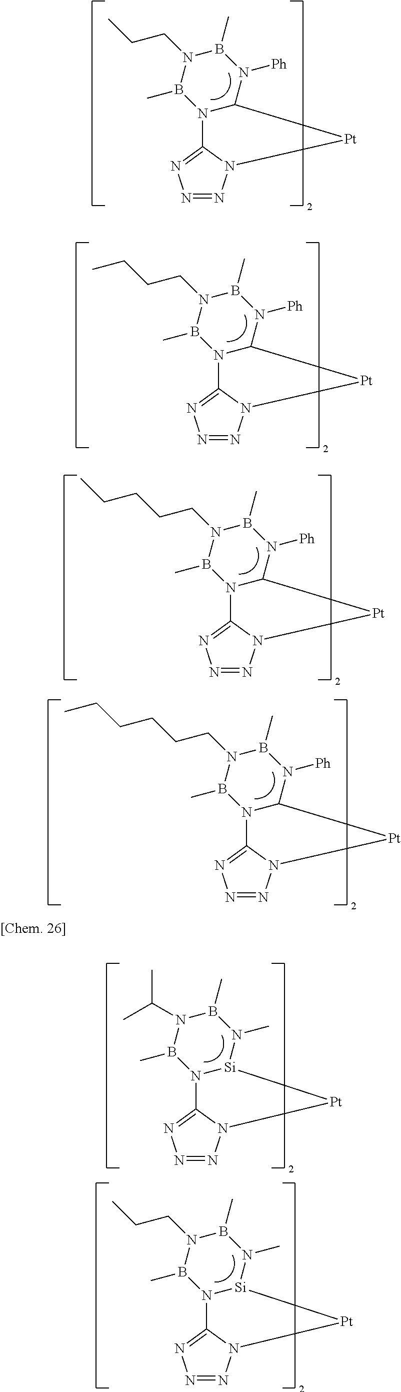

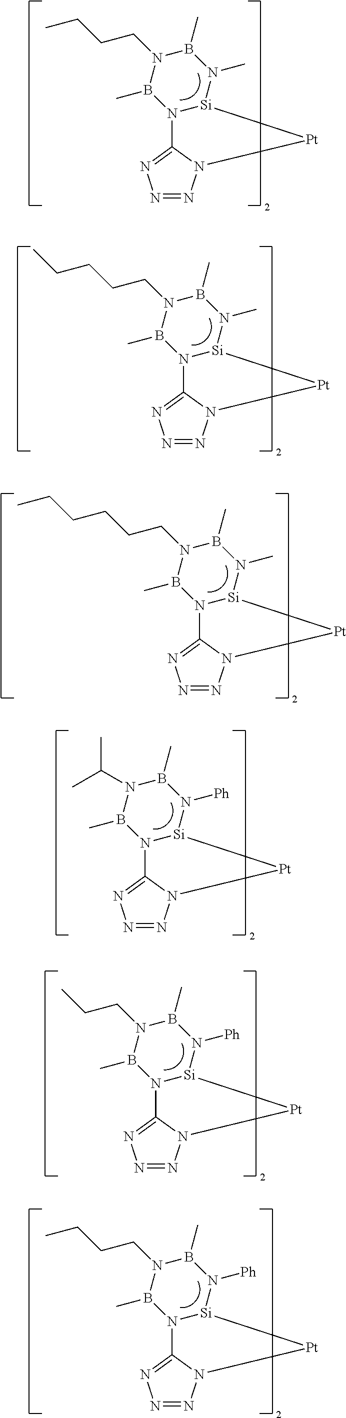

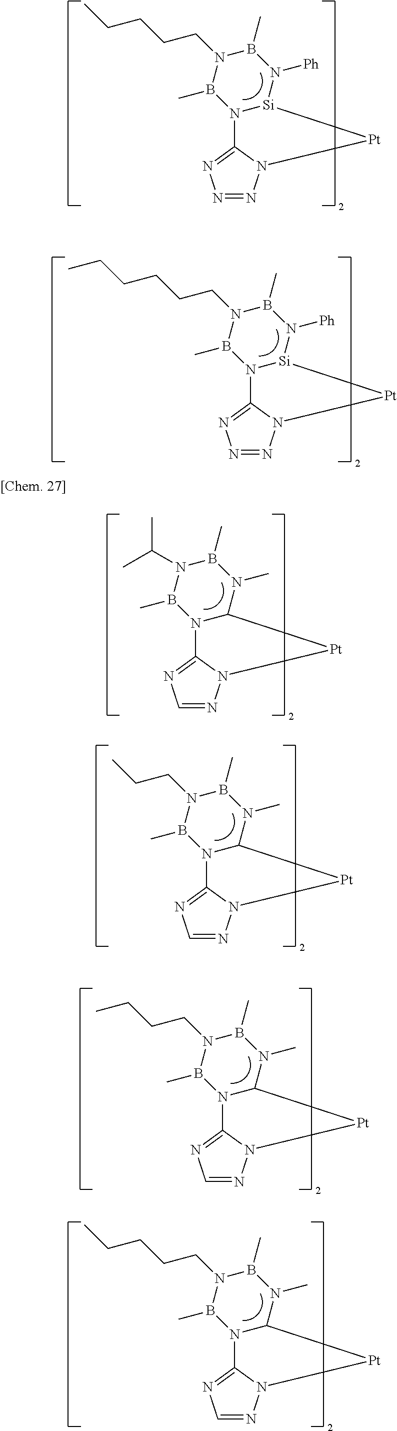

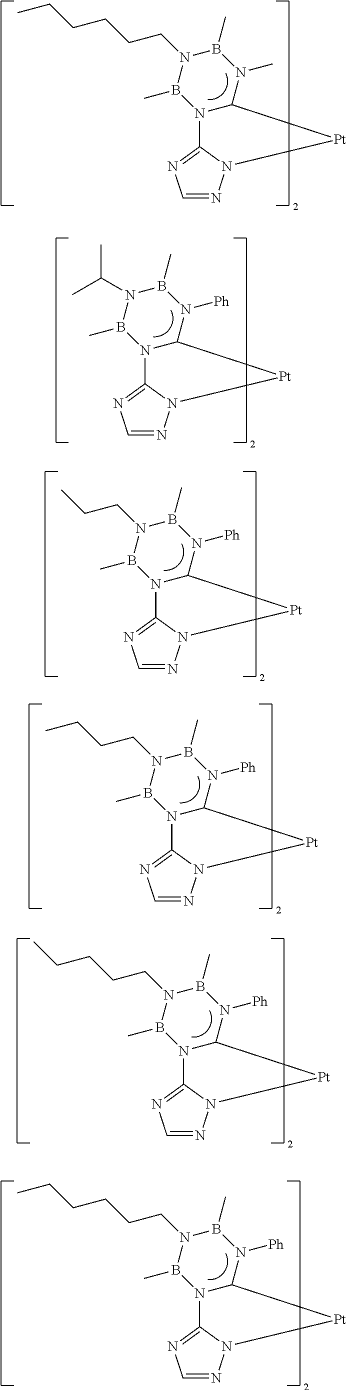

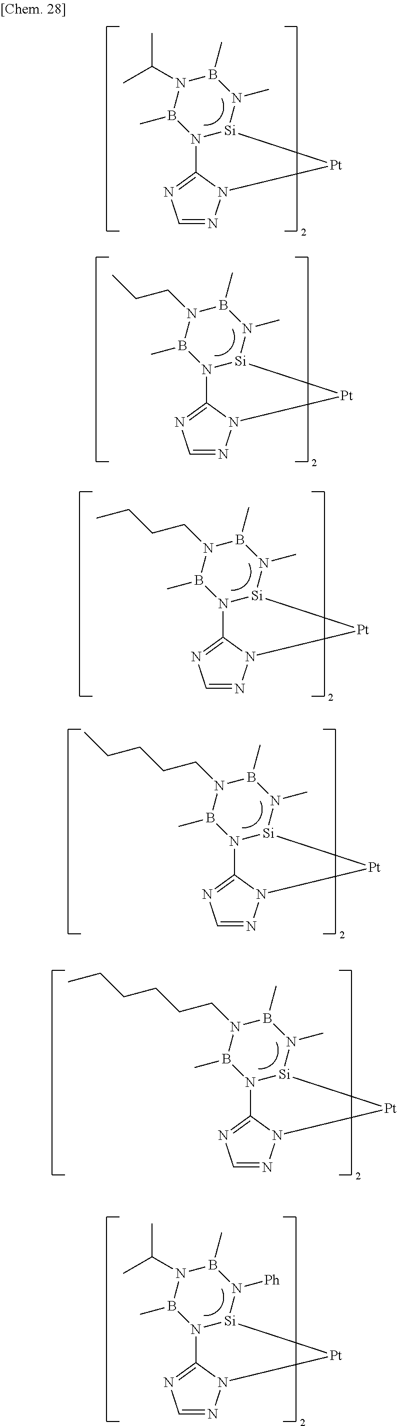

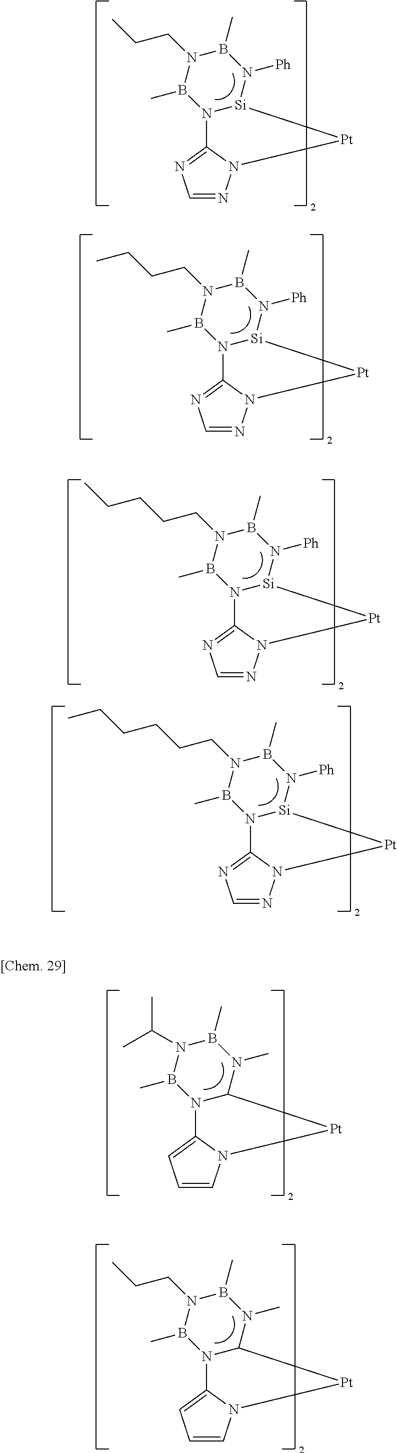

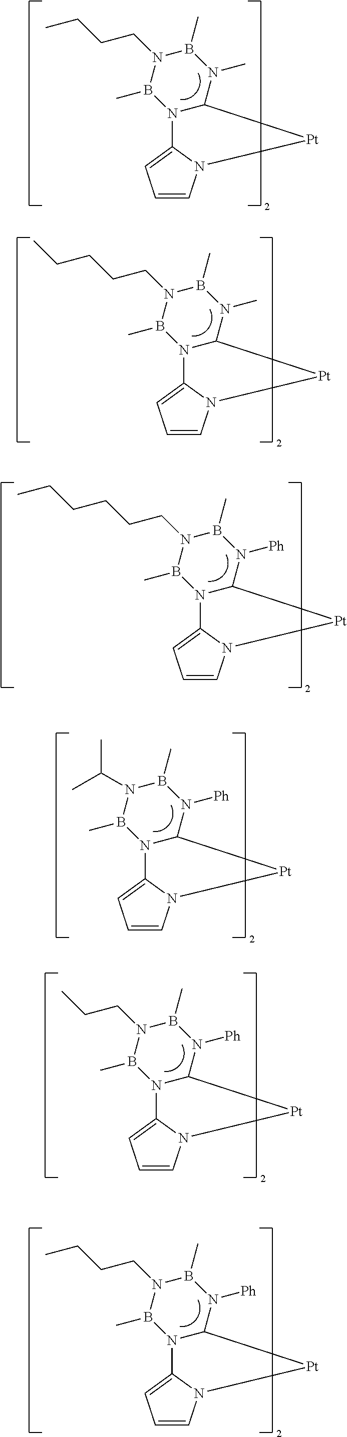

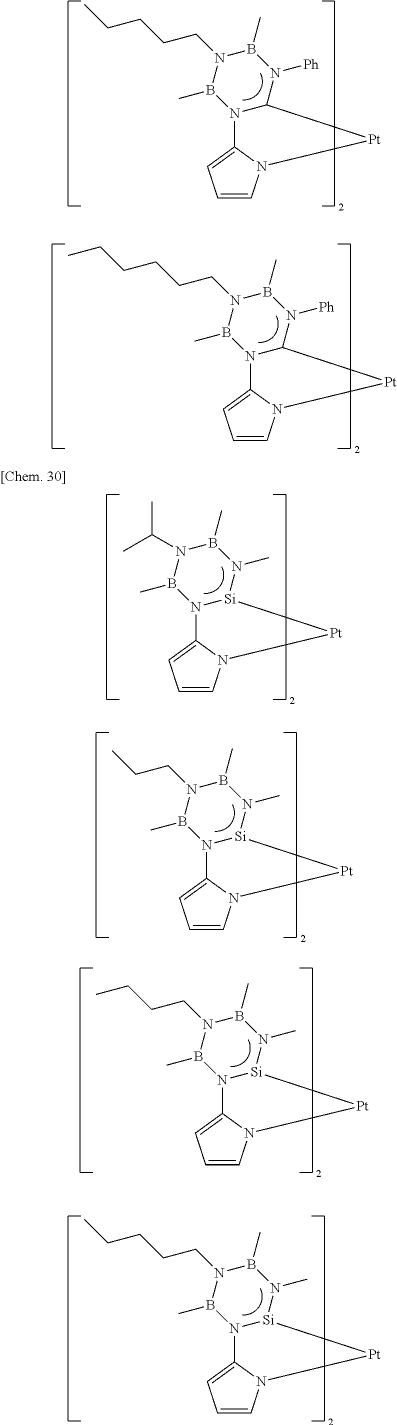

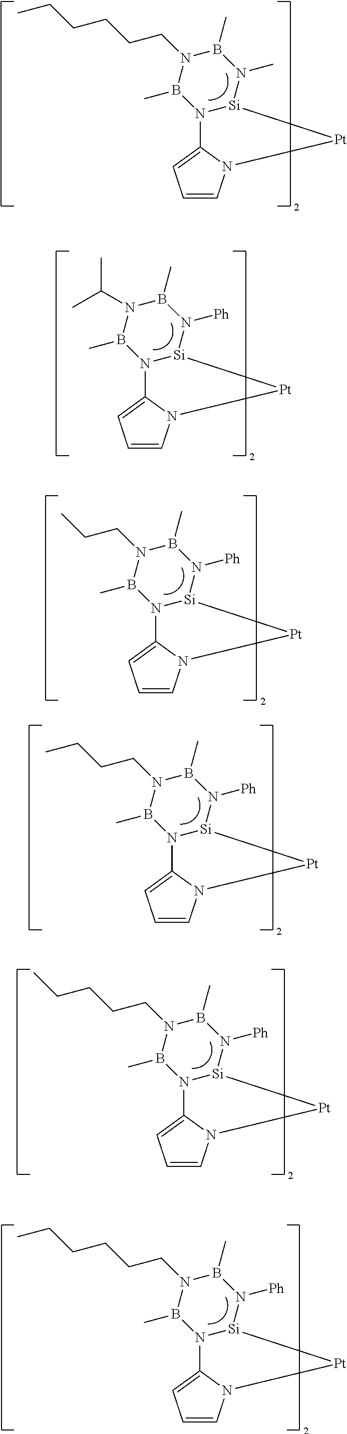

Among the above examples of the transition metal complex, the following compounds are particularly preferable as the luminescent material according to the embodiment.

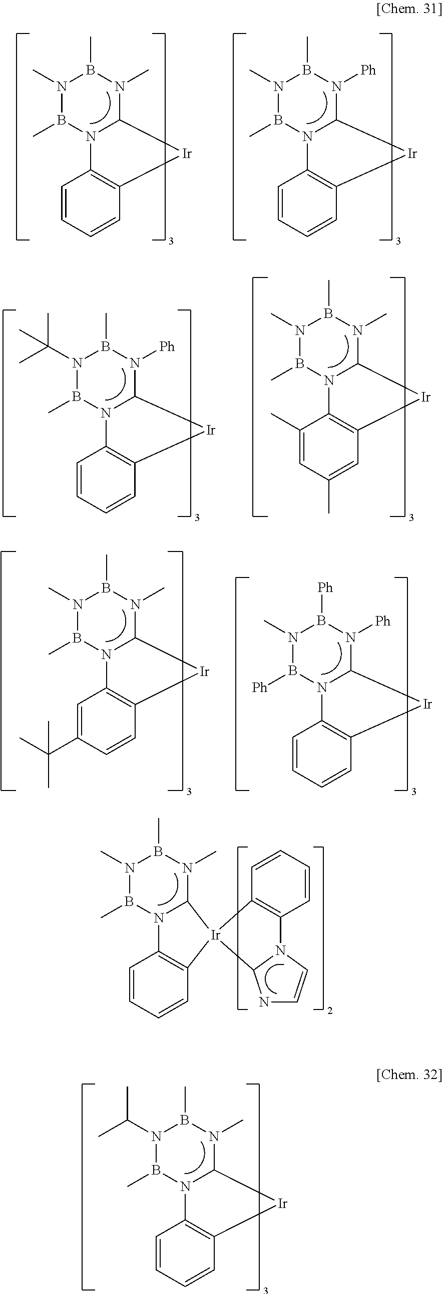

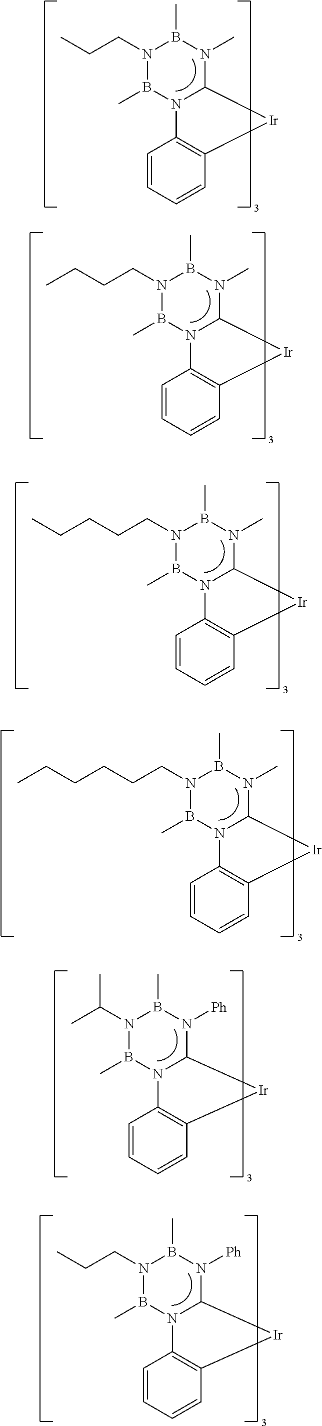

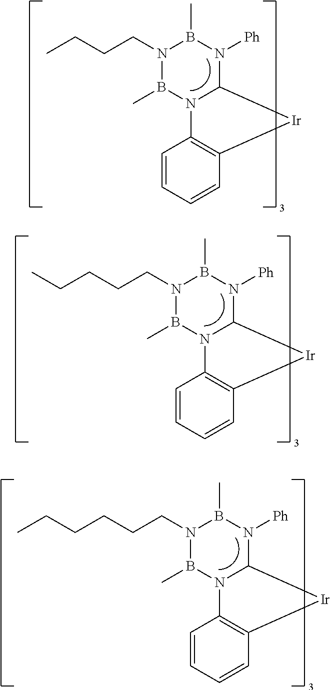

It is generally known that, when a transition metal complex is expected as a highly efficient phosphorescent luminescent material, MLCT (Metal-to-Ligand Charge Transfer) is used as an emission mechanism. At this time, a heavy atom effect of a central metal works effectively on a ligand, and intersystem crossing (transition from the first excited state to the triplet excited state, S-T: approximately 100%) occurs rapidly. Then, similarly, due to a heavy atom effect, the transition rate constant (kᵣ) from T₁ to S₀ is increased. As a result, the PL quantum yield (φ_{PL}=kᵣ/(kₙᵣ+kᵣ); wherein kₙᵣ represents the rate constant of being thermally deactivated from T₁ to S₀) is increased. The increase in PL quantum yield leads to an increase in the luminous efficiency of an organic electronic device. The luminescent material according to the embodiment is the transition metal complex which includes, as a central metal, Ir, Os, or Pt. In Ir, Os, or Pt, the atomic radius is relatively short due to lanthanide contraction, whereas the atomic weight is great. Therefore, the above-described heavy atom effect can be effectively exhibited. Accordingly, in the luminescent material according to the embodiment, the PL quantum yield is increased due to the heavy atom effect and a high luminous effect can be exhibited.

In addition, the luminescent material according to the embodiment is the transition metal complex which includes at least one carbene ligand or silylene ligand including a boron atom in a structure thereof.

In particular, when a ligand which includes a carbene structure including a boron atom is used for a metal complex, as described below in Examples, a result of emitting light with a high efficiency can be obtained. A boron atom has a high Lewis acid strength, an empty p orbital, and a strong electron-accepting property. In addition, it is known that, when N and B are bonded in a carbene structure, similar characteristics to those of a C═C bond are exhibited. It is considered that the emission mechanism using MLCT becomes predominant and the luminous efficiency is improved by increasing charge localization, generating an electron-rich state, and forming at least one aromatic ring (in which a ring current effect is obtained and electrons are easily moved) at a carbene position.

In addition, it is preferable that the luminescent material according to the embodiment have a structure, which can donate an electron to a metal center and does not satisfy the octet rule as in the case of carbene, as a transition metal complex. When the luminescent material does not satisfy the octet rule, the electron-donating property is high, the electron-donating property to a metal center is increased, and the electron density of an original metal position in MLCT can be increased. As a result, the MLCT ratio can be increased. Therefore, in addition to a carbene complex, it is particularly preferable that the luminescent material have a silylene (Si) complex from the viewpoint of strong σ donor property.

The luminescent material according to the embodiment realizes highly efficient blue light emission even when the luminescent material does not contain an electron-attracting group which is normally required.

Next, a synthesis method of the transition metal complex which is the luminescent material according to the embodiment will be described. The transition metal complex having a partial structure represented by any one of the formulae (1) to (9) can be synthesized in a combination of well-known methods. For example, a ligand can be synthesized referring to, for example, J. Am. Chem. Soc., 2005, 127, 10182; Eur. J. Inorg. Chem., 1999, 1765; J. Am. Chem. Soc., 2004, 126, 10198; Synthesis, 1986, 4, 288; Chem. Ber., 1992, 125, 389; and J. Organometal. Chem., 11 (1968), 399. The transition metal complex can be synthesized referring to, for example, Dalton Trans., 2008, 916, Angew. Chem. Int. Ed., 2008, 47, 4542.

Hereinafter, as an example of a synthesis method of a metal transition complex which is the luminescent material according to the embodiment, a synthesis method of a transition metal complex including a partial structure of a carbene ligand (X═C, M=Ir) represented by the formula (8) will be described. An Ir complex (Compound (a-5)) includings a partial structure of a carbene ligand (X═C) represented by the formula (8) can be synthesized according to the following synthesis route.

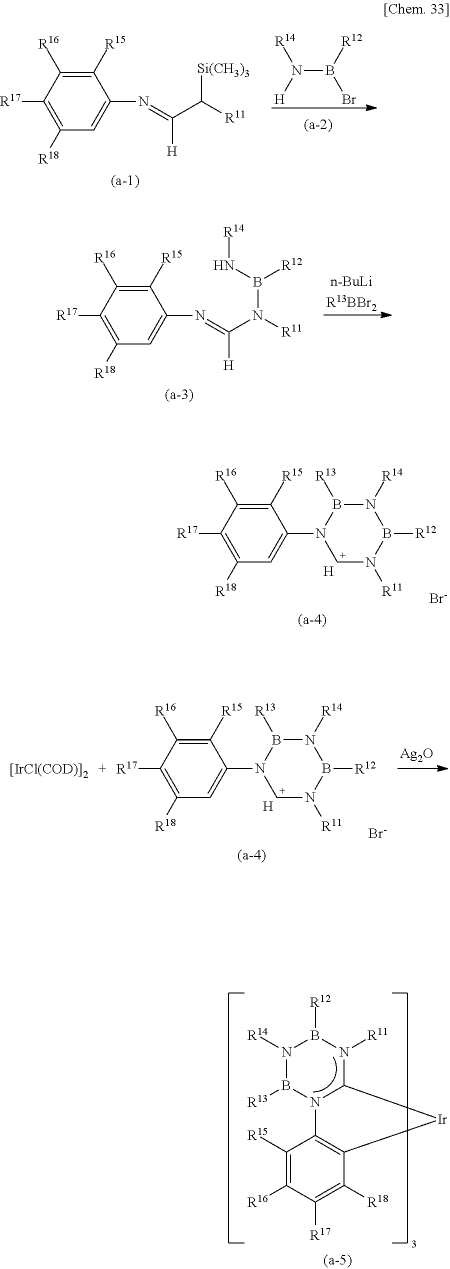

Compound (a-4) which is a ligand can be synthesized referring to, for example, J. Am. Chem. Soc., 2005, 127, 10182 and Eur. J. Inorg. Chem., 1999, 1765. First, Compound (a-1) and Compound (a-2) are caused to react with each other in a toluene solution at −78° C., followed by heating to room temperature. As a result, Compound (a-3) can be synthesized. Next, an n-butyllithium solution is added dropwise to Compound (a-3) at 0° C., followed by cooling to −100° C. Then, a dibromoborane compound having a desired ligand R¹³ is added thereto, followed by slow heating to room temperature. As a result, Compound (a-4) can be synthesized.

Compound (a-5) which is a transition metal complex can be synthesized referring to, for example, Dalton Trans., 2008, 916. 6 equivalents of Compound (a-4) are added to 1 equivalent of [IrCl(COD)]₂ (COD=1,5-cyclooctadiene) and silver oxide is further added thereto, followed by heating to reflux. As a result, Compound (a-5) can be synthesized. In the case of a trix complex such as Compound (a-5), a mer isomer or a fac isomer which is a geometric isomer may be present. These geometric isomers can be separated with a method such as recrystallization.

In addition, when the luminescent material according to the embodiment contains two different kinds of ligands, a metal transition complex can be synthesized referring to, for example, Angew. Chem. Int. Ed., 2008, 47, 4542. For example, when an Ir complex [Ir(La)₂(Lb)] having two bidentate ligands La and one bidentate ligand Lb is synthesized, 1 equivalent of [IrCl(COD)]₂ and 4 equivalents of the ligand La are heated to reflux in an alcohol solution in the presence of sodium methoxide according to a method described in, for example, Dalton Trans., 2008, 916. As a result, a chlorine bridged dinuclear iridium complex [Ir(μ—Cl)(La)₂]₂ is synthesized. This chlorine-bridged dinuclear iridium complex is caused to react with the ligand Lb. As a result, the Ir complex [Ir(La)₂(Lb)] can be synthesized. When either the ligand La or the ligand Lb is a carbene ligand or a silylene ligand, or when both the ligand La and the ligand Lb are a carbene ligand or a silylene ligand, this synthesis method can be applied.

The synthesized transition metal complex which is a luminescent material can be identified using MS spectrum (FAB-MS), ¹H-NMR spectrum, LC-MS spectrum, or the like.

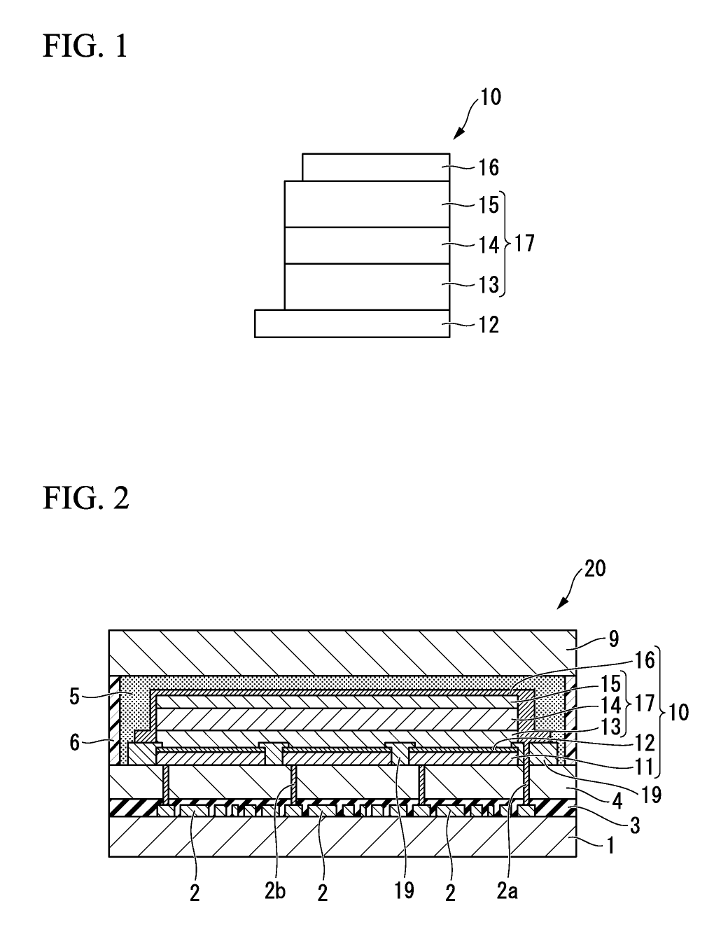

Hereinafter, embodiments of an organic light-emitting element, a wavelength-converting light-emitting element, an organic laser diode element, a dye laser, a display device, and an illumination device according to embodiments of the present invention will be described referring to the drawings. In the respective drawings of FIGS. 1 to 10, the reduction scales of the respective members are different from each other so as to make the sizes of the respective members recognizable in the drawings.

### <Organic Light-Emitting Element>

An organic light-emitting element (organic EL element) according to an embodiment of the present invention includes at least one organic layer that includes a light-emitting layer; and a pair of electrodes between which the organic layer is interposed.

FIG. 1 is a diagram schematically illustrating a first embodiment of the organic light-emitting element according to the embodiment. An organic light-emitting 10 illustrated in FIG. 1 has a configuration in which a first electrode 12, an organic EL layer (organic layer) 17, and a second electrode 16 are laminated in this order on a substrate (not illustrated). In an example of FIG. 1, the organic EL layer 17 that is interposed between the first electrode 12 and the second electrode 16 has a configuration in which a hole transport layer 13, an organic light-emitting layer 14, and an electron transport layer 15 are laminated in this order.

The first electrode 12 and the second electrode 16 functions as an anode or a cathode of the organic light-emitting element 10 as a pair. That is, when the first electrode 12 is an anode, the second electrode 16 is a cathode; and when the first electrode 12 is a cathode, the second electrode 16 is an anode. In FIG. 1 and the following description, a case in which the first electrode 12 is an anode and the second electrode 16 is a cathode will be described as an example. When the first electrode 12 is a cathode and the second electrode 16 is an anode, as described below, the organic EL layer (organic layer) 17 may have a lamination structure in which a hole injection layer and a hole transport layer are disposed on the second electrode 16 side; and an electron injection layer and an electron transport layer are disposed on the first electrode 12 side.

The organic EL layer (organic layer) 17 may have a single-layer structure including the organic light-emitting layer 14; and may have a multilayer structure such as the lamination structure illustrated in FIG. 1 including the hole transport layer 13, the organic light-emitting layer 14, and the electron transport 15. Specific configuration examples of the organic EL layer (organic layer) 17 are as follows. However, the embodiment is not limited thereto. In the following configurations, a hole injection layer and the hole transport layer 13 are disposed on the first electrode 12 side which is an anode; and an electron injection layer and the electron transport layer 15 are disposed on the second electrode 16 side which is a cathode.

(1) Organic light-emitting Layer 14
(2) Hole transport layer 13/Organic light-emitting layer 14
(3) Organic light-emitting layer 14/Electron transport layer 15
(4) Hole injection layer/Organic light-emitting layer 14
(5) Hole transport layer 13/Organic light-emitting layer 14/Electron transport layer 15
(6) Hole injection layer/Hole transport layer 13/Organic light-emitting layer 14/Electron transport layer 15
(7) Hole injection layer/Hole transport layer 13/Organic light-emitting layer 14/Electron transport layer 15/Electron injection layer
(8) Hole injection layer/Hole transport layer 13/Organic light-emitting layer 14/Hole blocking layer/Electron transport layer 15
(9) Hole injection layer/Hole transport layer 13/Organic light-emitting layer 14/Hole blocking layer/Electron transport layer 15/Electron injection layer
(10) Hole injection layer/Hole transport layer 13/Electron blocking layer/Organic light-emitting layer 14/Hole blocking layer/Electron transport layer 15/Electron injection layer

Here, each layer of the organic light-emitting layer 14, the hole injection layer, the hole transport layer 13, the hole blocking layer, the electron blocking layer, the electron transport layer 15, and the electron injection layer may have a single-layer structure or a multilayer structure.

The organic light-emitting layer 14 may be formed of only the above-described luminescent material according to the embodiment. The organic light-emitting layer 14 may be formed of a combination of the luminescent material according to the embodiment, which is a dopant, and a host material; may further contain a hole transport material, an electron transport material, and an additive (for example, a donor or an acceptor) as necessary; and may have a configuration in which the above-described materials are dispersed in a polymer material (binder resin) or in an inorganic material. From the viewpoints of luminous efficiency and lifetime, it is preferable that the luminescent material according to the embodiment, which is a light-emitting dopant, be dispersed in a host material. The organic light-emitting layer 14 recombines holes injected from the first electrode 12 with electrons injected from the second electrode 16 and discharges (emits) light using phosphorescent emission of the luminescent material according to the embodiment contained in the organic light-emitting layer 14.

When the organic light-emitting layer 14 is formed of a combination of the luminescent material according to the embodiment, which is a light-emitting dopant, and a host material, a well-known host material for organic EL of the related art can be used as the host material. Examples of such a host material include carbazole derivatives such as 4,4′-bis(carbazole)biphenyl, 9,9-di(4-dicarbazole-benzyl)fluorene (CPF), 3,6-bis(triphenylsilyl)carbazole (mCP), and poly(N-octyl-2,7-carbazole-O-9,9-dioctyl-2,7-fluorene) (PCF); aniline derivatives such as 4-(diphenylphosphoryl)-N,N-diphenylaniline (HM-AI); fluorene derivatives such as 1,3-bis(9-phenyl-9H-fluoren-9-yl)benzene (mDPFB), and 1,4-bis(9-phenyl-9H-fluoren-9-yl)benzene (pDPFB); 1,3,5-tris[4-(diphenylamino)phenyl]benzene (TDAPB); and 1,4-bis(triphenylsilyl)benzene (UGH-2).

The hole injection layer and the hole transport layer 13 are provided between the first electrode 12 and the organic light-emitting layer 14 in order to efficiently perform the injection of holes from the first electrode 12, which is the anode, and the transport (injection) of holes to the organic light-emitting layer 14. The electron injection layer and the electron transport layer 15 are provided between the second electrode 16 and the organic light-emitting layer 14 in order to efficiently perform the injection of electrons from the second electrode 16, which is the cathode, and the transport (injection) of electrons to the organic light-emitting layer 14.

Each of the hole injection layer, the hole transport layer 13, the electron injection layer, and the electron transport layer 15 can be formed of a well-known material of the related art. Each of the hole injection layer, the hole transport layer 13, the electron injection layer, and the electron transport layer 15 may be formed of only the following exemplary materials. As necessary, each of the hole injection layer, the hole transport layer 13, the electron injection layer, and the electron transport layer 15 may further include an additive (for example, a donor or an acceptor) as well as the following exemplary compounds. Each of the hole injection layer, the hole transport layer 13, the electron injection layer, and the electron transport layer 15 may have a configuration in which the following exemplary materials are dispersed in a polymer material (binder resin) or in an inorganic material.

Examples of a material forming the hole transport layer 13 include low-molecular-weight materials including oxides such as vanadium oxide (V₂O₅) and molybdenum oxide (MoO₂), inorganic p-type semiconductor materials, porphyrin compounds, aromatic tertiary amine compounds such as N,N′-bis(3-methylphenyl)-N,N′-bis(phenyl)-benzidine (TPD) and N,N′-di(naphthalene-1-yl)-N,N′-diphenyl-benzidine (NPD), hydrazone compounds, quinacridone compounds, and styrylamine compounds; and polymer materials including polyaniline (PANI), polyaniline-camphorsulfonic acid (PANI-CSA), 3,4-polyethylenedioxithiophene/polystyrenesulfonate (PEDOT/PSS), poly(triphenylamine) derivetives (Poly-TPD), polyvinyl carbazole (PVCz), poly(p-phenylenevinylene) (PPV), and poly(p-naphthalenevinylene) (PNV).

In order to efficiently perform the injection and transport of holes from the first electrode 12, as a material forming the hole injection layer, it is preferable that a material having a smaller energy level of highest occupied molecular orbital (HOMO) than that of a material forming the hole transport layer 13 be used. As the material forming the hole transport layer 13, it is preferable that a material having a higher hole mobility than that of the material forming the hole injection layer be used.

Examples of the material forming the hole injection layer include phthalocyanine derivatives such as copper phthalocyanine; amine compounds such as
4,4′,4″-tris(3-methylphenylphenylamino)triphenylamine,
4,4′,4″-tris(1-naphthylphenylamino)triphenylamine,
4,4′,4″-tris(2-naphthylphenylamino)triphenylamine,
4,4′,4″-tris[biphenyl-2-yl(phenyl)amino]triphenylamine,
4,4′,4″-tris[biphenyl-3-yl(phenyl)amino]triphenylamine,
4,4′,4″-tris[biphenyl-4-yl(3-methylphenyl)amino]triphenylamine, and
4,4′,4″-tris[9,9-dimethyl-2-fluorenyl(phenyl)amino]triphenylamine; and oxides such as vanadium oxide (V₂O₅) and molybdenum oxide (MoO₂). However, the material forming the hole injection layer is not limited thereto.

In addition, in order to improve hole injecting and transporting properties, it is preferable that the hole injection layer and the hole transport layer 13 be doped with an acceptor. As the acceptor, materials which are well-known in the related art as an acceptor material for organic EL can be used.

Examples of the acceptor material include inorganic materials such as Au, Pt, W, Ir, POCl₃, AsF₆, Cl, Br, I, vanadium oxide (V₂O₅), and molybdenum oxide (MoO₂); compounds having a cyano group such as TCNQ (7,7,8,8-tetracyanoquinodimethane), TCNQF4 (tetrafluorotetracyanoquinodimethane), TCNE (tetracyanoethylene), HCNB (hexacyanobutadiene), and DDQ (dicyclodicyanobenzoquinone); compounds having a nitro group such as TNF (trinitrofluorenone) and DNF (dinitrofluorenone); and organic materials such as fluorenyl, chloranil, and bromanil. Among these, compounds having a cyano group such as TCNQ, TCNQF4, TCNE, HCNB, and DDQ are more preferable from the viewpoint of being able to efficiently increasing the carrier density.

As a material forming the electron blocking layer, the above-described examples of the material forming the hole transport layer 13 and the hole injection layer can be used.

Examples of a material forming the electron transport layer 15 include low-molecular-weight materials such as inorganic materials which are n-type semiconductors, oxadiazole derivatives, triazole derivatives, thiopyrazine dioxide derivatives, benzoquinone derivatives, naphthoquinone derivatives, anthraquinone derivatives, diphenoquinone derivatives, fluorenone derivatives, and benzodifuran derivatives; and polymer materials such as poly(oxadiazole) (Poly-OXZ) and polystyrene derivatives (PSS).

Examples of a material forming the electron injection layer include, particularly, fluorides such as lithium fluoride (LiF) and barium fluoride (BaF₂); and oxides such as lithium oxide (Li₂O).

From the viewpoints of efficiently performing the injection and transport of electrons from the second electrode 16 which is the cathode, as the material forming the electron injection layer, it is preferable that a material having a higher energy level of lowest unoccupied molecular orbital (LUMO) than that of the material forming the electron transport material 15 be used; and as the material forming the electron transport layer 15, it is preferable that a material having a higher electron mobility than that of the material forming the electron injection layer be used.

In addition, in order to improve electron injecting and transporting properties, it is preferable that the electron injection layer and the electron transport layer 15 be doped with a donor. As the donor, materials which are well-known in the related art as a donor material for organic EL can be used.

Examples of the donor material include inorganic materials such as alkali metals, alkaline earth metals, rare earth elements, Al, Ag, Cu and In; and organic materials such as anilines, phenylenediamines, benzidines (for example, N,N,N′,N′-tetraphenylbenzidine, N,N′-bis-(3-methylphenyl)-N,N′-bis-(phenyl)-benzidine, and N,N′-di(naphthalene-1-yl)-N,N′-diphenyl-benzidine), compounds having an aromatic tertiary amine in a structure thereof such as triphenylamines (for example, triphenylamine, 4,4′,4″-tris(N,N-diphenyl-amino)-triphenylamine, 4,4′,4″-tris(N-3-methylphenyl-N-phenyl-amino)-triphenylamine, and 4,4′,4″-tris(N-(1-naphthyl)-N-phenyl-amino)-triphenylamine), and triphenyldiamines (for example, N,N′-di-(4-methyl-phenyl)-N,N′-diphenyl-1,4-phenylenediamine), condensed polycyclic compounds (which may have a substituent; for example, phenanthrene, pyrene, perylene, anthracene, tetracene, and pentacene), TTF (tetrathiafulvalene), dibenzofuran, phenothiazine, and carbazole. Among these, compounds having an aromatic tertiary amine in a structure thereof, condensed polycyclic compounds, and alkali metals are more preferable from the viewpoint of more efficiently increasing the carrier density.

As a material forming the hole blocking layer, the above-described examples of the material forming the electron transport layer 15 and the electron injection layer can be used.

Examples of a method of forming the organic light-emitting layer 14, the hole transport layer 13, the electron transport layer 15, the hole injection layer, the electron injection layer, the hole blocking layer, the electron blocking layer and the like included in the organic EL layer 17 include methods of forming the layers using an organic EL layer-forming coating solution in which the above-described materials are dissolved and dispersed in a solvent through a well-known wet process including a coating method such as a spin coating method, a dipping method, a doctor blade method, a discharge coating method, and a spray coating method; and a printing method such as an ink jet method, a relief printing method, an intaglio printing method, a screen printing method, or a micro gravure method. Other examples thereof include methods of forming the layers using the above-described materials through a well-known dry process such as a resistance heating deposition method, an electron beam (EB) deposition method, a molecular beam epitaxy (MBE) method, a sputtering method, or an organic vapor-phase deposition (OVPD) method. Alternatively, for example, methods of forming the layers using a laser transfer method can be used. When the organic EL layer 17 is formed through a wet process, the organic EL layer-forming coating solution may contain an additive for adjusting properties of the coating solution such as a leveling agent or a viscosity adjuster.

In general, the thickness of each layer included in the organic EL layer 17 is approximately 1 nm to 1000 nm and more preferably 10 nm to 200 nm. When the thickness of each layer included in the organic EL layer 17 is less than 10 nm, there are concerns that necessary properties (injecting properties, transporting properties, and confinement properties of charge (electron and hole)) may not be obtained and images defects may occur due to foreign materials such as dust. In addition, when the thickness of each layer included in the organic EL layer 17 is greater than 200 nm, the drive voltage is increased and there is a concern that the power consumption may increase.

The first electrode 12 is formed on the substrate (not illustrated), and the second electrode 16 is formed on the organic EL layer (organic layer) 17.

As an electrode material forming the first electrode 12 and the second electrode 16, a well-known electrode material can be used. From the viewpoint of efficiently performing the injection of holes to the organic EL layer 17, examples of the material forming the first electrode 12 which is the anode include metals having a work function of 4.5 eV or higher such as gold (Au), platinum (Pt), and nickel (Ni); oxide (ITO) formed of indium (In) and tin (Sn); oxide (SnO2) of tin (Sn); and oxide (IZO) formed of indium (In) and zinc (Zn). From the viewpoint of efficiently performing the injection of electrons to the organic EL layer 17, examples of the material forming the second electrode 16 which is the cathode include metals having a work function of 4.5 eV or lower such as lithium (Li), calcium (Ca), cerium (Ce), barium (Ba), and aluminum (Al); and alloys containing these metals such as Mg:Ag alloy and Li:Al alloy.

The first electrode 12 and the second electrode 16 can be formed on the substrate using the above-described materials according to a well-known method such as an EB (electron beam) deposition method, a sputtering method, an ion plating method, or a resistance heating deposition method. However, the embodiment is not limited to these formation methods. In addition, as necessary, the formed electrode can be patterned using a photolithography method or a laser lift-off method. In this case, by using a shadow mask in combination, the electrode can be directly patterned.

The thicknesses of the first electrode 12 and the second electrode 16 are preferably greater than or equal to 50 nm. When the thicknesses of the first electrode 12 and the second electrode 16 are less than 50 nm, the interconnection resistance is increased, and thus there is a concern that the drive voltage may increase.

The organic light-emitting element 10 illustrated in FIG. 1 includes the organic EL (organic layer) 17 that includes the organic light-emitting layer 14 having the above-described luminescent material according to the embodiment. Therefore, the organic light-emitting element 10 recombines holes injected from the first electrode 12 with electrons injected from the second electrode 16 and can discharge (emit) blue light with a high efficiency using phosphorescent emission of the luminescent material according to the embodiment contained in the organic layer 17 (organic light-emitting layer 14).

The organic light-emitting element according to the embodiment may have a bottom emission type device configuration in which emitted light is discharged through a substrate; or a top emission type device configuration in which emitted light is discharged to the opposite side to a substrate. In addition, a method of driving the organic light-emitting element according to the embodiment is not particularly limited, and an active driving method or a passive driving method may be used. However, it is preferable that the organic light-emitting element be driven using an active driving method. By adopting an active driving method, the light-emitting time of the organic light-emitting element is increased compared to a passive driving method, a drive voltage required for obtaining a desired luminance can be reduced, and the power consumption can be reduced. Therefore, an active driving method is preferable.

### Second Embodiment

FIG. 2 is a cross-sectional view schematically illustrating a second embodiment of the organic light-emitting element according to the embodiment. An organic light-emitting element 20 illustrated in FIG. 2 includes a substrate 1; TFT (thin film transistor) circuits 2 that are provided on the substrate 1; and an organic light-emitting element 10 (hereinafter, also referred to as “organic EL element 10”). The organic light-emitting element 10 includes a pair of electrodes 12 and 16 that are formed on the substrate 1; and an organic EL layer (organic layer) 17 that is interposed between the pair of electrodes 12 and 16. The organic light-emitting element 20 is a top emission type organic light-emitting element that is driven with an active driving method. In FIG. 2, the same components as those of the organic light-emitting element 10 illustrated in FIG. 1 are represented by the same reference numerals, and the description thereof will not be repeated.

The organic light-emitting element 20 illustrated in FIG. 2 includes the substrate 1, the TFT (thin film transistor) circuits 2, an interlayer dielectric 3, a planarizing film 4, the organic EL element 10, an inorganic sealing film 5, a sealing substrate 9, and a sealing material 6. The TFT (thin film transistor) circuits 2 are provided on the substrate 1. The interlayer dielectric 3 and the planarizing film 4 are provided on the substrate. The organic EL element 10 is formed on the substrate with the interlayer dielectric 3 and the planarizing film 4 interposed therebetween. The inorganic sealing film 5 covers the organic EL element 10. The sealing substrate 9 is provided on the inorganic sealing film 5. A gap between the substrate 1 and the sealing substrate 9 is filled with the sealing material 6. The organic EL element 10 includes the organic EL layer (organic layer) 17, the first electrode 12 and the second electrode 16 between which the organic EL layer (organic layer) 17 is interposed, and a reflective electrode 11. As in the case of the first embodiment, the organic EL layer (organic layer) 17 has a structure in which a hole transport layer 13, a light-emitting layer 14, and an electron transport layer 15 are laminated. The reflective electrode 11 is formed on a lower surface of the first electrode 12. The reflective electrode 11 and the first electrode 12 are connected to one of the TFT circuits 2 through an interconnection 2b which penetrates the interlayer dielectric 3 and the planarizing film 4. The second electrode 16 is connected to one of the TFT circuits 2 through an interconnection 2a which penetrates the interlayer dielectric 3, the planarizing film 4, and an edge cover 19.

The TFT circuits 2 and various interconnections (not illustrated) are formed on the substrate 1. Furthermore, the interlayer dielectric 3 and the planarizing film 4 are sequentially laminated so as to cover an upper surface of the substrate 1 and the TFT circuits 2.

Examples of the substrate 1 include inorganic material substrates formed of glass, quartz, or the like; plastic substrates formed of polyethylene terephthalate, polycarbazole, polyimide, or the like; insulating substrates such as a ceramic substrate formed of alumina or the like; metal substrates formed of aluminum (Al), iron (Fe), or the like; substrates obtained by coating a surface of the above-described substrates with an organic insulating material such as silicon oxide (SiO₂); and substrates obtained by performing an insulation treatment on a surface of a metal substrate formed of Al or the like using a method such as anodic oxidation. However, the embodiment is not limited thereto.

The TFT circuits 2 are formed on the substrate 1 in advance before forming the organic light-emitting element 20 and have a switching function and a driving function. As the TFT circuits 2, well-known TFT circuits 2 of the related art can be used. In addition, in the embodiment, for the switching and driving functions, metal-insulator-metal (MIM) diodes can be used instead of TFTs.

The TFT circuits 2 can be formed using a well-known material, structure, and formation method. Examples of a material of an active layer of the TFT circuits 2 include inorganic semiconductor materials such as amorphous silicon, polycrystalline silicon (polysilicon), microcrystalline silicon, and cadmium selenide; oxide semiconductor materials such as zinc oxide and indium oxide-gallium oxide-zinc oxide; and organic semiconductor materials such as polythiophene derivatives, thiophene oligomers, poly(p-phenylenevinylene) derivatives, naphthacene, and pentacene. In addition, examples of a structure of the TFT circuits 2 include a staggered type, an inverted staggered type, a top-gate type, and a coplanar type.

A gate insulator of the TFT circuits 2 used in the embodiment can be formed of a well-known material. Examples of the material include SiO₂ which is formed using a plasma-enhanced chemical vapor deposition (PECVD) method, a low pressure chemical vapor deposition (LPCVD), or the like; and SiO2 obtained by thermally oxidizing a polysilicon film. In addition, a signal electrode line, a scanning electrode line, and a common electrode line of the TFT circuits 2, the first electrode, and the second electrode which are used in the embodiment can be formed of a well-known material, and examples thereof include tantalum (Ta), aluminum (Al), and copper (Cu).

The gate insulator 3 can be formed of a well-known material, and examples thereof include inorganic materials such as silicon oxide (SiO₂), silicon nitride (SiN or Si₂N4), tantalum oxide (TaO or Ta₂O₅); and organic materials such as acrylic resins and resist materials.

Examples of a method of forming the interlayer dielectric 3 include a dry process such as a chemical vapor deposition (CVD) method and a vacuum deposition method; and a wet process such as a spin coating method. In addition, as necessary, patterning can be performed using a photolithography method or the like.

In the organic light-emitting element 20 according to the embodiment, light emitted from the organic EL element 10 is extracted from the sealing substrate 9 side. Therefore, in order to prevent TFT properties of the TFT circuits 2, formed on the substrate 1, from being changed by light incident from outside, it is preferable that the light-shielding interlayer dielectric 3 (light-shielding insulating film) be used. In addition, in the embodiment, the interlayer dielectric 3 and the light-shielding insulating film can be used in combination. Examples of the light-shielding insulating film include polymer resins such as polyimide in which a pigment or a dye such as phthalocyanine or quinacridone is dispersed; color resists; black matrix materials; and inorganic insulating materials such as and NiₓZn_{y}Fe₂O₄.

The planarizing film 4 is provided for preventing defects of the organic EL element 10 (for example, a defect of a pixel electrode, a defect of the organic EL layer, disconnection of a counter electrode, short-circuiting between a pixel electrode and a counter electrode, or reduction in withstand voltage) caused by convex and concave portions on a surface of the TFT circuits 2. The planarizing film 4 may not be provided.

The planarizing film 4 can be formed of a well-known material, and examples thereof include inorganic materials such as silicon oxide, silicon nitride, and tantalum oxide; and organic materials such as polyimide, acrylic resins, and resist materials. Examples of a method of forming the planarizing film 4 include a dry process such as a CVD method and a vacuum deposition method; and a wet process such as a spin coating method. However, the embodiment is not limited to these materials and formation methods. In addition the planarizing film 4 may have a single-layer structure or a multilayer structure.

In the organic light-emitting element 20 according to the embodiment, light emitted from the organic light-emitting layer 14 of the organic EL element 10, which is a light source, is extracted from the second electrode 16 side which is the sealing substrate 9 side. Therefore, as the second electrode 16, it is preferable that a semitransparent electrode be used. As a material of the semitransparent electrode, a metal semitransparent electrode may be used alone; or a metal semitransparent electrode and a transparent electrode material may be used in combination. From the viewpoints of reflectance and transparency, silver or silver alloys are preferable.

In the organic light-emitting element 20 according to the embodiment, as the first electrode 12 that is disposed on the opposite side to the side of extracting light from the organic light-emitting layer 14, in order to increase the efficiency of extracting light from the organic light-emitting layer 14, it is preferable that an electrode (reflective electrode) having high light reflectance be used. Examples of an electrode material used at this time include a reflective metal electrode such as aluminum, silver, gold, aluminum-lithium alloys, aluminum-neodymium alloys, or aluminum-silicon alloys; and electrodes obtained by combining a transparent electrode and the above-described reflective metal electrode (reflective electrode). FIG. 2 illustrates an example in which the first electrode 12, which is the transparent electrode, is formed on the planarizing film 4 with the reflective electrode 11 interposed therebetween.

In addition, in the organic light-emitting element 20 according to the embodiment, plural first electrodes 12 that are arranged on the substrate 1 side (opposite side to the side of extracting light from the organic light-emitting layer 14) are provided so as to correspond to respective pixels; and the edge cover 19 that is formed of an insulating material so as to cover respective edge portions (end portions) of first electrodes 12 and 12 adjacent to each other is formed. This edge cover 19 is provided for preventing leakage between the first electrode 12 and the second electrode 16. The edge cover 19 can be formed of an insulating material with a well-known method such as an EB deposition method, a sputtering method, an ion plating method, or a resistance heating deposition method. In addition, patterning can be performed using a well-known dry or wet photolithography method. However, the embodiment is not limited to these formation methods. In addition, as the insulating material forming the edge cover 19, a well-known material of the related art can be used. The insulating material is not particularly limited in the embodiment, and examples thereof include SiO, SiON, SiN, SiOC, SiC, HfSiON, ZrO, HfO, and LaO.

The thickness of the edge cover 19 is preferably 100 nm to 2000 nm. When the thickness of the edge cover 19 is greater than or equal to 100 nm, sufficient insulating property can be secured. As a result, an increase in power consumption and non-emission, caused by leakage between the first electrode 12 and the second electrode 16, can be prevented. In addition, when the thickness of the edge cover 19 is less than or equal to 2000 nm, deterioration in the productivity of a film-forming process and disconnection of the second electrode 16 in the edge cover 19 can be prevented. In addition, the reflective electrode 11 and the first electrode 12 are connected to one of the TFT circuits 2 through the interconnection 2b which penetrates the interlayer dielectric 3 and the planarizing film 4. The second electrode 16 is connected to one of the TFT circuits 2 through the interconnection 2a which penetrates the interlayer dielectric 3, the planarizing film 4, and the edge cover 19. The interconnections 2a and 2b are not particularly limited as long as they are formed of a conductive material such as Cr, Mo, Ti, Ta, Al, Al alloys, Cu, or Cu alloys. The interconnections 2a and 2b are formed using a well-known method of the related art such as a sputtering method or CVD method and a mask process.

The inorganic sealing film 5 that is formed of SiO, SiON, SiN, or the like is formed so as to cover the upper surface and side surface of the organic EL element 10 formed on the planarizing film 4. The inorganic sealing film 5 can be formed by forming an inorganic film of SiO, SiON, SiN, or the like with an plasma CVD method, an ion plating method, an ion beam method, a sputtering method, or the like. In order to extract light from the organic EL element 10, it is necessary that the inorganic sealing film 5 be light-transmissive.

The sealing substrate 9 is provided on the inorganic sealing film 5, and the organic light-emitting element 10, formed between the substrate 1 and the sealing substrate 9, is sealed in a sealing region surrounded by the sealing material 6. By providing the inorganic sealing film 5 and the sealing material 6, oxygen or water can be prevented from being mixed into the organic EL layer 17 from outside. As a result, the lifetime of the organic light-emitting element 20 can be improved.

As a material forming the sealing substrate 9, the same materials as those of the above-described substrate 1 can be used. However, since the organic light-emitting element 20 according to the embodiment extracts light from the sealing substrate 9 side (when the observer observes emission from the outside of the sealing substrate 9), it is necessary that the sealing substrate 9 be light-transmissive. In addition, in order to improve color purity, a color filter may be formed on the sealing substrate 9.

As the sealing material 6, a well-known sealing material of the related art can be used. In addition, as a method of forming the sealing material 6, a well-known sealing method of the related art can be used.

As the sealing material 6, for example, a resin (curing resin) can be used. In this case, the upper surface and/or side surface of the inorganic sealing film 5 of the substrate 1 on which the organic EL element 10 and the inorganic sealing film 5 are formed; or the sealing substrate 9 is coated with a curing resin (photocurable resin, thermosetting resin) using a spin coating method or a laminate method. Then, the substrate 1 and the sealing substrate 9 are bonded to each other through the resin layer to perform photo-curing or thermal curing. As a result, the sealing material 6 can be formed. It is necessary that the sealing material 6 be light-transmissive.

In addition, inactive gas such as nitrogen gas or argon gas may be introduced into a gap between the inorganic sealing film 5 and the sealing material 6. For example, a method of sealing inactive gas such as nitrogen gas or argon gas with the sealing substrate 9 such as a glass substrate may be used.

In this case, in order to efficiently reduce deterioration of the organic EL portion caused by water, it is preferable that a moisture absorbent such as barium oxide or the like be mixed into inorganic gas to be sealed.

As in the case of the organic light-emitting element 10 according to the first embodiment, the organic EL layer (organic layer) 17 of the organic light-emitting element 20 according to the embodiment also contains the luminescent material according to the embodiment. Therefore, the organic light-emitting element 20 recombines holes injected from the first electrode 12 with electrons injected from the second electrode 16 and can discharge (emit) blue light with a high efficiency using phosphorescent emission of the luminescent material according to the embodiment contained in the organic layer 17 (organic light-emitting layer 14).

### <Wavelength-Converting Light-Emitting Element>

A wavelength-converting light-emitting element according to an embodiment of the present invention includes a light-emitting element; and a fluorescent layer that is disposed on a side of extracting light from the light-emitting element, absorbs light emitted from the light-emitting element, and emits light having a different wavelength from that of the absorbed light.

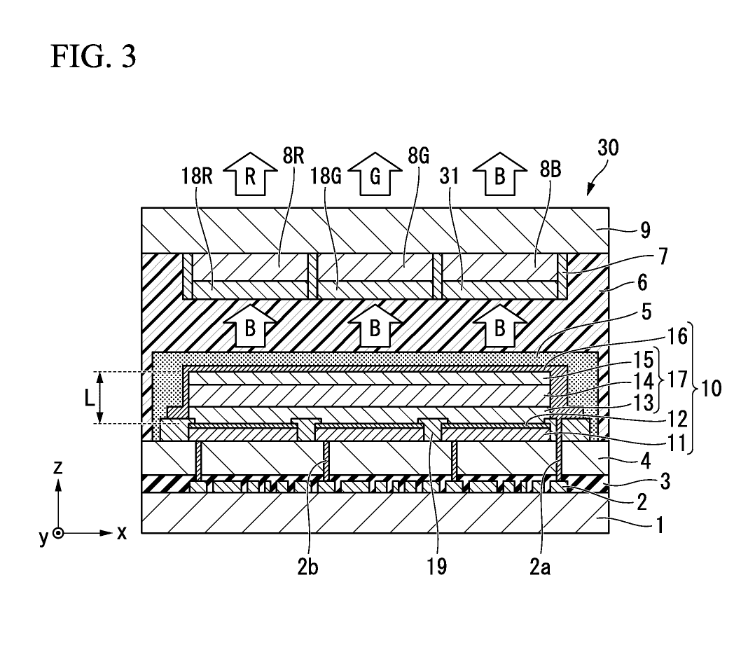

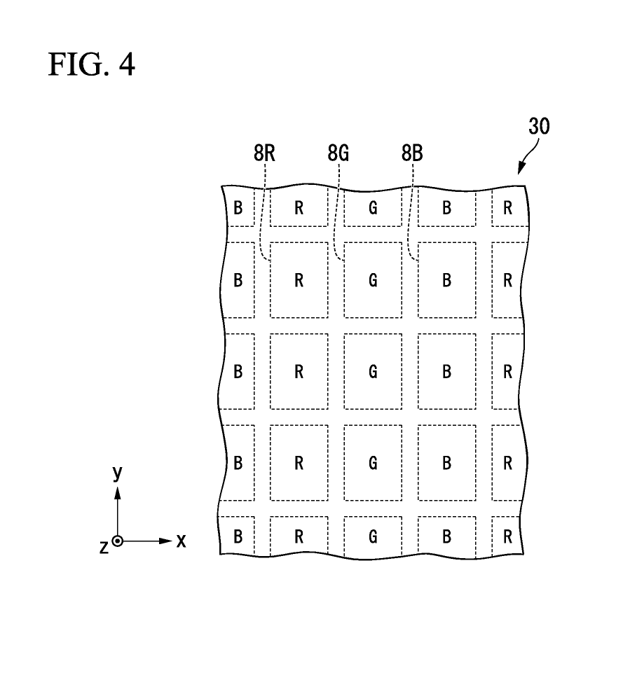

FIG. 3 is a cross-sectional view illustrating a first embodiment of the organic light-emitting element according to the embodiment, and FIG. 4 is a top view illustrating the wavelength-converting light-emitting element of FIG. 3. A wavelength-converting light-emitting element 30 illustrated in FIG. 3 includes a red fluorescent layer 18R that absorbs blue light emitted from the above-described organic light-emitting element according to the embodiment and converts the blue light into red light; and a green fluorescent layer 18G that absorbs blue light and converts the blue light into green light. Hereinafter, the red fluorescent layer 18R and the green fluorescent layer 18G are also collective referred to as “fluorescent layers”. In the wavelength-converting light-emitting element 30 illustrated in FIG. 3, the same components as those of the organic light-emitting elements 10 and 20 are represented by the same reference numerals and the description thereof will not be repeated.

The wavelength-converting light-emitting element 30 illustrated in FIG. 3 briefly includes a substrate 1, TFT (thin film transistor) circuits 2, an interlayer insulating film 3, a planarizing film 4, an organic light-emitting element (light source) 10, a sealing substrate 9, a red color filter 8R, a green color filter 8G, a blue color filter 8B, the red fluorescent layer 18R, the green fluorescent layer 18G, a sealing substrate 9, a black matrix 7, and a scattering layer 31. The TFT (thin film transistor) circuits 2 are provided on the substrate 1. The organic light-emitting element (light source) 10 is formed on the substrate 1 with the interlayer dielectric 3 and the planarizing film 4 interposed therebetween. The red color filter 8R, the green color filter 8G, and the blue color filter 8B are partitioned by the black matrix 7 and disposed in parallel on one surface of the sealing substrate 9. The red fluorescent layer 18R is aligned and formed on the red color filter 8R formed on one surface of the sealing substrate 9. The green fluorescent layer 18G is aligned and formed on the green color filter 8G formed on one surface of the sealing substrate 9. The scattering layer 31 is aligned and formed on the blue color filter 8B formed on the sealing substrate 9. The substrate 1 and the sealing substrate 9 are disposed such that the organic light-emitting element 10 is disposed opposite the respective fluorescent layers 18R and 18G and the scattering layer 31 with a sealing material interposed therebetween. The respective fluorescent layers 18R and 18G and the scattering layer 31 are partitioned by the black matrix 7.

The organic EL light-emitting portion 10 is covered with the inorganic sealing film 5. In the organic EL light-emitting portion 10, the organic EL layer (organic layer) 17 in which a hole transport layer 13, a light-emitting layer 14, and an electron transport layer 15 are laminated is interposed between a first electrode 12 and a second electrode 16. A reflective electrode 11 is formed on a lower surface of the first electrode 12. The reflective electrode 11 and the first electrode 12 are connected to one of the TFT circuits 2 through an interconnection 2b which penetrates the interlayer dielectric 3 and the planarizing film 4. The second electrode 16 is connected to one of the TFT circuits 2 through an interconnection 2a which penetrates the interlayer dielectric 3, the planarizing film 4, and an edge cover 19.

In the wavelength-converting light-emitting element 30 according to the embodiment, light emitted from the organic light-emitting element 10, which is a light source, is incident to the respective fluorescent layers 18R and 18G and the scattering layer 31; this incident layer transmits through the scattering layer 31 without any change; the respective fluorescent layers 18R and 18G converts the incident light into light beams of three colors including red, green, and blue; and the converted three light beams are emitted to the sealing substrate 9 side (observer side).

In FIG. 3, in order to make the drawing more recognizable, an example of the wavelength-converting light-emitting element 30 according to the embodiment is illustrated in which the red fluorescent layer 18R and the red color filter 8R, the green fluorescent layer 18G and the green color filter 8G, and the scattering layer 31 and the blue color filter 8B are disposed in parallel, respectively. However, as illustrated in FIG. 4, the respective color filters 8R, 8G, and 8B surrounded by broken lines have a two-dimensional stripe arrangement in which the respective color filters 8R, 8G, and 8B extend in a stripe shape along the y-axis and are sequentially arranged along the x-axis.

In an example of FIG. 4, the respective RGB pixels (respective color filters 8R, 8G, and 8B) are arranged in a stripe shape, but the embodiment is not limited thereto. The arrangement of the respective RGB pixels can be a well-known RGB pixel arrangement such as a mosaic arrangement or a delta arrangement.

The red fluorescent layer 18R absorbs light in a blue wavelength range emitted from the organic light-emitting element 10, which is a light source; converts the light in a blue wavelength range into light in a red wavelength range; and emits the light in a red wavelength range to the sealing substrate 9 side.

The green fluorescent layer 18G absorbs light in a blue wavelength range emitted from the organic light-emitting element 10, which is a light source; converts the light in a blue wavelength range into light in a green wavelength range; and emits the light in a green wavelength range to the sealing substrate 9 side.

The scattering layer 31 is provided for improving the viewing angle characteristic and extraction efficiency of light in a blue wavelength range emitted from the organic light-emitting element 10 which is a light source; and emits the light in a blue wavelength range to the sealing substrate 9 side. The scattering layer 31 may not be provided.

In this way, by providing the red fluorescent layer 18R and the green fluorescent layer 18G (and the scattering layer 31), light emitted from the organic light-emitting element 10 is converted into light beams of three colors including red, green, and blue; and the converted light beams are emitted to the sealing substrate 9 side, thereby making full-color display possible.

The color filters 8R, 8G, and 8B that are disposed between the sealing substrate 9 on the light extraction side (observer side) and the fluorescent layers 18R and 18G and the scattering layer 31 are provided for improving the color purity of red, green, and blue light beams emitted from the wavelength-converting light-emitting element (color-converting light-emitting element) 30; and for enlarging the color reproduction range of the wavelength-converting light-emitting element 30. In addition, the red color filter 8R that is formed on the red fluorescent layer 18R and the green color filter 8G that is formed on the green fluorescent layer 18G absorb blue components and ultraviolet components of outside light. Therefore, the emission of the respective fluorescent layers 8R and 8G caused by outside light can be reduced and prevented; and deterioration in contrast can be reduced and prevented.

The color filters 8R, 8G, and 8B are not particularly limited, and well-known color filters of the related art can be used. In addition, likewise, as a method of forming the color filters 8R, 8G, and 8B, a well-known method of the related art can be used. The thickness thereof can also be appropriately adjusted.

The scattering layer 31 has a configuration in which transparent particles are dispersed in a binder resin. The thickness of the scattering layer 31 is normally 10 μm to 100 μm and preferably 20 μm to 50 μm.

As the binder resin used for the scattering layer 31, a well-known resin of the related art can be used. The binder resin is not particularly limited, but a light-transmissive resin is preferable. The transparent particles are not particularly limited as long as light emitted from the organic light-emitting element 10 are scattered by and pass through the transparent particles. For example, polystyrene particles having an average particle size of 25 μm and a standard deviation of particle size distribution of 1 μm can be used. In addition, the content of the transparent particles in the scattering layer 31 can be appropriately changed and is not particularly limited.

The scattering layer 31 can be formed using a well-known method of the related art, and the formation method is not particularly limited. Examples of the formation method include methods of forming the layer using a coating solution in which a binder resin and transparent particles are dissolved and dispersed in a solvent through a well-known wet process including a coating method such as a spin coating method, a dipping method, a doctor blade method, a discharge coating method, and a spray coating method; and a printing method such as an ink jet method, a relief printing method, an intaglio printing method, a screen printing method, or a micro gravure method.

The red fluorescent layer 18R contains a fluorescent material capable of absorbing light in a blue wavelength range emitted from the organic light-emitting element 10 to be excited; and emitting fluorescence in a red wavelength range.

The green fluorescent layer 18G contains a fluorescent material capable of absorbing light in a blue wavelength range emitted from the organic light-emitting element 10 to be excited; and emitting fluorescence in a green wavelength range.

The red fluorescent layer 18R and the green fluorescent layer 18G may be formed of the following exemplary fluorescent materials alone; may further contain an additive or the like as necessary; and may have a configuration in which these materials are dispersed in a polymer material (binder resin) or in an inorganic material.

As the fluorescent material forming the red fluorescent layer 18R and the green fluorescent layer 18G, well-known fluorescent materials of the related art can be used. Such fluorescent materials are divided into organic fluorescent materials and inorganic fluorescent materials. Specific exemplary compounds of these fluorescent materials are described below, but the embodiment is not limited to these materials.

First, examples of the organic fluorescent materials will be described. Examples of fluorescent materials used for the red fluorescent layer 18R include cyanine-based dyes such as 4-dicyanomethylene-2-methyl-6-(p-dimethylaminostyryl)-4H-pyran; pyridine-based dyes such as 1-ethyl-2-[4-(p-dimethylamino phenyl)-1,3-butadienyl]-pyridinium-perchlorate; and rhodamine-based dyes such as rhodamine B, rhodamine 6G, rhodamine 3B, rhodamine 101, rhodamine 110, basic violet 11, and sulforhodamine 101. In addition, examples of fluorescent materials used for the green fluorescent layer 18G include coumarin-based dyes such as 2,3,5,6-1H,4H-tetrahydro-8-trifluomethyl quinolizine(9,9a, 1-gh)coumarin (coumarin 153), 3-(2′-benzothiazolyl)-7-diethylamino coumarin (coumarin 6), 3-(2′-benzoimidazolyl)-7-N,N-diethylamino coumarin (coumarin 7); and naphthalimide-based dyes such as basic yellow 51, solvent yellow 11, and solvent yellow 116. In addition, the luminescent material according to the embodiment can be used.

Next, examples of the inorganic fluorescent materials will be described. Examples of fluorescent materials used for the red fluorescent layer 18R include Y₂O₂S:Eu³⁺, YAlO₃:Eu³⁺, Ca₂Y₂(SiO₄)₆:Eu³⁺, LiY₉(SiO₄)₆O₂:Eu³⁺, YVO₄:Eu³⁺, CaS:Eu³⁺, Gd₂O₃:Eu³⁺, Gd₂O₂S:Eu³⁺, Y(P,V)O₄:Eu³⁺, Mg₄GeOs_{5.5}F:Mn⁴⁺, Mg₄GeO₆:Mn⁴⁺, K₅Eu_{2.5}(WO₄)_{6.25}, Na₅Eu_{2.5}(WO₄)_{6.25}, K₅Eu_{2.5}(MoO₄)_{6.25}, and, Na₅Eu_{2.5}(MoO₄)_{6.25}. Examples of fluorescent materials used for the green fluorescent layer 18G include (BaMg)Al₁₆O₂₇:Eu²⁺,Mn²⁺, Sr₄Al₁₄O₂₅:Eu²⁺, (SrBa)Al₁₂Si₂O₈:Eu²⁺, (BaMg)₂SiO₄:Eu²⁺, Y₂SiO₅:Ce₃₊, Tb³⁺, Sr₂P₂O₇—Sr₂B₂O₅:Eu²⁺, (BaCaMg)₅(PO₄)₃Cl:Eu²⁺, Sr₂Si₃₀O₈-2SrCl₂:Eu²⁺, Zr₂SiO₄, MgA₁₁O₁₉:Ce³⁺, Tb³⁺, Ba₂SiO₄:Eu²⁺, Sr₂SiO₄:Eu²⁺, and (BaSr)SiO₄:Eu²⁺As necessary, it is preferable that the above-described inorganic fluorescent materials be subjected to a surface modification treatment. Examples of a method of the surface modification treatment include a chemical treatment using a silane coupling agent and the like; a physical treatment of adding submicron-order particles and the like; and a combination of the above-described methods. When deterioration caused by excitation light and deterioration caused by emission are taken into consideration, it is preferable that the inorganic fluorescent materials be used from the viewpoint of stability. In addition, when the inorganic fluorescent materials are used, it is preferable that the average particle size (d50) of the materials be 0.5 μm to 50 μm.

In addition, when the red fluorescent layer 18R and the green fluorescent layer 18G have a configuration in which the above-described fluorescent materials are dispersed in a polymer material (binder resin), patterning can be performed with a photolithography method by using a photosensitive resin as the polymer material. Here, as the photosensitive layer, one kind or a mixture of plural kinds selected from photosensitive resins (photocurable resist materials) having a reactive vinyl group such as acrylic acid-based resins, methacrylic acid-based resins, polyvinyl cinnamate-based resins, and vulcanite-based resins can be used.

In addition, the red fluorescent layer 18R and the green fluorescent layer 18G can be formed according to a well-known wet process, dry process, or laser transfer method using a fluorescent layer-forming coating solution in which the above-described fluorescent materials (pigments) and binder resin are dissolved and dispersed in a solvent. Here, examples of the well-known wet process include a coating method such as a spin coating method, a dipping method, a doctor blade method, a discharge coating method, and a spray coating method; and a printing method such as an ink jet method, a relief printing method, an intaglio printing method, a screen printing method, or a micro gravure method. In addition, examples of the well-known dry process include a resistance heating deposition method, an electron beam (EB) deposition method, a molecular beam epitaxy (MBE) method, a sputtering method, or an organic vapor-phase deposition (OVPD) method.

The thicknesses of the red fluorescent layer 18R and the green fluorescent layer 18G are normally 100 nm to 100 μm and preferably 1 μm to 100 μm. When the thickness of each of the red fluorescent layer 18R and the green fluorescent layer 18G is less than 100 nm, it is difficult to sufficiently absorb blue light emitted from the organic light-emitting element 10. Therefore, there are cases in which the luminous efficiency of the light-converting light-emitting element 30 may deteriorate or blue transmitted light may be mixed into light converted by the respective fluorescent layers 18R and 18G; and, as a result, the color purity may deteriorate. In addition, in order to improve the absorption of blue light emitted from the organic light-emitting element 10 and to reduce blue transmitted light to a degree that does not have adverse effects on color purity, it is preferable that the thickness of each of the fluorescent layers 18R and 18G be greater than or equal to 1 μm. Even if the thickness of each of the red fluorescent layer 18R and the green fluorescent layer 18G is greater than 100 μm, the luminous efficiency of the light-converting light-emitting element 30 is not increased because blue light emitted from the organic light-emitting element 10 is already sufficiently absorbed. Therefore, since an increase in material cost can be suppressed, it is preferable that the thickness of each of the red fluorescent layer 18R and the green fluorescent layer 18G be less than or equal to 100 μm.

The inorganic sealing film 5 is formed so as to cover the upper surface and side surface of the organic EL element 10. Furthermore, the red fluorescence-converting layer 8R, the green fluorescence-converting layer 8G, the scattering layer 31, and the respective color filters 8R, 8G, and 8B are partitioned by the black matrix 7 and disposed in parallel on one surface of the sealing substrate 9, and the sealing substrate 9 is disposed on the inorganic sealing film 5 such that the respective fluorescent layers 18R and 18G and the scattering layer 31 are disposed opposite the organic light-emitting element. A gap between the inorganic sealing film 5 and the sealing substrate 9 is filled with a sealing material 6. That is, each of the respective fluorescent layers 18R and 18G and the scattering layer 31 that are disposed opposite the organic light-emitting element 10 is partitioned by being surrounded by the black matrix 7; and is sealed in a sealing region surrounded by the sealing material 6.

When a resin (curing resin) is used as the sealing material 6, the inorganic sealing film 5 of the substrate 1 on which the organic light-emitting element 10 and the inorganic sealing film 5 are formed; or the respective fluorescent layers 18R and 18G and the functional layer 31 of the sealing substrate 9 on which the respective fluorescent layers 18R and 18G, the functional layer 31, and the respective color filters 8R, 8G, and 8B are formed, are coated with a curing resin (photocurable resin, thermosetting resin) using a spin coating method or a laminate method. Then, the substrate 1 and the sealing substrate 9 are bonded to each other through the resin layer to perform photo-curing or thermal curing. As a result, the sealing material 6 can be formed.

It is preferable that opposite surfaces of the respective fluorescence-converting layers 18R and 18G and the scattering layer 31 to the sealing substrate 9 be planarized by the planarizing film (not illustrated) and the like. As a result, when the organic light-emitting element 10 is disposed opposite and comes into close contact with the respective fluorescent layers 18R and 18G and the scattering layer 31 with the sealing material 6 interposed therebetween, a gap between the organic light-emitting element 10 and the respective fluorescent layers 18R and 18G and the functional layer 31 can be prevented. Furthermore, the adhesion between the substrate 1, on which the organic light-emitting element 10 is formed, and the sealing substrate 9, on which the respective fluorescent layers 18R and 18G, the scattering layer 31, and the color filters 8R, 8G, and 8B are formed can be improved. As the planarizing film, for example, the same film as the above-described planarizing film 4 can be used.

A material and a formation method of the black matrix 7 are not particularly limited, and a well-known material and formation method of the related art can be used. Among these, it is preferable that the black matrix 7 be formed of a material which further reflects light, which is incident to and scattered by the respective fluorescent layers 18R and 18G, to the respective fluorescent layers 18R and 18G, for example, a light-reflecting metal.

It is preferable that the organic light-emitting element 10 have a top emission type such that a large amount of light can reach the respective fluorescent layers 18R and 18G and the scattering layer 31. At this time, it is preferable that reflective electrodes be used as the first electrode 12 and the second electrode 16; and the optical distance L between these electrode 12 and 16 be adjusted to form a microresonator structure (microcavity structure). In this case, it is preferable that a reflective electrode be used as the first electrode 12; and a semitransparent electrode be used as the second electrode 16.

As a material of the semitransparent electrode, a semitransparent metal electrode may be used alone; or a combination of a semitransparent metal electrode and a transparent electrode material may be used. In particular, as the material of the semitransparent material, silver or silver alloys are preferable from the viewpoints of reflectance and transparency.

It is preferable that the thickness of the second electrode 16 which is the semitransparent electrode be 5 nm to 30 nm. When the thickness of the semitransparent film is less than 5 nm, light is not sufficiently reflected and thus there is a possibility that an interference effect may be insufficiently obtained. In addition, when the thickness of the semitransparent film is greater than 30 nm, the light transmittance rapidly deteriorates and thus there is a concern that luminance and efficiency may deteriorate.

In addition, it is preferable that an electrode having high light reflectance be used as the first electrode 12 which is the reflective electrode. Examples of the reflective electrode include a reflective metal electrode such as aluminum, silver, gold, aluminum-lithium alloys, aluminum-neodymium alloys, or aluminum-silicon alloys. As the reflective electrode, a transparent electrode and the above-described reflective metal electrode may be used in combination. In FIG. 3, an example in which the first electrode 12 which is the transparent electrode is formed on the planarizing film 4 with the reflective electrode 11 interposed therebetween is illustrated.

When the microresonator structure (microcavity structure) is formed by the first electrode 12 and the second electrode 16, light emitted from the organic EL layer 17 is collected in the front direction (light extraction direction: sealing substrate 9 side) due to an interference effect between the first electrode 12 and the second electrode 16. That is, since directivity can be given to light emitted from the organic EL layer 17, light loss escaping to the vicinity can be reduced, and thus the luminous efficiency can be improved. As a result, the light emission energy emitted from the organic light-emitting element 10 can be propagated to the respective fluorescent layers 18R and 18G with a higher efficiency; and the luminance on the front side of the wavelength-converting light-emitting element 30 can be increased.

In addition, due to the above-described microresonator structure, the emission spectrum of the organic EL layer 17 can be adjusted; and a desired emission peak wavelength and full width at half maximum can be obtained. Therefore, the emission spectrum of the organic EL layer 17 can be adjusted to the spectrum capable of effectively exciting fluorescents in the fluorescent layers 18R and 18G.

By using a semitransparent electrode as the second electrode 16, light, emitted to the opposite direction to the light extraction direction of the respective fluorescent layers 18R and 18G and the scattering layer 31, can be reused.

In the respective fluorescent layer 18R and 18G, the optical distance from an emission position of converted light to a light extraction surface is set to vary depending on each color of the light-emitting element. In the light-converting light-emitting element 30 according to the embodiment, the above-described “emission position” is set to a surface of the respective fluorescent layers 18R and 18G opposite the organic light-emitting element 10 side.

Here, in the respective fluorescent layer 18R and 18G, the optical distance from an emission position of converted light to a light extraction surface can be adjusted by the thickness of the respective fluorescent layers 18R and 18G. The thickness of the respective fluorescent layers 18R and 18G can be adjusted by changing printing conditions in a screen printing method (attack pressure of squeegee, attack angle of squeegee, squeegee speed, or clearance width), the specification of a screen printing plate (selection of screen printing gauze, thickness of emulsion, tension, or strength of frame), and the specification of a fluorescent layer-forming coating solution (viscosity, fluidity, or mixing ratios of resin, pigment, and solvent).

In the light-converting light-emitting element 30 according to the embodiment, light emitted from the organic light-emitting element 10 can be amplified by the microresonator structure (microcavity structure); and the light extraction efficiency of light converted by the respective fluorescent layers 18R and 18G can be improved by adjusting the above-described optical distance (by adjusting the thickness of the respective fluorescent layers 18R and 18G). As a result, the luminous efficiency of the light-converting light-emitting element 30 can be further improved.

The light-converting light-emitting element 30 according to the embodiment has a configuration in which light, emitted from the organic light-emitting element 10 containing the above-described luminescent material according to the embodiment, is converted by the fluorescent layers 18R and 18G. Therefore, light can be emitted with a high efficiency.

Hereinabove, the wave-converting light-emitting element according to the embodiment has been described. However, the wave-converting light-emitting element according to the embodiment is not limited thereto. For example, in the wave-converting light-emitting element 30 according to the embodiment, it is preferable that a polarizer be provided on the light extraction surface (upper surface of the sealing substrate 9). As the polarizer, a well-known linear polarizer and a well-known λ/4 polarizer of the related art can be used in combination. Here, by providing the polarizer, outside light reflection from the first electrode 12 and the second electrode 16; or outside light reflection from a surface of the substrate 1 or the sealing substrate 9 can be prevented; and the contrast of the light-converting light-emitting element 30 can be improved.

In addition, in the above-described embodiment, the organic light-emitting element 10 containing the above-described luminescent material according to the embodiment is used as a light source (light-emitting element). However, the embodiment is not limited thereto. Another configuration can be adopted in which a light source such as an organic EL, an inorganic EL, or an LED (light-emitting diode) containing another luminescent material is used as a light-emitting element; and a layer containing the luminescent material according to the embodiment is provided as a fluorescent layer which absorbs emitted from the light-emitting element (light source) and emits blue light. At this time, it is desirable that the light-emitting element which is the light source emit light (ultraviolet light) having a shorter wavelength than that of the blue light.

In the wave-converting light-emitting element 30 according to the embodiment, an example of emitting light beams of three colors including red, green, blue has been described. However, the wave-converting light-emitting element according to the embodiment is not limited thereto. The wave-converting light-emitting element may be a single-color light-emitting element containing only one kind of fluorescent layer; or can include multi-color light-emitting elements of white, yellow, magenta, cyan and the like in addition to light-emitting elements of red, green, and blue. In this case, a fluorescent layer corresponding to each color may be used. As a result, power consumption can be reduced and color reproduction range can be enlarged. In addition, multi-color fluorescent layers can be easily formed by using a photolithography method using a resist, a printing method, or a wet formation method rather than a shadow mask method.

### <Light-Converting Light-Emitting Element>

A light-converting light-emitting element according to an embodiment of the present invention includes at least one organic layer that includes a light-emitting layer containing the above-described luminescent material according to the embodiment, a layer for multiplying a current, and a pair of electrodes between which the organic layer and the layer for multiplying a current are interposed.

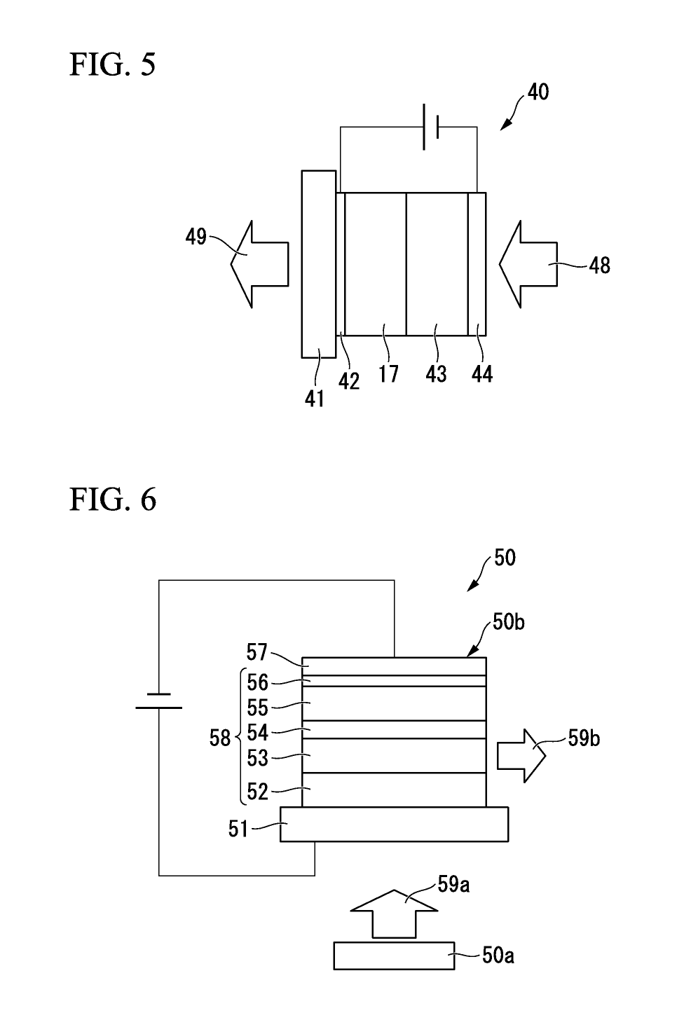

FIG. 5 is a diagram schematically illustrating an embodiment of the light-converting light-emitting element according to the embodiment. A light-converting light-emitting element 40 illustrated in FIG. 5 converts electrons, obtained using photoelectric conversion due to the photocurrent multiplication effect, into light again according to the principle of EL emission.

The light-converting light-emitting element 40 illustrated in FIG. 5 includes an element substrate 41, a bottom electrode 42, an organic EL layer 17, an organic photoelectric material layer 43, and an Au electrode 44. The element substrate 41 is formed of a transparent glass substrate. The bottom electrode 42 is formed on one surface of the electrode substrate 41 and is formed of an ITO electrode. The organic EL layer 17, the organic photoelectric material layer 43, and the Au electrode 44 are sequentially laminated on the bottom electrode 42. A positive terminal of a drive power supply is connected to the bottom electrode 42, and a negative terminal of the drive power supply is connected to the Au electrode 44.

The organic EL layer 17 can adopt the same configuration as that of the above-described organic EL layer 17 in the organic light-emitting element according to the first embodiment.

The organic photoelectric material layer 43 exhibits a photoelectric effect of multiplying a current, and may include only one NTCDA (naphthalene tetracarboxylic dianhydride) layer; or may include plural layers capable of selecting a sensitivity wavelength range. For example, the organic photoelectric material layer 43 may include two layers including a Me-PTC (perylene pigment) layer and a NTCDA layer. The thickness of the organic photoelectric material layer 43 is not particularly limited and is, for example, approximately 10 nm to 100 nm. The organic photoelectric material layer 43 is formed using a vacuum deposition method.

The light-converting light-emitting element 40 according to the embodiment applies a predetermined voltage between the bottom electrode 42 and the Au electrode 44. When the Au electrode 44 is irradiated with light from outside (incident light 48), holes generated by the irradiation of light are trapped and accumulate in the vicinity of the Au electrode 44, which is the negative terminal. As a result, an electric field is concentrated on the interface between the organic photoelectric material layer 43 and the Au electrode 44, electrons are injected from the Au electrode 44, and the current multiplication phenomenon occurs. The organic EL layer 17 emits light based on the current multiplied in this way. Therefore, superior luminescence property can be obtained. Light generated from the organic EL 17 is emitted outside through the element substrate 41 as outgoing light 49.

Since the light-converting light-emitting element 40 according to the embodiment includes the organic EL layer 17 containing the above-described luminescent material according to the first embodiment, the luminous efficiency can be further improved.

### <Organic Laser Diode Light-Emitting Element>

An organic laser diode light-emitting element according to an embodiment of the present invention includes an excitation light source (including a continuous wave excitation light source); and a resonator structure that is irradiated with light emitted from the excitation light source. In the resonator structure, at least one organic layer that includes a laser-active layer is interposed between a pair of electrodes.

FIG. 6 is a diagram schematically illustrating an embodiment of the organic laser diode light-emitting element according to the embodiment. An organic laser diode light-emitting element 50 illustrated in FIG. 6 includes an excitation light source 50a that emits laser light; and a resonator structure 50b. The resonator structure 50b includes an ITO substrate 51, a hole transport layer 52, a laser-active layer 53, a hole blocking layer 54, an electron transport layer 55, an electron injection layer 56, and an electrode 57. The hole transport layer 52, the laser-active layer 53, the hole blocking layer 54, the electron transport layer 55, the electron injection layer 56, and the electrode 57 are sequentially laminated on the ITO substrate 51. The ITO electrode formed on the ITO substrate 51 is connected to a positive terminal of a drive power supply, and the electrode 57 is connected to a negative terminal of the drive power supply.

The hole transport layer 52, the hole blocking layer, the electron transport layer 55, and the electron injection layer 56 have the same configurations as those of the above-described hole transport layer 13, the hole blocking layer, the electron transport layer 15, and the electron injection layer in the organic light-emitting element according to the first embodiment, respectively. The laser-active layer 53 can adopt the same configuration as that of the above-described organic light-emitting layer 14 in the organic light-emitting element according to the first embodiment. It is preferable that a host material be doped with the luminescent material according to the first embodiment. In FIG. 6, the organic EL layer 58 in which the hole transport layer 52, the laser-active layer 53, the hole blocking layer 54, the electron transport layer 55, and the electron injection layer 56 are sequentially laminated is illustrated. However, the organic laser diode light-emitting element 50 according to the first embodiment is not limited thereto and can adopt the same configuration as that of the above-described organic light-emitting layer 14 in the organic light-emitting element according to the first embodiment.

In the organic laser diode light-emitting element 50 according to the embodiment, laser light 59a is emitted by the excitation light source 50a from the ITO substrate 51 side which is the anode. As a result, ASE (edge emission 59b) in which the peak luminance is increased corresponding to the excitation intensity of laser light can be produced from a side surface of the resonator structure 50b.

### <Dye Laser>

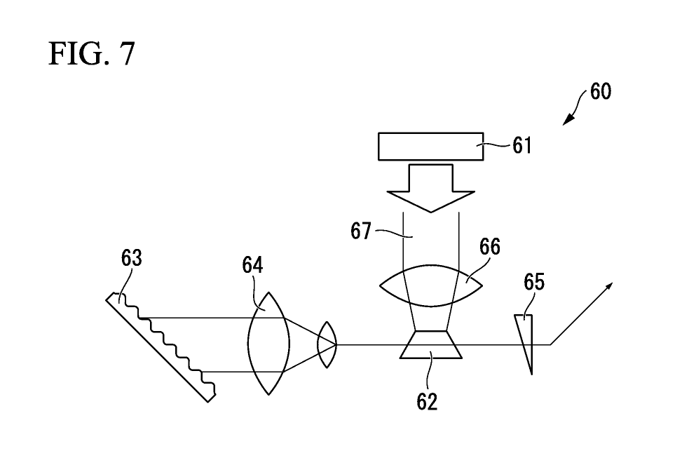

FIG. 7 is a diagram schematically illustrating an embodiment of a dye laser according to an embodiment of the present invention. A dye laser 60 illustrated in FIG. 7 includes an excitation light source 61, a dye cell 62, a lens 66, a partially reflecting mirror 65, a diffraction grating 63, and a beam expander 64. The excitation light source 61 emits pump light 67. The lens 66 collects the pump light 67 to the dye cell 62. The partially reflecting mirror 65 is disposed opposite the beam expander 64 with the dye cell 62 interposed therebetween. The beam expander 64 is disposed between the diffraction grating 63 and the dye cell 62. The beam expander 64 collects light from the diffraction grating 63. The dye cell 62 is formed of quartz glass or the like. The dye cell 62 is filled with a laser medium which is a solution containing the luminescent material according to the embodiment.

In the dye laser 60 according to the embodiment, when the excitation light source 61 emits the pump light 67, the pump light 67 is collected to the dye cell 62 by the lens 66 and excites the luminescent material according to the embodiment contained in the laser medium of the dye cell 62 to emit light. The light emitted from the luminescent material is discharged outside the dye cell 62 and is reflected and amplified between the partially reflecting mirror 62 and the diffraction grating 63. The amplified light passes through the partially reflecting mirror 65 and is emitted outside. In this way, the luminescent material according to the first embodiment can also be applied to the dye laser.

The above-described organic light-emitting element, wavelength-converting light-emitting element, and light-converting light-emitting element according to the embodiments can be applied to a display device, an illumination device, and the like.

### <Display Device>

A display according to an embodiment of the present invention includes an image signal output portion, a drive portion, and a light-emitting portion. The image signal output portion outputs an image signal. The drive portion applies a current or a voltage based on the signal output from the image signal output portion. The light-emitting portion emits light based on the current or the voltage applied from the drive portion. In the display device according to the embodiment, the light-emitting portion is configured as any one of the above-described organic light-emitting element, wavelength-converting light-emitting element, and light-converting light-emitting element according to the embodiments. In the following description, a case in which the light-emitting porting is the organic light-emitting element according to the embodiment will be described as an example. However the embodiment is not limited thereto. In the display device according to the embodiment, the light-emitting portion can be configured as the wavelength-converting light-emitting element or the light-converting light-emitting element.

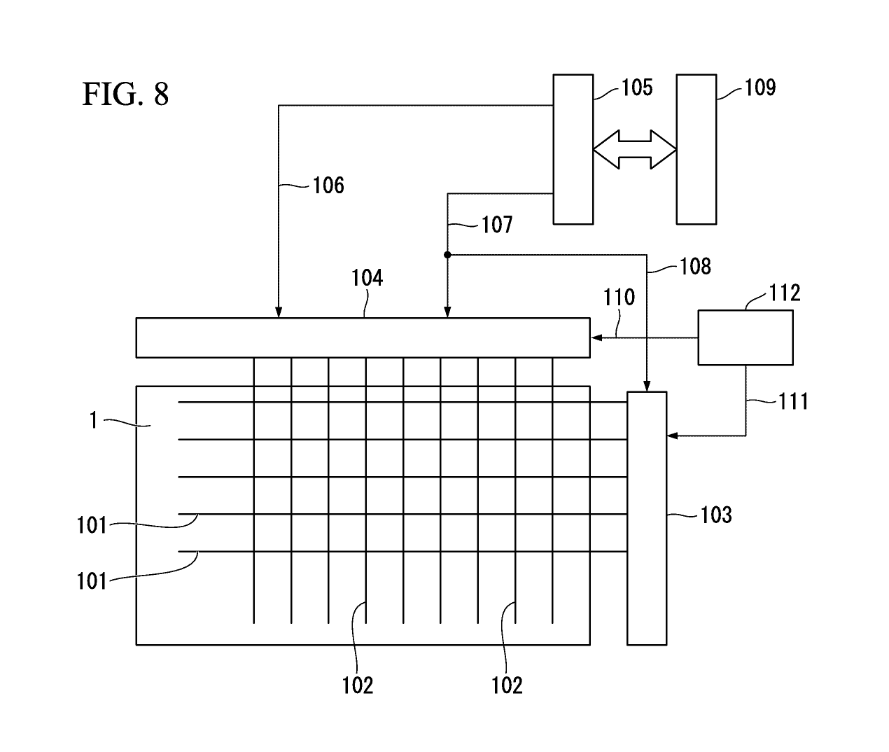

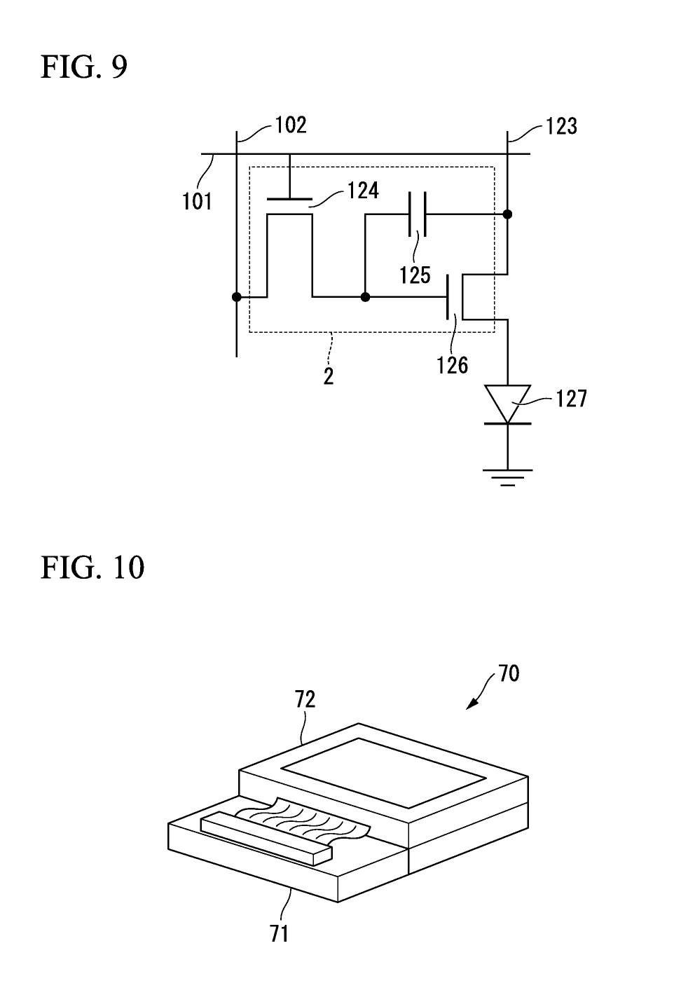

FIG. 8 is a diagram illustrating a configuration example of the connection between an interconnection structure and a drive circuit in a display device which includes the organic light-emitting element 20 according to the second embodiment and a drive portion. FIG. 9 is a diagram illustrating a circuit constituting one pixel which is arranged in a display device including the organic light-emitting element according to the embodiment.

As illustrated in FIG. 8, in a display device 70 according to the embodiment, scanning lines 101 and signal lines 102 are arranged on the substrate 1 of the organic light-emitting element 20 in a matrix shape when seen in a plan view. The respective scanning lines 101 are connected to a scanning circuit 103 which is provided at one edge of the substrate 1. The respective signal lines 102 are connected to an image signal drive circuit 104 which is provided at another edge of the substrate 1. More specifically, drive elements (TFT circuits 2) such as the thin film transistors of the organic light-emitting element 20 illustrated in FIG. 2 are provided in the vicinity of the respective intersections between the scanning lines 101 and the signal lines 102. The respective drive elements are connected to pixel electrodes. These pixel electrodes correspond to the reflective electrodes 11 of the organic light-emitting element 20 having the structure illustrated in FIG. 2, and these reflective electrodes 11 correspond to the first electrodes 12.

The scanning circuit 103 and the image signal drive circuit 104 are electrically connected to a controller 105 through control lines 106, 107, and 108. The operation of the controller 105 is controlled by a central processing unit 109. In addition, the scanning circuit 103 and the image signal drive circuit 104 are separately connected to a power circuit 112 through power distribution lines 110 and 111. The image signal output portion includes the CPU 109 and the controller 105.

The drive portion that drives the organic EL light-emitting portion 10 of the organic light-emitting element 20 includes the scanning circuit 103, the image signal drive circuit 104, and the organic EL power circuit 112. The respective regions which are partitioned by the scanning lines 101 and the signal lines 102 form the TFT circuits 2 of the organic light-emitting element 20 illustrated in FIG. 2.

FIG. 9 is a diagram illustrating a circuit constituting one pixel of the organic light-emitting element 20 which is arranged in one of the regions which are partitioned by the scanning lines 101 and the signal lines 102. In the pixel circuit illustrated in FIG. 9, when a scanning signal is applied to the scanning line 101, this signal is applied to a gate electrode of a switching TFT 124 configured by a thin film transistor and thus the switching TFT 124 is switched on. Next, when an image signal is applied to the signal line 102, this signal is applied to a source electrode of the switching TFT 124 and thus a storage capacitor 125, connected to a drain electrode of the switching TFT 124, is charged through the switching TFT 124 which has been switched on. The storage capacitor 125 is connected between a source electrode and a gate electrode of a driving TFT 126. Accordingly, as a gate voltage of the driving TFT 126a value is stored which is determined by a voltage of the storage capacitor 125 until the switching TFT 124 is subsequently scanned and selected. A power line 123 is connected to the power circuit (FIG. 8). A current supplied from the power line 123 flows to the organic light-emitting element (organic EL element) 127 through the driving TFT 126 to cause the organic light-emitting element 127 to continuously emit light.

Using the image signal output portion and the drive portion having such configurations, when a voltage is applied to the organic EL layer (organic layer) 17 which is interposed between the first electrode 12 and the second electrode 16 of a desired pixel, the organic light-emitting element 20 corresponding to the pixel emits light; light in a visible wavelength range can be emitted from the corresponding pixel; and as a result, a desired color or image can be displayed.

In the display device according to the embodiment, the example in which the above-described organic light-emitting element 20 according to the second embodiment is included as the light-emitting portion has been described. However, the embodiment is not limited thereto. The display device according to the embodiment can suitably include, as the light-emitting portion, any one of the above-described organic light-emitting element, wavelength-converting light-emitting element, and light-converting light-emitting element according to the second embodiment.

When the display device according to the embodiment includes, as the light-emitting portion, any one of the above-described organic light-emitting element, wavelength-converting light-emitting element, and light-converting light-emitting element using the luminescent material according to the embodiment, high luminous efficiency can be obtained.

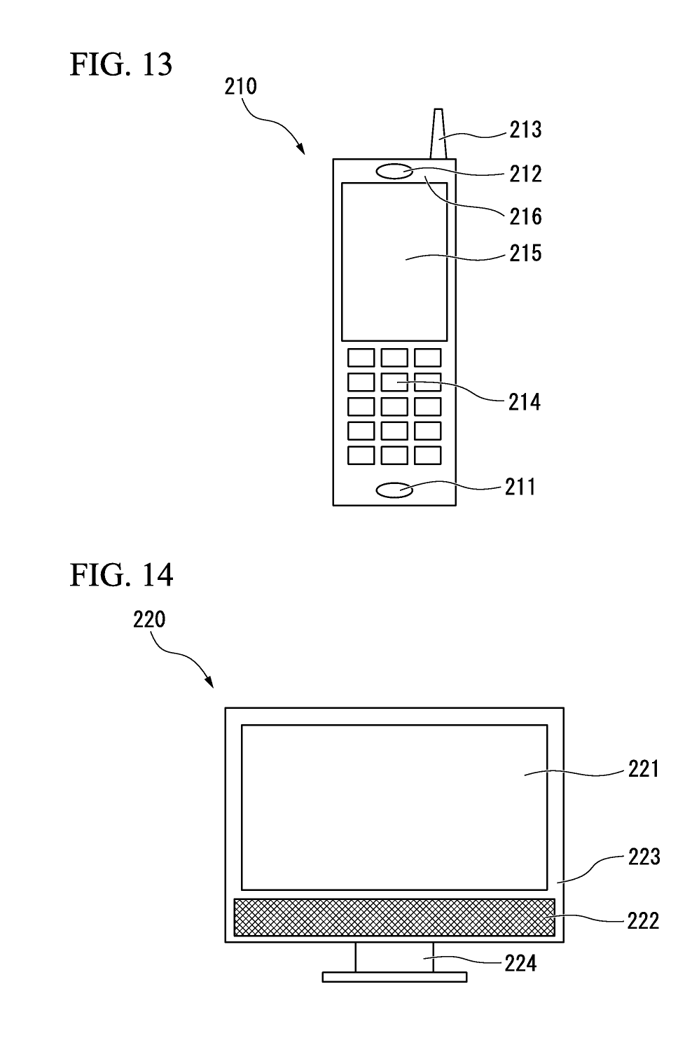

Needless to say, the display device according to the embodiment can be incorporated into various electronic apparatuses. Hereinafter, electronic apparatuses including the display device according to the embodiment will be described referring to FIGS. 13 to 16.

The display device according to the embodiment can be applied to, for example, a mobile phone illustrated in FIG. 13. The mobile phone 210 illustrated in FIG. 13 includes a voice input portion 211, a voice output portion 212, an antenna 213, a manipulation switch 214, a display portion 215, and a case 216. The display device according to the embodiment can be suitably applied to the display portion 215. When the display device according to the embodiment is applied to the display portion 215 of the mobile phone 210, an image can be displayed with a higher luminous efficiency.

The display device according to the embodiment can be applied to, for example, a thin-screen TV illustrated in FIG. 14. The thin-screen TV 220 illustrated in FIG. 14 includes a display portion 221, a speaker 222, a cabinet 223, and a stand 224. The display device according to the embodiment can be suitably applied to the display portion 221. When the display device according to the embodiment is applied to the display portion 221 of the thin-screen TV 220, an image can be displayed with a higher luminous efficiency.

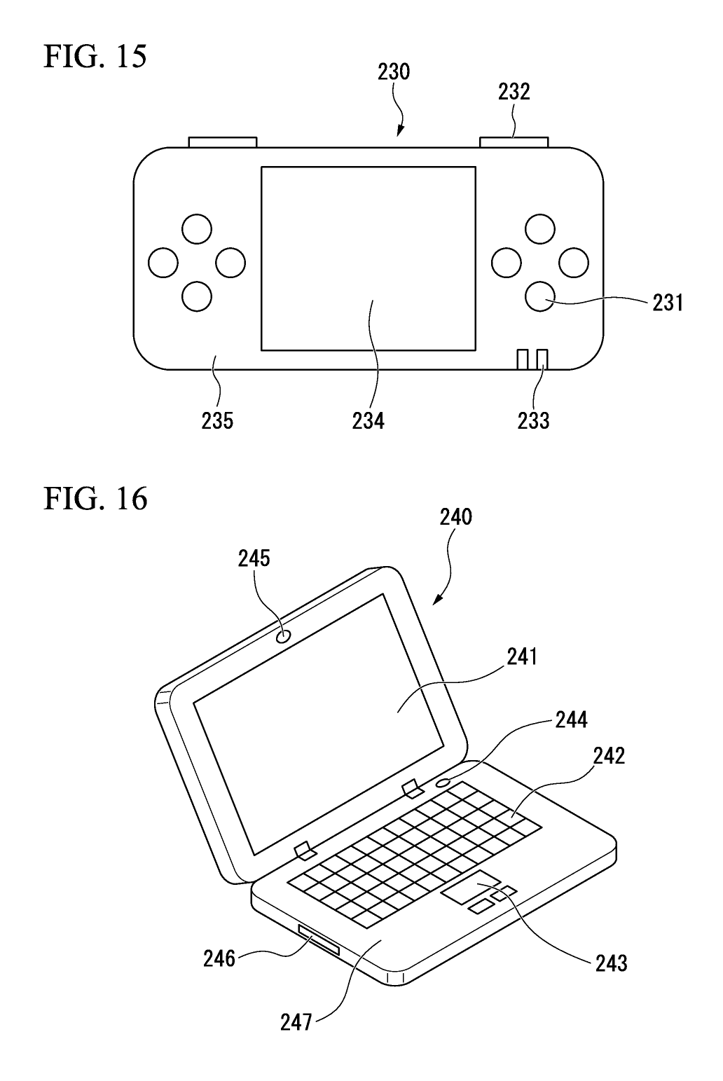

Furthermore, the display device according to the embodiment can be applied to, for example, a portable game machine illustrated in FIG. 15. The portable game machine 230 illustrated in FIG. 15 includes manipulation buttons 231 and 232, an external connection terminal 233, a display portion 234, and a case 235. The display device according to the embodiment can be suitably applied to the display portion 234. When the display device according to the embodiment is applied to the display portion 234 of the portable game machine 230, an image can be displayed with a higher luminous efficiency.

In addition, the display device according to the embodiment can be applied to a laptop computer illustrated in FIG. 13. The laptop computer 240 illustrated in FIG. 13 include a display portion 241, a keyboard 242, a touch panel 243, a main switch 244, a camera 245, a recording medium slot 246, and a case 247. The display device according to the embodiment can be suitably applied to the display portion 241 of the laptop computer 240. When the display device according to the embodiment is applied to the display portion 241 of the laptop computer 240, an image can be displayed with a higher luminous efficiency.

Hereinabove, preferable examples according to one aspect of the present invention have been described referring to FIGS. 13 to 16, but it is needless to say that the present invention is not limited to the examples. The shapes and combinations of the respective components illustrated in the above-described examples are merely examples and can be modified in various ways within a range not departing from the scope of the present invention based on the design requirements.

### <Illumination Device>

FIG. 10 is a perspective view schematically illustrating an embodiment of an illumination device according to an embodiment of the present invention. An illumination device 70 illustrated in FIG. 10 includes a drive portion 71 that applies a current or a voltage; and a light-emitting portion 72 that emits light based on the current or the voltage applied from the drive portion 71. In the illumination device according to the embodiment, the light-emitting portion 72 is configured as any one of the above-described organic light-emitting element, wavelength-converting light-emitting element, and light-converting light-emitting element according to the embodiments. In the following description, a case in which the light-emitting porting is the organic light-emitting element 10 according to the embodiment will be described as an example. However the embodiment is not limited thereto. In the illumination device according to the embodiment, the light-emitting portion can also be configured as the wavelength-converting light-emitting element or the light-converting light-emitting element.

In the illumination device 70 illustrated in FIG. 10, when the drive portion applies a voltage to the organic EL layer (organic layer) 17 which is interposed between the first electrode 12 and the second electrode 16, the organic light-emitting element 10 corresponding to the pixel emits light and thus blue light can be emitted. The organic light-emitting element 10 corresponds to a pixel selected by the drive portion.

When the organic light-emitting element 10 according to the embodiment is used as the light-emitting portion 72 of the display device 70, the organic light-emitting layer 14 of the organic light-emitting element 10 may contain a well-known organic EL material of the related art in addition to the luminescent material according to the embodiment.

In the illumination device 70 according to the embodiment, the example in which the above-described organic light-emitting element 10 according to the first embodiment is included as the light-emitting portion has been described. However, the embodiment is not limited thereto. The illumination device according to the embodiment can suitably include, as the light-emitting portion, any one of the above-described organic light-emitting element, wavelength-converting light-emitting element, and light-converting light-emitting element according to the first embodiments.

When the illumination device 70 according to the embodiment includes, as the light-emitting portion, any one of the above-described organic light-emitting element, wavelength-converting light-emitting element, and light-converting light-emitting element using the luminescent material according to the embodiment, high luminous efficiency can be obtained.

Needless to say, the illumination device according to the embodiment can be incorporated into various illumination apparatuses.

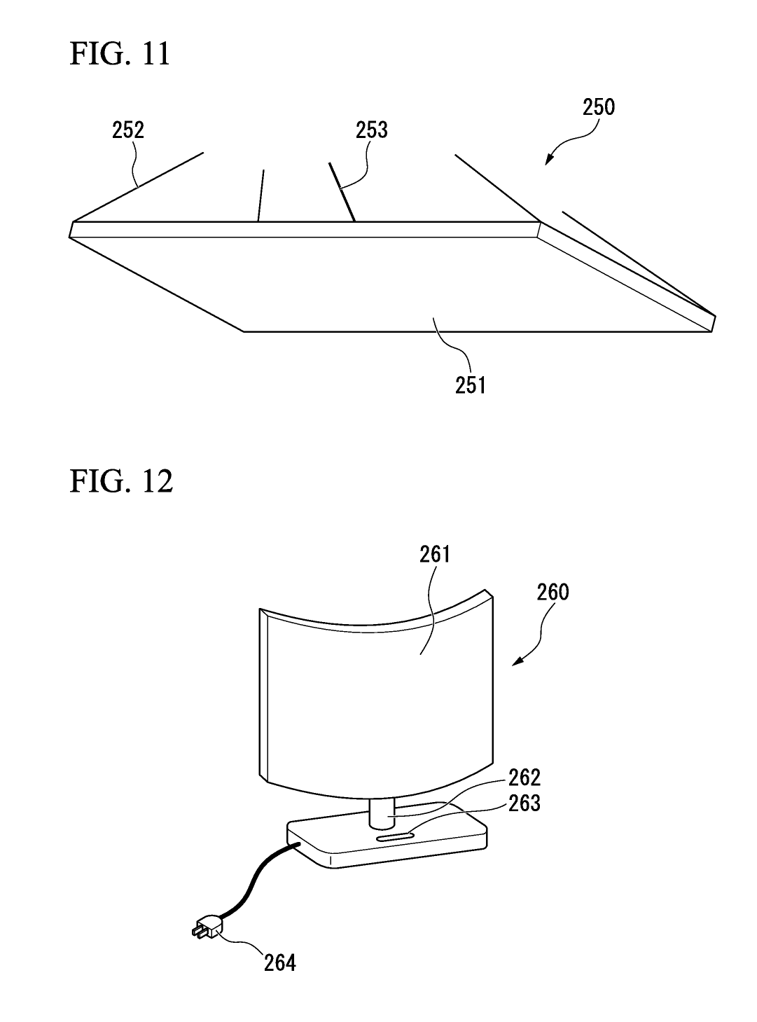

The organic light-emitting element, wavelength-converting light-emitting element, and light-converting light-emitting element according to the embodiments can also be applied to, for example, a ceiling light (illumination apparatus) illustrated in FIG. 11. The ceiling light 250 illustrated in FIG. 11 includes a light-emitting portion 251, a pendent line 252, and a power cord 253. The organic light-emitting element, wavelength-converting light-emitting element, and light-converting light-emitting element according to the embodiments can be applied to the light-emitting portion 251. When the ceiling light 250 according to the embodiment includes, as the light-emitting portion 261, any one of the above-described organic light-emitting element, wavelength-converting light-emitting element, and light-converting light-emitting element using the luminescent material according to the embodiment, high luminous efficiency can be obtained.

Likewise, the organic light-emitting element, wavelength-converting light-emitting element, and light-converting light-emitting element according to the embodiments can be applied to, for example, an illumination stand (illumination apparatus) illustrated in FIG. 12. The illumination stand 260 illustrated in FIG. 12 include a light-emitting portion 261, a stand 262, a main switch 263, and a power cord 264. The organic light-emitting element, wavelength-converting light-emitting element, and light-converting light-emitting element according to the embodiments can be suitably applied to the light-emitting portion 261. When the illumination stand 260 according to the embodiment includes, as the light-emitting portion 251, any one of the above-described organic light-emitting element, wavelength-converting light-emitting element, and light-converting light-emitting element using the luminescent material according to the embodiment, high luminous efficiency can be obtained.

For example, in the display device described in the embodiment, it is preferable that a polarizer be provided on a light extraction surface. As the polarizer, a well-known linear polarizer and a well-known λ/4 polarizer of the related art can be used in combination. Here, by providing such a polarizer, outside light reflection from the electrodes of the display device; or outside light reflection from a surface of the substrate or the sealing substrate can be prevented; and the contrast of the display device can be improved. In addition, the specific description relating to the shapes, numbers, arrangements, materials, formation methods, and the like of the respective components of the fluorescent substrate, the display device, and the illumination device are not limited to the above-described embodiments and can be appropriately modified.

### EXAMPLES

Hereinafter, the present invention will be described in detail based on Examples, but the present invention is not limited to these Examples.

Compounds used in Examples and Comparative Examples will be shown below. In the following structural formulae, Ph represents a phenyl group.

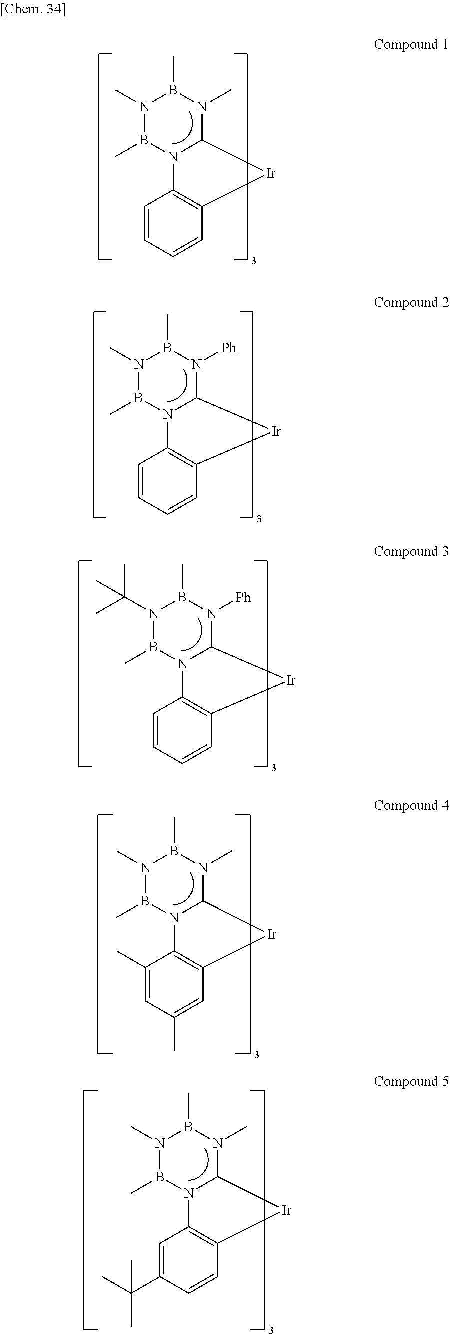

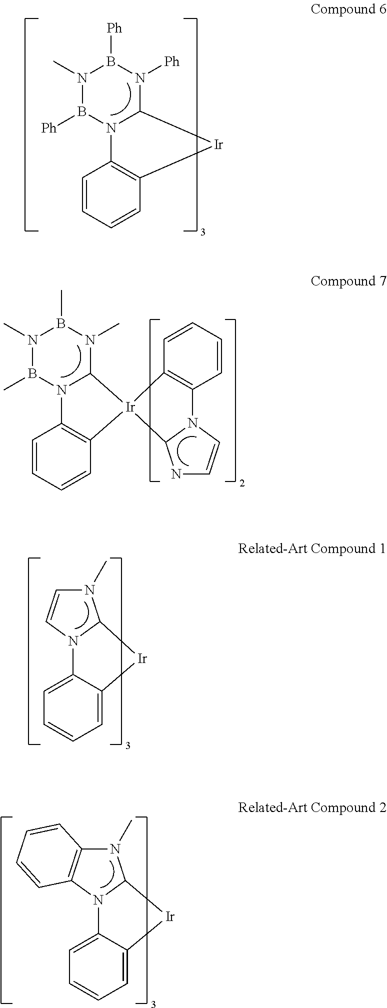

### [Synthesis of Transition Metal Complex]

In the following synthesis examples, compounds in the respective steps and a final compound (transition metal complex) were identified using MS spectrum (FAB-MS).

### Synthesis Example 1

### Synthesis of Compound 1

Compound 1 was synthesized according to the following route.

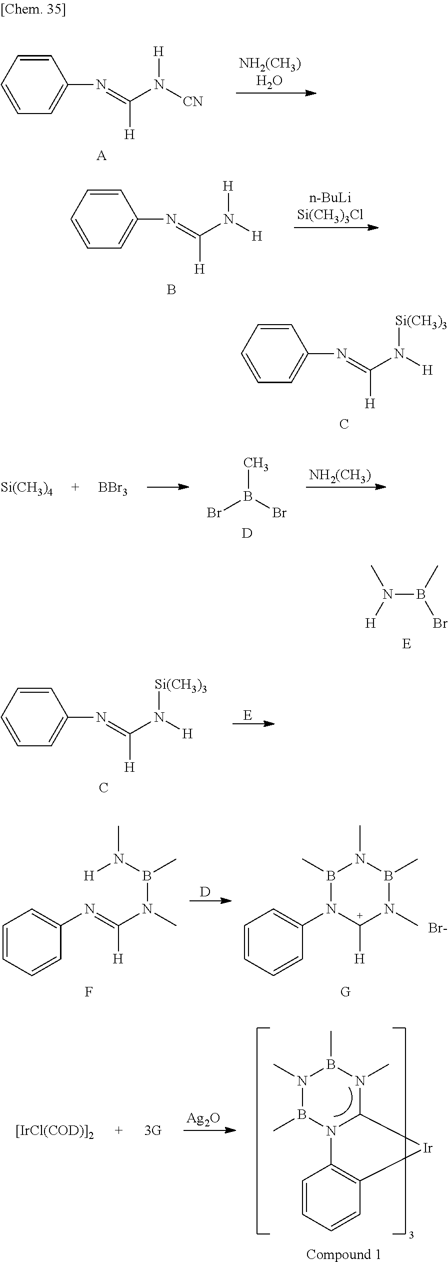

### Synthesis of Compound B:

Compound A (0.1 mol) was added dropwise to an aqueous methylamine solution (0.5 mol). After stirring for several minutes, a solid material precipitated. Water is added to the reaction solution and the solid material was separated by filtration in a liquid separating treatment, followed by drying. As a result, Compound B was obtained.

Yield: 82%

### Synthesis of Compound C

A hexane solution of n-BuLi (10.2 mmol) was slowly added to a solution in which Compound B (10.2 mmol) was dissolved in THF (tetrahydrofuran) at room temperature. After 30 minutes, trimethylsilyl chloride (10.2 mmol) was added thereto. Next, the solvent was removed under reduced pressure, followed by extraction with ether. As a result, Compound C was obtained. Yield: 93%

### Synthesis of Compound D:

Sn(CH₃)₄(5 mol) was added to BBr₃ (100 mol) at −50° C. under stirring, followed by stirring for 1 hour. Next, the solvent was removed under reduced pressure, followed by extraction with ether. As a result, Compound D was obtained. Yield: 80%

### Synthesis of Compound E:

n-BuLi (9 mmol) was added dropwise to a hexane solution in which methylamine (10 mmol) was dissolved at −10° C. A hexane solution (50 mL) of dibromomethylborane (Compound D: 9 mmol) was slowly added dropwise to this solution at −20° C. The temperature was returned to room temperature, followed by stirring for 1 day. Next, filtration was performed in order to remove LiCl and excess Li[N(H)CH₃]. Then, the solvent was removed under reduced pressure, followed by recrystallization with ether. As a result, Compound E was obtained. Yield: 70%

### Synthesis of Compound F:

A solution in which Compound E (10.2 mmol) was dissolved in 20 mL of toluene was added dropwise to a solution in which Compound C (10.2 mmol) was dissolved in 10 mL of toluene at −78° C. under stirring. The temperature was returned to room temperature, followed by stirring for 1 hour. The solvent was removed under reduced pressure, followed by extraction with ether. As a result, Compound F was obtained. Yield: 80%

### Synthesis of Compound G:

Dibromophenylborane (Compound D) and Compound F were dissolved in 20 mL of chloroform, followed by reflux for 1.5 days. The temperature was returned to room temperature. The solvent was removed under reduced pressure and a residue was washed with hexane. As a result, Compound G was obtained. Yield: 82%

### Synthesis of Compound 1:

[IrCl(COD)]₂ (COD=1,5-cyclooctadiene) (0.15 mmol), Compound G (0.90 mmol), and silver oxide (0.90 mmol) were added to 2-ethoxyethanol (10 mL), followed by reflux for 24 hours under light-shading conditions. Purification was performed by flash chromatography (silica gel/chloroform). Furthermore, the resultant was dissolved in dichloromethane and hexane was added thereto, followed by recrystallization. As a result, Compound 1 having a desired mer isomer was obtained.

Yield: 45%, FAB-MS (+): m/e=832

### Synthesis Example 2

### Synthesis of Compound 2

Compound 2 was synthesized according to the following route.

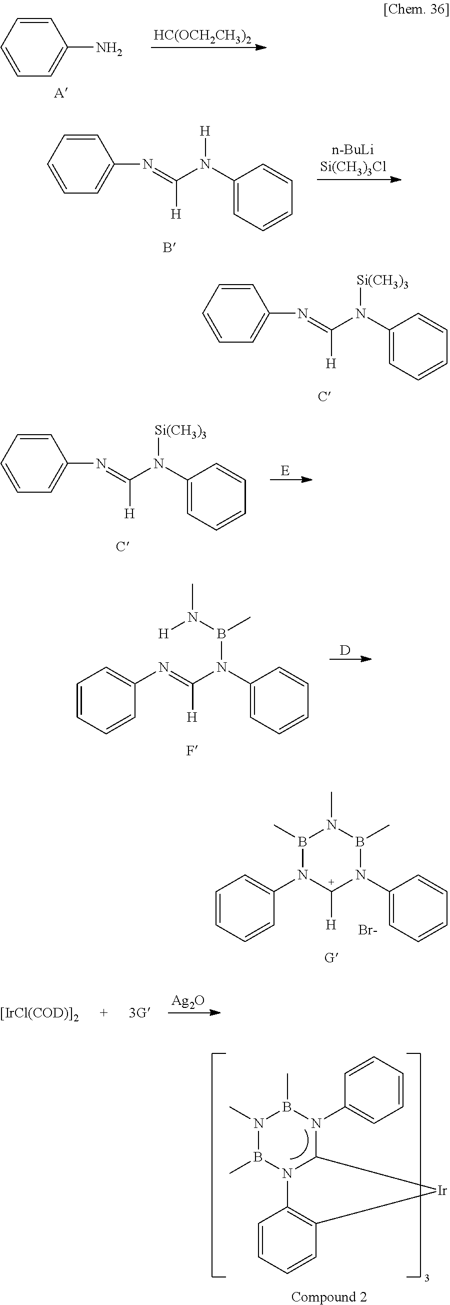

### Synthesis of Compound B′:

A mixture of diethoxymethane (0.05 mol), aniline (Compound A′, 0.1 mol), and 0.25 mL of glacial acetic acid was heated to reflux for 2 hours. By-products and unreacted materials were removed under reduced pressure. As a result, Compound B′ was obtained. Yield: 80%

Compound D and Compound E were the same materials used in the synthesis of Compound 1. Compound C′, Compound F′, and Compound G′ were synthesized under conditions of the same equivalent relationship and the same reaction temperature as those of Compound 1.

### Synthesis of Compound 2:

Compound 2 was synthesized under conditions of the same equivalent relationship and the same reaction temperature as those of Compound 1. Recrystallization was performed with chloroform. As a result, Compound 2 having a desired mer isomer was obtained as a white solid material. Yield: 80%, FAB-MS (+): m/e=1018

### Synthesis Example 3

### Synthesis of Compound 3

Compound 3 (mer isomer) was obtained with the same synthesis method as that of Synthesis Example 2, except that N-(bromo(methyl)boryl)-2-methylpropan-2-amine was used instead of Compound E. Yield: 60%, FAB-MS (+): m/e=1143

### Synthesis Example 4

### Synthesis of Compound 4

Compound 4 (mer isomer) was obtained with the same synthesis method as that of Synthesis Example 1, except that (E)-N-cyano-N-(2,4-dimethylphenyl) formamidine was used instead of Compound A. Yield: 70%, FAB-MS (+): m/e=915 (Synthesis Example 5: Synthesis of Compound 5)

Compound 5 (mer isomer) was obtained with the same synthesis method as that of Synthesis Example 1, except that (E)-N′-(4-tert-butylphenyl)-N-cyanoformamidine was used instead of Compound A. Yield: 72%, FAB-MS (+): m/e=999

### Synthesis Example 6

### Synthesis of Compound 6

Compound 6 (mer isomer) was obtained with the same synthesis method as that of Synthesis Example 2, except that N-(bromo(phenyl)boryl)methaneamine was used instead of Compound D; and dibromo(phenyl)borane was used instead of Compound E.

Yield: 65%, FAB-MS (+): m/e=1516

### Synthesis Example 7

### Synthesis of Compound 7

Compound 7 was synthesized according to the following route.

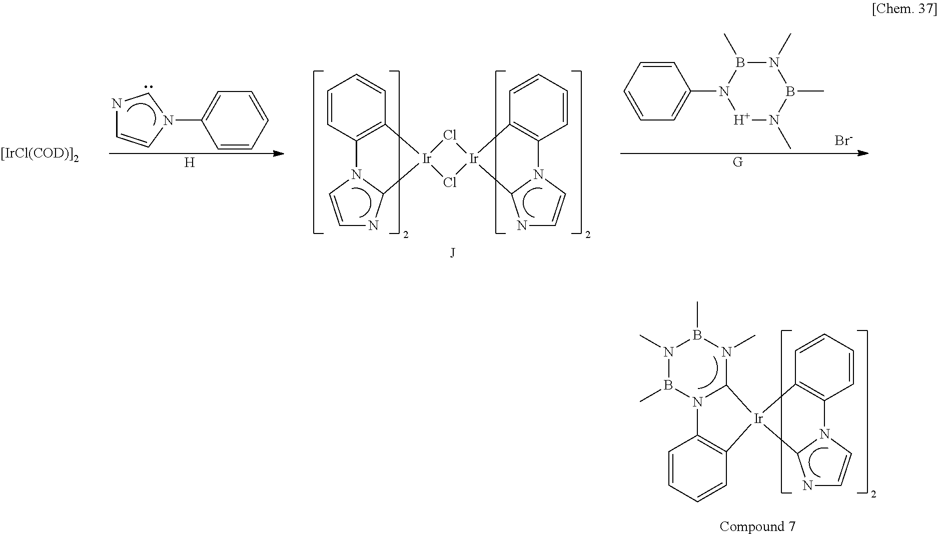

### Synthesis of Compound J:

A 2-ethoxyethanol solution in which 4 equivalents of Compound H and an excess amount of sodium methoxide were mixed with 1 equivalent of [IrCl(COD)]₂ (COD=1,5-cyclooctadiene) was heated to reflux for 3 hours, followed by separation by chromatography. As a result, Compound J was obtained. Yield: 50%

### Synthesis of Compound 7:

A mixed solution of Compound J (0.08 mmol), Compound G (0.16 mmol), silver oxide (1.0 mmol), and 20 mL of THF were heated to reflux for 3 hours. Then, the reaction solution was separated by chromatography. As a result, Compound 7 (mer isomer) was obtained. Yield: 60%, FAB-MS (+): m/e=691

### Example 1

Regarding Compound 1 and Compound 3, the PL quantum yields of a mixed complex containing a fac isomer and a mer isomer (fac isomer:mer isomer=5:1); and a complex containing only a mer isomer in a deaerated toluene solution were obtained. The PL quantum yields were measured according to the following order. First, the emission spectrum of each compound was measured using a PL measurement device FluoroMax-4 (manufactured by Horiba Ltd., excitation wavelength: 380 nm), and the absorbance was measured using an absorbance measurement device UV-2450 (manufactured by Shimadzu Corporation). Next, the PL quantum yield was calculated by matching the absorbance at the excitation wavelength (380 nm) between the well-known reference material fac-Ir(ppy)₃ and each compound and comparing the emission intensities to each other. The results thereof are shown in Table 1.

TABLE 1

| | | PL Quantum Yield |
|---|---|---|
| Compound 1 | fac isomer + mer isomer | 60% |
| | Only isomer | 72% |
| Compound 3 | fac isomer + mer isomer | 63% |
| | Only isomer | 70% |

It was confirmed from the results of Table 1 that the complex containing only a mer isomer had a higher PL quantum yield than that of a mixed complex containing a fac isomer and a mer isomer; and in Compounds 1 and 3 which are the luminescent materials according to this example, a mer isomer had a higher PL quantum yield that that of a fac isomer.

### Preparation of Organic Light-Emitting Material and Evaluation for Organic EL Characteristic

### Example 2

A silicon semiconductor film was formed on a glass substrate with a plasma chemical vapor deposition (plasma CVD) method, followed by crystallization. As a result, a polycrystalline semiconductor film (polycrystalline silicon thin film) was formed. Next, the polycrystalline silicon thin film was etched to form plural island-shaped patterns. Next, silicon nitride (SiN) was formed on each island structure of the polycrystalline silicon thin film as a gate insulating film. Next, a laminated film of titanium (Ti)-aluminum (Al)-titanium (Ti) was sequentially formed as a gate electrode, followed by etching and patterning. A source electrode and a drain electrode were formed on the gate electrode using Ti—Al—Ti to prepare plural thin film transistors (TFT).

Next, an interlayer dielectric having a through-hole was formed on each of the formed thin film transistors for planarization. Then, indium tin oxide (ITO) was formed as an anode through the through-hole. A single layer of polyimide-based resin was patterned so as to surround the ITO electrode. Then, a substrate on which the ITO electrode was formed was washed with ultrasonic waves, followed by baking at 200° C. under reduced pressure for 3 hours.

Next, 4,4′-bis[N-(1-naphthyl)-N-phenyl-amino]biphenyl (α-NPD) was deposited on the anode using a vacuum deposition method at a deposition rate of 1 angstrom/sec to form a hole injection layer with a thickness of 45 nm on the anode.

Next, N,N-dicarbazolyl-3,5-benzene (mCP) was deposited on the hole injection layer using a vacuum deposition method at a deposition rate of I angstrom/sec to form a hole transport layer with a thickness of 15 nm on the hole injection layer.

Next, 2,8-bis(diphenylphosphoryl)dibenzothiophene (PPT) (thickness: 50 nm) was deposited on the hole transport layer.

Next, UGH 2 (1,4-bis(triphenylsilyl)benzene) and Compound 1 (mer isomer) were co-evaporated on the hole transport layer using a vacuum deposition method to form an organic light-emitting layer. At this time, UGH 2 which was the host material was doped with approximately 7.5% of Compound 1. Next, UGH 2 with a thickness of 5 nm was formed on the organic light-emitting layer as a hole blocking layer. Furthermore, 1,3,5-tris(N-phenylbenzimidazol-2-yl)benzene (TPBI) was deposited on the hole blocking layer using a vacuum deposition method. As a result, an electron transport layer with a thickness of 30 nm was formed on the hole blocking layer.

Next, lithium fluoride (LiF) was deposited on the electron transport layer using a vacuum deposition method at a deposition rate of 1 angstrom/sec. As a result, a LiF film with thickness of 0.5 nm was formed. Next, an aluminum (Al) film with a thickness of 100 nm was formed on the LiF film. In this way, the laminated film of LiF and Al was formed as a cathode. As a result, an organic EL element (organic light-emitting element) was prepared.

The current efficiency (luminous efficiency) of the obtained organic EL at 1000 cd/m² was measured. As a result, the current efficiency was 12.2 cd/A and the emission wavelength was 2.8 eV (440 nm), and highly efficient blue light emission was exhibited.

### Examples 3 to 8 and Comparative Examples 1 and 2

Organic EL elements (organic light-emitting elements) were prepared with the same preparation method as that of Example 2, except that dopants (luminescent materials) with which the organic light-emitting layers were doped were changed to compounds shown in Table 2. The current efficiency (luminous efficiency) and emission wavelength of each of the obtained organic EL element at 1000 cd/m² were measured.

The results are shown in Table 2. In Examples 3 to 8, mer isomers were used, and in Comparative Examples 1 and 2, mer isomers were used.

TABLE 2

| | | | Emission | |
|---|---|---|---|---|
| | Dopant | Luminous | Wavelength | |
| | (Luminescent Material) | Efficiency (cd/A) | (eV) | (nm) |
| Example 4 | Compound 1 | 12.2 | 2.8 | 440 |
| Example 5 | Compound 2 | 12.5 | 2.7 | 459 |
| Example 6 | Compound 3 | 12.1 | 2.7 | 459 |
| Example 7 | Compound 4 | 12.1 | 2.8 | 443 |
| Example 8 | Compound 5 | 12.3 | 2.8 | 443 |
| Example 9 | Compound 6 | 12.3 | 2.6 | 477 |
| Example 10 | Compound 7 | 10.3 | 2.9 | 428 |
| Example 1 | Related-Art Compound 1 | 4.0 | 3.1 | 400 |
| Example 2 | Related-Art Compound 2 | 4.2 | 3.0 | 413 |

According to the results of Table 2, the organic EL elements using Compounds 1 to 7 which are the luminescent materials according to Examples had a higher luminous efficiency (current efficiency) than that of the organic EL elements using Related-Art Compounds 1 and 2 as the luminescent material. In addition, the other compounds except Compound 6 had an emission wavelength of 460 nm or lower (2.69 eV or higher) and exhibited highly efficient blue light emission.

### Preparation of Wavelength-Converting Light-Emitting Element

### Example 9

In this example, using the organic blue light-emitting elements (organic EL elements) containing the luminescent materials according to Examples, a wavelength-converting light-emitting element which converted light emitted from the organic light-emitting element into light in a red wavelength and a wavelength-converting light-emitting element which converted light emitted from the organic light-emitting element into light in a green wavelength were prepared, respectively.

### <Preparation of Organic EL Substrate>

A silver film with a thickness of 100 nm was formed on a glass substrate with a thickness of 0.7 mm using a sputtering method to form a reflective electrode. An indium-tin oxide (ITO) film having a thickness of 20 nm was formed on the silver film using a sputtering method to form a reflective electrode (anode) as a first electrode. Then, the first electrode was patterned using a well-known photolithography method so as to have 90 stripe patterns with a width of 2 mm.

Next, a SiO₂ layer with a thickness of 200 nm was laminated on the first electrode (reflective electrode) using a sputtering method and then was patterned using a well-known photolithography method so as to cover edge portions of the first electrode (reflective electrode). As a result, an edge cover was formed. The edge cover had a structure in which short sides of the reflective electrode were covered with SiO₂ by 10 m from the edges. The resultant was washed with water, followed by washing with pure water and ultrasonic waves for 10 minutes, washing with acetone and ultrasonic waves for 10 minutes, washing with isopropyl alcohol steam for 5 minutes, and drying at 100° C. for 1 hour.

Next, the dried substrate was fixed to a substrate holder in an inline type resistance heating deposition device. The pressure was reduced to a vacuum of 1×10⁻⁴ Pa or lower, and respective organic layers of the organic EL layer were formed.

First, using 1,1-bis-di-4-tolylamino-phenyl-cyclohexane (TAPC) as a hole injection material, a hole injection layer with a thickness of 100 nm was formed with a resistance heating deposition method.

Next, using N,N′-di-[(1-naphthyl)-N,N′-diphenyl]-1,1′-biphenyl-1, 1′-biphenyl-4,4′-diamine (NPD) as a hole transport material, a hole transport layer having a thickness of 40 nm was formed on the hole injection layer with a resistance heating deposition method.

Next, an organic blue light-emitting layer (thickness: 30 nm) was formed at a desired pixel position on the hole transport layer. This organic blue light-emitting layer was prepared by co-evaporating 1,4-bis(triphenylsilyl)benzene (UGH-2; host material) and Compound 1 at deposition rates of 1.5 angstrom/sec and 0.2 angstrom/sec, respectively.

Next, using 2,9-dimethyl-4,7-diphenyl-1,10-phenanthroline (BCP), a hole blocking layer (thickness: 10 nm) was formed on the organic light-emitting layer.

Next, using tris(8-hydroxyquinoline)aluminum (Alq3), an electron transport layer (thickness: 30 nm) was formed on the hole blocking material.

Next, using lithium fluoride (LiF), an electron injection layer (thickness: 0.5 nm) was formed on the electron transport layer.

Through the above-described processes, the respective organic layers of the organic EL layer were formed.

Next, a semitransparent electrode was formed on the electron injection layer as a second electrode. In order to form the second electrode, first, the substrate on which the electron injection layer was formed in the above-described process was fixed to a metal deposition chamber. Then, a shadow mask for forming the semitransparent electrode (second electrode) and the substrate were aligned. As the shadow mask, a mask having openings is used so as to form the semitransparent electrodes (second electrodes) in a stripe shape having a width of 2 mm in a direction opposite the reflective electrodes (first electrodes) in a stripe shape. Next, magnesium and silver were co-evaporated on a surface of the electron injection layer of the organic EL layer at deposition rates of 0.1 angstrom/sec and 0.9 angstrom/sec to form desired patterns of magnesium and silver (thickness: 1 nm). Furthermore, a desired pattern of silver (thickness: 19 nm) was formed thereon at a deposition rate of 1 angstrom/sec in order to enhance the interference effect and to prevent voltage drop due to interconnection resistance in the second electrode. Through the above-described processes, the semitransparent electrode (second electrode) was formed. Here, the microcavity effect (interference effect) was exhibited between the reflective electrode (first electrode) and the semitransparent electrode (second electrode), which can improve the luminance on the front side.

Through the above-described processes, the organic EL substrate on which the organic EL portion is formed is prepared.

### <Preparation of Fluorescent Substrate>

Next, a red fluorescent layer was formed on a glass substrate equipped with a red color filter with a thickness of 0.7 mm, and a green fluorescent layer was formed on a glass substrate equipped with a green color filter with a thickness of 0.7 mm.

The red fluorescent layer was formed according to the following order. First, 15 g of ethanol and 0.22 g of γ-glycidoxypropyl triethoxysilane were added to 0.16 g of aerosol having an average particle size of 5 nm, followed by stirring for 1 hour at room temperature in open system. This mixture and 20 g of red fluorescent material (pigment) K₅Eu_{2.5}(WO₄)_{6.25} were put into a mortar and pounded, followed by heating with an oven at 70° C. for 2 hours and heating with an oven at 120° C. for 2 hours. As a result, a surface-modified K₅Eu_{2.5}(WO₄)_{6.25} was obtained. Next, 30 g of polyvinyl alcohol in which a mixed solution (300 g; water/dimethylsulfoxide=1/1) was dissolved was added to 10 g of the surface-modified K₅Eu_{2.5}(WO₄)_{6.25}, followed by stirring with a disperser. As a result, a red fluorescent layer-forming coating solution was prepared. The red fluorescent layer-forming coating solution was coated at a red pixel position on a CF-equipped glass substrate using a screen printing method so as to have a width of 3 mm. Next, the resultant was heated and dried with a vacuum oven (under conditions of 200° C. and 10 mmHg) for 4 hours. As a result, a red fluorescent layer having a thickness of 90 m was formed.

The green fluorescent layer was formed according to the following order. First, 15 g of ethanol and 0.22 g of γ-glycidoxypropyl triethoxysilane were added to 0.16 g of aerosol having an average particle size of 5 nm, followed by stirring for 1 hour at room temperature in open system. This mixture and 20 g of green fluorescent material (pigment) Ba₂SiO₄:Eu²⁺ were put into a mortar and pounded, followed by heating with an oven at 70° C. for 2 hours and heating with an oven at 120° C. for 2 hours. As a result, a surface-modified Ba₂SiO₄:Eu²⁺ was obtained. Next, 30 g of polyvinyl alcohol (resin) in which a mixed solution (300 g, solvent; water/dimethylsulfoxide=1/1) was dissolved was added to 10 g of the surface-modified Ba₂SiO₄:Eu²⁺, followed by stirring with a disperser. As a result, a green fluorescent layer-forming coating solution was prepared. The green fluorescent layer-forming coating solution was coated at a green pixel position on a CF-equipped glass substrate 16 using a screen printing method so as to have a width of 3 mm. Next, the resultant was heated and dried with a vacuum oven (under conditions of 200° C. and 10 mmHg) for 4 hours. As a result, a green fluorescent layer with a thickness of 60 μm was formed.

Through the above-described processes, a fluorescent substrate on which the red fluorescent layer was formed and a fluorescent substrate on which the green fluorescent layer was formed were prepared, respectively.

### <Assembly of Wavelength-Converting Light-Emitting Elements>

Regarding the wavelength-converting red light-emitting element and the wavelength-converting green light-emitting element, the organic EL substrate and each of the fluorescent substrates prepared as described above were aligned according to alignment markers which were formed outside a pixel arrangement position. Each of the fluorescent substrates were coated with a thermosetting resin before the alignment.

After the alignment, both substrates are bonded to each other through the thermosetting resin, followed heating at 90° C. for 2 hours to perform curing. The bonding process of both substrates are performed in a dry air environment (water content: −80° C.) in order to prevent the organic EL layer from deteriorating due to water.

A peripheral terminal of each of the obtained wavelength-converting light-emitting elements is connected to an external power supply. As a result, superior green light emission and red light emission can be obtained.

### Preparation of Display Device

### Example 10

Display devices in which the organic light-emitting elements (organic EL elements) prepared in Examples 2 to 8 were respectively arranged in a 100×100 matrix shape were prepared, and a moving image was displayed thereon. Each of the display devices includes an image signal output portion that outputs an image signal; a drive portion that includes a scanning electrode drive circuit and a signal drive circuit which output the image signal from the image signal output portion; and a light-emitting portion that includes organic light-emitting elements (organic EL element) which are arranged in a 100×100 matrix shape. In all the display devices, an image having a high color purity was obtained. In addition, even when plural display devices were prepared, there were no variations between the devices and the in-plane uniformity was superior.

### Preparation of Illumination Device

### Example 11

An illumination device including a drive portion that applies a current; and a light emitting portion that emits light based on the current applied from the drive portion, was prepared. In this example, organic light-emitting elements (organic EL elements) were respectively prepared with the same preparation methods as those of Examples 2 to 8, except that the organic light-emitting elements (organic EL elements) were formed on a film substrate. Each of the organic light-emitting elements was used as the light-emitting portion. When a voltage is applied to this organic light-emitting device for lighting, a surface-emitting illumination device having a uniform lighting surface was obtained without using indirect illumination resulting in luminance loss. In addition, the prepared illumination device can be used as a backlight of a liquid crystal display panel.

### Preparation of Light-Converting Light-Emitting Element

### Example 12

The light-converting light-emitting element illustrated in FIG. 5 was prepared.

The light-converting light-emitting element was prepared according to the following order. First, the same processes as those of Example 1 were performed until the electron transport layer formation. Then, a NTCDA (naphthalene tetracarboxylic dianhydride) layer with a thickness of 500 nm was formed on the electron transport layer as a photoelectric material layer. Next, an Au thin film with a thickness of 20 nm was formed on the NTCDA layer to form an Au electrode. Here, a part of the Au electrode was led out to an end of the element substrate through a desired pattern interconnection, which was integrally formed of the same material, to be connected to a negative terminal of a drive power supply. Likewise, a part of the ITO electrode was led out to an end of the element substrate through a desired pattern interconnection, which was integrally formed of the same material, to be connected to a positive terminal of the drive power supply. In addition, this pair of electrodes (ITO electrode and Au electrode) were configured such that a predetermined voltage was applied therebetween.

A voltage was applied to the light-converting light-emitting element prepared through the above-described processes using the ITO electrode as the anode. When the Au electrode was irradiated with monochromatic light having a wavelength of 335 nm, the photoelectric current and the illuminance (wavelength: 442 nm) of light emitted from Compound 1 were measured with respect to the applied voltage, respectively. When the measurement was performed with respect to the applied voltage, the photocurrent multiplication effect was observed at 20 V

### Preparation of Dye Laser

### Example 13

The dye laser illustrated in FIG. 7 was prepared.

The dye laser having a configuration in which Compound 1 (in a deaerated acetonitrile solution; concentration 1×10⁴M) was used as a laser dye in an XeCl excimer (excitation wavelength: 308 nm) was prepared. The emission wavelength was 430 nm to 450 nm, and a phenomenon in which the intensity was increased in the vicinity of 440 nm was observed.

### Preparation of Organic Laser Diode Light-Emitting Element

### Example 14

Referring to H. Yamamoto et al., Appl. Phys. Lett., 2004, 84, 1401, an organic laser diode light-emitting element having the configuration illustrated in FIG. 6 was prepared.

The organic laser diode light-emitting element was prepared according to the following order. First, the same processes as those of Example 1 were performed until the formation of the anode.

Next, 4,4′-bis[N-(1-naphthyl)-N-phenyl-amino]biphenyl (α-NPD) was deposited on the anode using a vacuum deposition method at a deposition rate of 1 angstrom/sec to form a hole injection layer with a thickness of 20 nm on the anode.

Next, N,N-dicarbazolyl-3,5-benzene (mCP) and Compound 1 (mer isomer) were co-evaporated on the hole injection layer using a vacuum deposition method to form an organic light-emitting layer. At this time, mCP which was the host material was doped with approximately 5.0% of Compound 1. Next, 1,4-bis(triphenylsilyl)benzene (UGH-2) with a thickness of 5 nm was formed on the organic light-emitting layer as a hole blocking layer. Furthermore, 1,3,5-tris(N-phenylbenzimidazol-2-yl)benzene (TPBI) was deposited on the hole blocking layer using a vacuum deposition method. As a result, an electron transport layer with a thickness of 30 nm was formed on the hole blocking layer.

Next, MgAg (9:1, thickness: 2.5 nm) was deposited on the electron transport layer using a vacuum deposition method. Then, an ITO layer having a thickness of 20 nm was formed using a sputtering method. As a result, the organic laser diode light-emitting element was prepared.

The prepared organic laser diode light-emitting element was irradiated with laser beams (Nd:YAG laser SHG, 532 nm, 10 Hz, 0.5 ns) from the anode side to investigate ASE oscillation characteristics. When the laser beam irradiation is performed while changing the excitation intensity, the oscillation starts at 1.0 J/cm² and ASE in which the peak intensity is increased in proportion to the excitation intensity was observed.

### INDUSTRIAL APPLICABILITY

The luminescent material according to the embodiments of the present invention is applicable to an organic electroluminescence element (organic EL element), a wavelength-converting light-emitting element, a light-converting light-emitting element, a photoelectric converting element, a laser dye, an organic laser diode element, and the like; and is also applicable to a display device and an illumination device using the respective light-emitting elements.

### REFERENCE SIGNS LIST

1 substrate
2 TFT circuit
2a, 2b interconnection
3 interlayer dielectric
4 planarizing film
5 inorganic sealing film
6 sealing material
7 black matrix
8R red color filter
8G green color filter
8B blue color filter
9 sealing substrate
8B blue fluorescence-converting layer
10, 20 organic light-emitting element (organic EL element, light source)
11 reflective electrode
12 first electrode (reflective electrode)
13 hole transport layer
14 organic light-emitting layer
15 electron transport layer
16 second electrode (reflective electrode)
17 organic EL layer (organic layer)
18R red fluorescent layer
18G green fluorescent layer
19 edge cover
30 wavelength-converting light-emitting element
31 scattering layer
40 light-converting light-emitting element
50 organic layer diode element
60 dye laser
70 illumination device

1. A luminescent material comprising:
a transition metal complex, wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

2. The luminescent material according to claim 1,
wherein the transition metal complex includes a partial structure represented by the following formula (1) or (2). 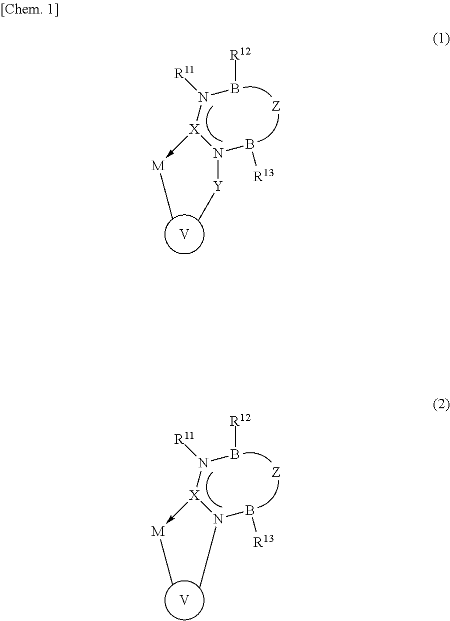
(In the formulae (1) and (2), M represents Ir, Os, or Pt; X represents C or Si; R¹¹, R¹², and R¹³ each independently represent a monovalent organic group; Y represents a divalent hydrocarbon group; Z represents a divalent organic group; and V represents a divalent organic group having a ring structure.)

3. The luminescent material according to claim 1,
wherein the transition metal complex includes a partial structure represented by the following formula (3) or (4). 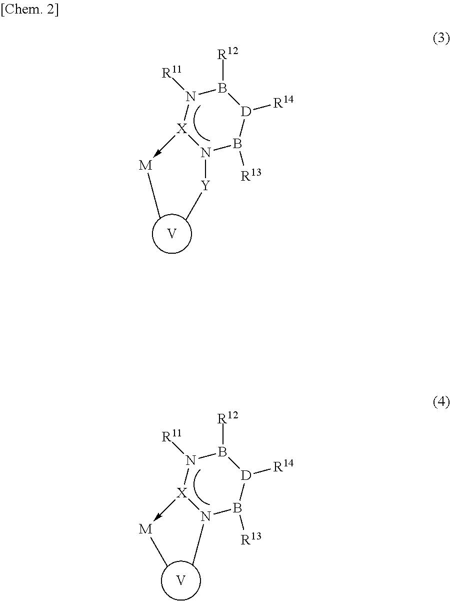
(In the formulae (3) and (4), M represents Ir, Os, or Pt; X represents C or Si; R¹¹, R¹², R¹³, and R¹⁴ each independently represent a monovalent organic group; Y represents a divalent hydrocarbon group; D represents an electron-donating atom; and V represents a divalent organic group having a ring structure.)

4. The luminescent material according to claim 1,
wherein the transition metal complex includes a partial structure represented by the following formula (5) or (6). 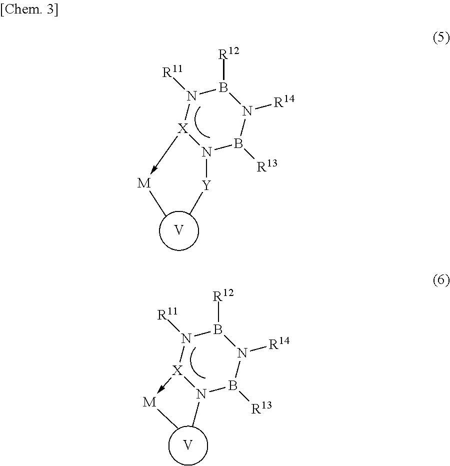
(In the formulae (5) and (6), M represents Ir, Os, or Pt; X represents C or Si; R¹¹, R¹², R¹³ and R¹⁴ each independently represent a monovalent organic group; Y represents a divalent hydrocarbon group; and V represents a divalent organic group having a ring structure.)

5. The luminescent material according to claim 1, wherein the transition metal complex includes a partial structure represented by the following formula (7) or (8). 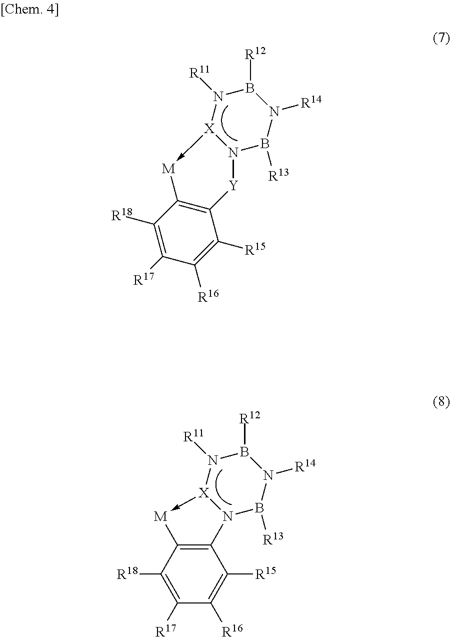
(In the formulae (7) and (8), M represents Ir, Os, or Pt; X represents C or Si; R¹¹, R¹², R¹³, R¹⁴, R¹⁵, R¹⁶, R¹⁷, and R¹⁸ each independently represent a monovalent organic group; and Y represents a divalent hydrocarbon group.)

6. The luminescent material according to claim 1,
wherein the transition metal complex is an Ir complex including a partial structure represented by the following formula (9). 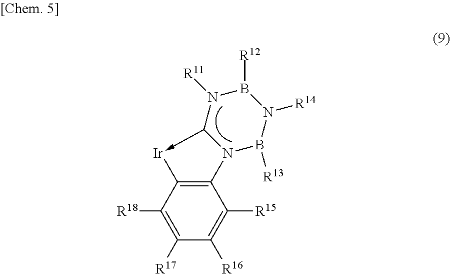
(In the formula (9), R¹¹, R¹², R¹³, R¹⁴, R¹⁵, R¹⁶, R¹⁷, and R¹⁸ each independently represent a monovalent organic group.)

7. The luminescent material according to claim 1,
wherein the transition metal complex is a tris complex in which three bidentate ligands are coordinated, and
wherein the amount of a mer (meridional) isomer contained in the transition metal complex is greater than that of a fac (facial) isomer.

8. An organic light-emitting element comprising:
at least one organic layer that includes a light-emitting layer; and
a pair of electrodes between which the organic layer is interposed,
wherein the organic layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

9. The organic light-emitting element according to claim 8,
wherein the light-emitting layer includes the metal transition complex.

10. A wavelength-converting light-emitting element comprising:
an organic light-emitting element; and
a fluorescent layer which is disposed on a side of extracting light from the organic light-emitting element, wherein the fluorescent layer absorbs the light emitted from the organic light-emitting element and emits light having a different wavelength from that of the absorbed light,
wherein the organic light-emitting element includes at least one organic layer that includes a light-emitting layer and a pair of electrodes between which the organic layer is interposed,
wherein the organic layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

11. A wavelength-converting light-emitting element comprising:
a light-emitting element; and
a fluorescent layer which is disposed on a side of extracting light from the light-emitting element, wherein the fluorescent layer absorbs light emitted from the light-emitting element and emits light having a different wavelength from that of the absorbed light,
wherein the fluorescent layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

12. A light-converting light-emitting element comprising:
at least one organic layer that includes a light-emitting layer;
a layer for multiplying a current; and
a pair of electrodes between which the organic layer and the layer for multiplying a current are interposed,
wherein the light-emitting layer includes a host material and a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

13. An organic laser diode light-emitting element comprising:
an excitation light source; and
a resonator structure that is irradiated with light emitted from the excitation light source,
wherein the resonator structure includes at least one organic layer that includes a laser-active layer and a pair of electrodes between which the organic layer is interposed,
wherein the laser active layer includes a host material and a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

14. A dye laser comprising:
a laser medium that includes a luminescent material; and
an excitation light source that stimulates the luminescent material of the laser medium to emit phosphorescence and to perform laser oscillation,
wherein the luminescent material is a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

15. A display device comprising:
an image signal output portion that outputs an image signal;
a drive portion that applies a current or a voltage based on the signal output from the image signal output portion; and
a light-emitting portion that emits light based on the current or the voltage applied from the drive portion,
wherein the light-emitting portion is an organic light-emitting element including at least one organic layer that includes a light-emitting layer and a pair of electrodes between which the organic layer is interposed,
wherein the organic layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

16. A display device comprising:
an image signal output portion that outputs an image signal;
a drive portion that applies a current or a voltage based on the signal output from the image signal output portion; and
a light-emitting portion that emits light based on the current or the voltage applied from the drive portion,
wherein the light-emitting portion is a wavelength-converting light-emitting element including an organic light-emitting element and a fluorescent layer which is disposed on a side of extracting light from the organic light-emitting element,
wherein the fluorescent layer absorbs light emitted from the organic light-emitting element and emits light having a different wavelength from that of the absorbed light,
wherein the organic light-emitting element includes at least one organic layer that includes a light-emitting layer and a pair of electrodes between which the organic layer is interposed,
wherein the organic layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

17. A display device comprising:
an image signal output portion that outputs an image signal;
a drive portion that applies a current or a voltage based on the signal output from the image signal output portion; and
a light-emitting portion that emits light based on the current or the voltage applied from the drive portion,
wherein the light-emitting portion is a light-converting light-emitting element including at least one organic layer that includes a light-emitting layer, a layer for multiplying a current, and a pair of electrodes between which the organic layer and the layer for multiplying a current are interposed,
wherein the light-emitting layer includes a host material and a transition metal complex, and
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

18. The display device according to claim 15,
wherein an anode and a cathode of the light-emitting portion are arranged in a matrix shape.

19. The display device according to claim 19,
wherein the light-emitting portion is driven by a thin film transistor.

20. An electronic apparatus comprising the display device according to claim 15.

21. An illumination device comprising:
a drive portion that applies a current or a voltage; and
a light-emitting portion that emits light based on the current or the voltage applied from the drive portion,
wherein the light-emitting portion is an organic light-emitting element including at least one organic layer that includes a light-emitting layer and a pair of electrodes between which the organic layer is interposed,
wherein the organic layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

22. An illumination device comprising:
a drive portion that applies a current or a voltage; and
a light-emitting portion that emits light based on the current or the voltage applied from the drive portion,
wherein the light-emitting portion is a wavelength-converting light-emitting element including an organic light-emitting element and a fluorescent layer which is disposed on a side of extracting light from the organic light-emitting element,
wherein the fluorescent layer absorbs light emitted from the organic light-emitting element and emits light having a different wavelength from that of the absorbed light,
wherein the organic light-emitting element includes at least one organic layer that includes a light-emitting layer and a pair of electrodes between which the organic layer is interposed,
wherein the organic layer includes a transition metal complex,
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

23. An illumination device comprising:
a drive portion that applies a current or a voltage; and
a light-emitting portion that emits light based on the current or the voltage applied from the drive portion,
wherein the light-emitting portion is a light-converting light-emitting element including at least one organic layer that includes a light-emitting layer, a layer for multiplying a current, and a pair of electrodes between which the organic layer and the layer for multiplying a current are interposed,
wherein the light-emitting layer includes a host material and a transition metal complex, and
wherein the transition metal complex comprises:
any one of Ir, Os, and Pt as a central metal; and
at least one of a carbene ligand and a silylene ligand, wherein the carbene ligand includes a boron atom in a skeleton thereof, wherein the carbene ligand is neutral or monoanionic, wherein the carbene ligand is monodentate, bidentate, or tridentate, wherein the silylene ligand includes a boron atom in a skeleton thereof, wherein the silylene ligand is neutral or monoanionic, wherein the silylene ligand is monodentate, bidentate, or tridentate.

24. An illumination apparatus comprising the illumination device according to claim 21.
